(19) United States
(12) Patent Application Publication
(10) Pub. No.: US 2026/0182036 A1
(43) Pub. Date: Jun. 25, 2026

(54) Display Substrate, Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Hongbo MA, Beijing (CN)

(21) Appl. No.: 18/726,830

(22) PCT Filed: Apr. 18, 2023
(86) PCT No.: PCT/CN2023/089064

§ 371 Date: Jul. 5, 2024

(51) Int. Cl. H10D 86/60

(52) U.S. Cl. CPC H10D 86/60

(57) ABSTRACT

Disclosed is a display substrate including: a base substrate, and a drive circuit layer disposed on the base substrate layer, which includes at least multiple circuit units, wherein at least one of the multiple circuit units includes a pixel circuit which includes at least a first capacitor a second capacitor, a data writing transistor, a drive transistor, and a first light emitting control transistor. A first end of the first capacitor is electrically connected with a gate electrode of the drive transistor, a second end of the first capacitor is electrically connected with a second end of the second capacitor, and a first end of the second capacitor is electrically connected with a first signal line. A first electrode of the first light emitting control transistor is electrically connected with a first power supply line and a second electrode is electrically connected with a first electrode of the drive transistor.

### CROSS-REFERENCE TO RELATED APPLICATION

The present application is a U.S. National Phase Entry of International Application No. PCT/CN2023/089064 having an international filing date of Apr. 18, 2023, contents of which should be construed as being incorporated into the present application by reference.

### TECHNICAL FIELD

The present disclosure relates to, but is not limited to, the field of display technologies, and particularly to a display substrate, a preparation method therefor, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, bendability, and a low cost, etc. With continuous development of the display technologies, a flexible display apparatus (Flexible Display) in which an OLED or a QLED is a light emitting device and signal control is performed using a Thin Film Transistor (TFT) has become a mainstream product in the field of display at present.

### SUMMARY

The following is a summary of subject matters described herein in detail. The summary is not intended to limit the protection scope of claims.

Embodiments of the present disclosure provide a display substrate, a preparation method therefor, and a display apparatus.

In one aspect, an embodiment of the present disclosure provides a display substrate including a base substrate and a drive circuit layer disposed on the base substrate, wherein the drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor. A first end of the first capacitor is electrically connected with a gate electrode of the drive transistor, a second end of the first capacitor is electrically connected with a second end of the second capacitor, and a first end of the second capacitor is electrically connected with a first signal line. A gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor. A gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor. The first signal line and the first power supply line are configured to provide different constant voltage signals.

In some exemplary implementation modes, the pixel circuit further includes a first reference transistor, wherein a gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor; the first signal line and the first reference signal line output a same signal.

In some exemplary implementation modes, the display substrate further includes a light emitting structure layer disposed at a side of the drive circuit layer away from the base substrate, wherein the light emitting structure layer includes at least a plurality of light emitting units, at least one of the plurality of light emitting units includes a cathode, and the cathode is connected with a second power supply line. The first signal line and the second power supply line output a same signal.

In some exemplary implementation modes, the first capacitor includes at least a first electrode plate as the first end of the first capacitor and a third electrode plate as the second end of the first capacitor, wherein an orthographic projection of the first electrode plate on the base substrate is at least partially overlapped with an orthographic projection of the third electrode plate on the base substrate. The second capacitor includes at least a second electrode plate as the second end of the second capacitor and a fourth electrode plate as the first end of the second capacitor, wherein an orthographic projection of the second electrode plate on the base substrate is at least partially overlapped with an orthographic projection of the fourth electrode plate on the base substrate. The fourth electrode plate is connected with the first signal line, the second electrode plate is connected with the third electrode plate, and the first electrode plate serves as the gate electrode of the drive transistor.

In some exemplary implementation modes, the first electrode plate and the second electrode plate are of a same layer structure, and the third electrode plate and the fourth electrode plate are of a same layer structure.

In some exemplary implementation modes, fourth electrode plates of second capacitors of pixel circuits of a plurality of circuit units adjacent along a first direction are of an interconnected integral structure.

In some exemplary implementation modes, the third electrode plate is provided with a second electrode plate connection line extending toward a direction to the fourth electrode plate, and the fourth electrode plate is provided with a second groove recessed toward a direction away from the third electrode plate; the second electrode plate connection line is disposed within the second groove, and an end of the second electrode plate connection line away from the third electrode plate is connected with the second electrode plate through a via and a connection electrode.

In some exemplary implementation modes, the first power supply line extends along a second direction, and the drive circuit layer further includes at least one first power supply connection line extending along a first direction, the first direction intersecting with the second direction; the first power supply line is connected with the first power supply connection line to form a mesh-like structure for transmitting a first power supply signal; an orthographic projection of the first power supply connection line on the base substrate is partially overlapped with an orthographic projection of the first capacitor on the base substrate.

In some exemplary implementation modes, the drive circuit layer further includes at least one second power supply connection line extending along the first direction and at least one second power supply line extending along the second direction, the first direction and the second direction intersect; the second power supply line is connected with the second power supply connection line to form a mesh-like structure for transmitting a second power supply signal; the second power supply connection line is located at a side of the first power supply connection line close to the second capacitor.

In some exemplary implementation modes, a portion of the second power supply connection line is located between the first capacitor and the second capacitor.

In some exemplary implementation modes, the second power supply line serves as the first signal line, and the fourth electrode plate of the second capacitor is connected with the second power supply line through the second power supply connection line.

In some exemplary implementation modes, at least two adjacent fourth electrode plates disposed along the first direction are connected through a first electrode plate connection line, an electrode plate connection block extending toward a direction to the third electrode plate is disposed on the first electrode plate connection line, and the electrode plate connection block is connected with the second power supply connection line extending along the first direction through a via.

In some exemplary implementation modes, fourth electrode plates of second capacitors of three adjacent circuit units disposed along the first direction are connected with the second power supply connection line through a same electrode plate connection block.

In some exemplary implementation modes, the drive circuit layer further includes at least one first reference signal line extending along a first direction and at least one reference signal connection line extending along a second direction, the first direction and the second direction intersect; the first reference signal line is connected with the reference signal connection line to form a mesh-like structure for transmitting a first reference signal. The first reference signal line serves as the first signal line, and the fourth electrode plate of the second capacitor is connected with the first reference signal line.

In some exemplary implementation modes, the first reference signal line is located at a side of the second capacitor away from the first capacitor, and a first reference connection block extending along the second direction is disposed at a side of the first reference signal line close to the second capacitor, the first reference connection block is connected with the fourth electrode plate of the second capacitor through a via, and is further connected with the reference signal connection line through another via.

In some exemplary implementation modes, the pixel circuit further includes a first initialization transistor and a compensation transistor. A gate electrode of the first initialization transistor is electrically connected with a first scan signal line, a first electrode of the first initialization transistor is electrically connected with a first initial signal line, and a second electrode of the first initialization transistor is electrically connected with the gate electrode of the drive transistor. A gate electrode of the compensation transistor is electrically connected with a second scan signal line, a first electrode of the compensation transistor is electrically connected with the gate electrode of the drive transistor, and a second electrode of the compensation transistor is electrically connected with a second electrode of the drive transistor.

In some exemplary implementation modes, the at least one circuit unit further includes a first shield electrode, wherein an orthographic projection of the first shield electrode on the base substrate is at least partially overlapped with an orthographic projection of a first active layer between two gate electrodes of first initialization transistors in the circuit unit on the base substrate, and the orthographic projection of the first shield electrode on the base substrate is further at least partially overlapped with an orthographic projection of a second active layer between two gate electrodes of compensation transistors in an adjacent circuit unit on the base substrate.

In some exemplary implementation modes, the first shield electrode includes a first shield end and a second shield end extending along a first direction; an orthographic projection of the first shield end on the base substrate is at least partially overlapped with an orthographic projection of the first active layer between two gate electrodes of first initialization transistors in the circuit unit on the base substrate. An orthographic projection of the second shield end on the base substrate is at least partially overlapped with the orthographic projection of the second active layer between two gate electrodes of compensation transistors in the adjacent circuit unit on the base substrate. The first shield electrode is connected with a first power supply connection line.

In some exemplary implementation modes, extension directions of the first initial signal line, the first scan signal line, and the second scan signal line are at least partially the same and the first initial signal line, the first scan signal line, and the second scan signal line are located at a same side of the first initialization transistor; the first initial signal line is located between the first scan signal line and the second scan signal line.

In some exemplary implementation modes, the first initial signal line, the first scan signal line, and the second scan signal line are of a same layer structure.

In some exemplary implementation modes, the pixel circuit further includes a second light emitting control transistor. A gate electrode of the second light emitting control transistor is electrically connected with a second light emitting signal line, a first electrode of the second light emitting control transistor is electrically connected with the second electrode of the drive transistor, and a second electrode of the second light emitting control transistor is electrically connected with a light emitting device. The second light emitting signal line and the first light emitting signal line are of a same layer structure.

In some exemplary implementation modes, the pixel circuit further includes a second reference transistor and a second initialization transistor; a gate electrode of the second reference transistor is electrically connected with a fourth scan signal line, a first electrode of the second reference transistor is electrically connected with a second reference signal line, and a second electrode of the second reference transistor is electrically connected with a first electrode of the drive transistor. A gate electrode of the second initialization transistor is electrically connected with the fourth scan signal line, a first electrode of the second initialization transistor is electrically connected with a second initial signal line, and a second electrode of the second initialization transistor is electrically connected with a light emitting device. Active layers of at least two adjacent second initialization transistors along a first direction are connected into an integral structure through a second active connection line.

In some exemplary implementation modes, in a direction perpendicular to the display substrate, the drive circuit layer includes a semiconductor layer, a first conductive layer, a second conductive layer, a third conductive layer, and a fourth conductive layer sequentially disposed on the base substrate. Active layers of the data writing transistor, the drive transistor, and the first light emitting control transistor are located in the semiconductor layer. Gate electrodes of the data writing transistor, the drive transistor, and the first light emitting control transistor, the first electrode plate of the first capacitor and the second electrode plate of the second capacitor are located in the first conductive layer. The third electrode plate of the first capacitor and the fourth electrode plate of the second capacitor are located in the second conductive layer. The third scan signal line is located in the third conductive layer. The first power supply line and the data signal line are located in the fourth conductive layer.

In another aspect, an embodiment of the present disclosure provides a display apparatus, which includes the aforementioned display substrate.

In another aspect, an embodiment of the present disclosure provides a preparation method of a display substrate, including: forming a drive circuit layer on a base substrate; wherein the drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor; a first end of the first capacitor is electrically connected with a gate electrode of the drive transistor, a second end of the first capacitor is electrically connected with a second end of the second capacitor, and a first end of the second capacitor is electrically connected with a first signal line; a gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor; a gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor; the first signal line and the first power supply line are configured to provide different constant voltage signals.

In another aspect, an embodiment of the present disclosure provides a display substrate including a base substrate and a drive circuit layer disposed on the base substrate, wherein the drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor. A first end of the first capacitor is electrically connected with a gate electrode of the drive transistor, a second end of the first capacitor is electrically connected with a second end of the second capacitor, and a first end of the second capacitor is electrically connected with a first signal line. A gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor. A gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor. The first signal line and the first power supply line are configured to provide different constant voltage signals. The data writing transistor, the second capacitor, the first capacitor, and the first light emitting control transistor are sequentially disposed along a second direction, and an orthographic projection of the first capacitor on the base substrate is partially overlapped with an orthographic projection of the drive transistor on the base substrate.

In some exemplary implementation modes, the pixel circuit further includes a first reference transistor, wherein a gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor. The first reference signal line is located at a side of the second capacitor away from the first capacitor.

In some exemplary implementation modes, the first signal line and the first reference signal line transmit a same signal. The first capacitor includes at least a first electrode plate as the first end of the first capacitor and a third electrode plate as the second end of the first capacitor, wherein an orthographic projection of the first electrode plate on the base substrate is at least partially with an orthographic projection of the third electrode plate on the base substrate. The second capacitor includes at least a second electrode plate as the second end of the second capacitor and a fourth electrode plate as the first end of the second capacitor, wherein an orthographic projection of the second electrode plate on the base substrate is at least partially with an orthographic projection of the fourth electrode plate on the base substrate. The fourth electrode plate of the second capacitor is connected with the first reference signal line through a via.

In some exemplary implementation modes, the drive circuit layer further includes at least one second power supply connection line extending along a first direction and at least one second power supply line extending along a second direction, the first direction intersecting with the second direction; the second power supply line is connected with the second power supply connection line to form a mesh-like structure for transmitting a second power supply signal; a portion of the second power supply connection line is located between the first capacitor and the second capacitor. The first signal line and the second power supply line transmit a same signal.

In some exemplary implementation modes, the pixel circuit further includes a first initialization transistor and a compensation transistor. A gate electrode of the first initialization transistor is electrically connected with a first scan signal line, a first electrode of the first initialization transistor is electrically connected with a first initial signal line, and a second electrode of the first initialization transistor is electrically connected with the gate electrode of the drive transistor. A gate electrode of the compensation transistor is electrically connected with a second scan signal line, a first electrode of the compensation transistor is electrically connected with the gate electrode of the drive transistor, and a second electrode of the compensation transistor is electrically connected with a second electrode of the drive transistor; the first initialization transistor and the compensation transistor are located at a side of the first capacitor away from the second capacitor; extension directions of the first initial signal line, the first scan signal line, and the second scan signal line are at least partially the same and the first initial signal line, the first scan signal line, and the second scan signal line are located at a side of the first initialization transistor away from the first capacitor; the first initial signal line is located between the first scan signal line and the second scan signal line.

Other aspects may be comprehended after drawings and detailed description are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with the embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a structure of a display apparatus.

FIG. 2 is a schematic diagram of a planar structure of a display substrate.

FIG. 3 is a schematic partial cross-sectional view of a display substrate.

FIG. 4 is an equivalent circuit diagram of a pixel circuit according to at least one embodiment of the present disclosure.

FIG. 5 is an example diagram of working timing of the pixel circuit shown in FIG. 4.

FIG. 6 is a schematic diagram of a planar structure of a display substrate according to at least one embodiment of the present disclosure.

FIG. 7 is a schematic partial cross-sectional view along a Q-Q′ direction in FIG. 6.

FIG. 8 is a schematic diagram of the display substrate after a semiconductor layer is formed in FIG. 6.

FIG. 9A is a schematic diagram of the display substrate after a first conductive layer is formed in FIG. 6.

FIG. 9B is a schematic diagram of the first conductive layer in FIG. 9A.

FIG. 10A is a schematic diagram of the display substrate after a second conductive layer is formed in FIG. 10.

FIG. 10B is a schematic diagram of the second conductive layer in FIG. 10A.

FIG. 11 is a schematic diagram of the display substrate after a third insulation layer is formed in FIG. 6.

FIG. 12A is a schematic diagram of the display substrate after a third conductive layer is formed in FIG. 6.

FIG. 12B is a schematic diagram of the third conductive layer in FIG. 12A.

FIG. 13 is a schematic diagram of the display substrate after a fourth insulation layer is formed in FIG. 6.

FIG. 14 is a schematic diagram of the fourth conductive layer in FIG. 6.

FIG. 15 is a schematic diagram of a planar structure of another display substrate according to at least one embodiment of the present disclosure.

FIG. 16 is a schematic diagram of the display substrate after a semiconductor layer and a first conductive layer are formed in FIG. 15.

FIG. 17A is a schematic diagram of the display substrate after a second conductive layer is formed in FIG. 15.

FIG. 17B is a schematic diagram of the second conductive layer in FIG. 17A.

FIG. 18 is a schematic diagram of the display substrate after a third insulation layer is formed in FIG. 15.

FIG. 19A is a schematic diagram of the display substrate after a third conductive layer is formed in FIG. 15.

FIG. 19B is a schematic diagram of the third conductive layer in FIG. 19A.

FIG. 20 is a schematic diagram of the display substrate after a fourth insulation layer is formed in FIG. 15.

FIG. 21 is a schematic diagram of the fourth conductive layer in FIG. 15.

FIG. 22 is a schematic diagram of a planar structure of another display substrate according to at least one embodiment of the present disclosure.

FIG. 23 is a schematic diagram of the display substrate after a semiconductor layer is formed in FIG. 22.

FIG. 24A is a schematic diagram of the display substrate after a first conductive layer is formed in FIG. 22.

FIG. 24B is a schematic diagram of the first conductive layer in FIG. 24A.

FIG. 25A is a schematic diagram of the display substrate after a second conductive layer is formed in FIG. 22.

FIG. 25B is a schematic diagram of the second conductive layer in FIG. 25A.

FIG. 26 is a schematic diagram of the display substrate after a third insulation layer is formed in FIG. 22.

FIG. 27A is a schematic diagram of the display substrate after a third conductive layer is formed in FIG. 22.

FIG. 27B is a schematic diagram of the third conductive layer in FIG. 27A.

FIG. 28 is a schematic diagram of the display substrate after a fourth insulation layer is formed in FIG. 22.

FIG. 29 is a schematic diagram of a planar structure of another display substrate according to at least one embodiment of the present disclosure.

FIG. 30 is a schematic diagram of the display substrate after a first conductive layer is formed in FIG. 29.

FIG. 31A is a schematic diagram of the display substrate after a second conductive layer is formed in FIG. 29.

FIG. 31B is a schematic diagram of the second conductive layer in FIG. 31A.

FIG. 32A is a schematic diagram of the display substrate after a third conductive layer is formed in FIG. 29.

FIG. 32B is a schematic diagram of the third conductive layer in FIG. 32A.

FIG. 33 is a schematic diagram of a display apparatus according to at least one embodiment of the present disclosure.

### DETAILED DESCRIPTION

The embodiments of the present disclosure will be described below in combination with the drawings in detail. Implementation modes may be implemented in multiple different forms. Those of ordinary skills in the art may easily understand such a fact that modes and contents may be transformed into other forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that a referred apparatus or element must have a specific orientation and be structured and operated with the specific orientation but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined explicitly, terms “mount”, “mutually connect”, “connect”, and “couple” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations. Among them, an “electrical connection” includes a case where constituent elements are connected together through an element with a certain electrical effect. The “element with the certain electrical effect” is not particularly limited as long as electrical signals between the connected constituent elements may be transmitted. Examples of the “element with the certain electrical effect” not only include electrodes and wirings, but also include switching elements such as transistors, resistors, inductors, capacitors, other elements with one or more functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source or a drain, and the second electrode may be a drain or a source. In addition, the gate of the transistor is referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

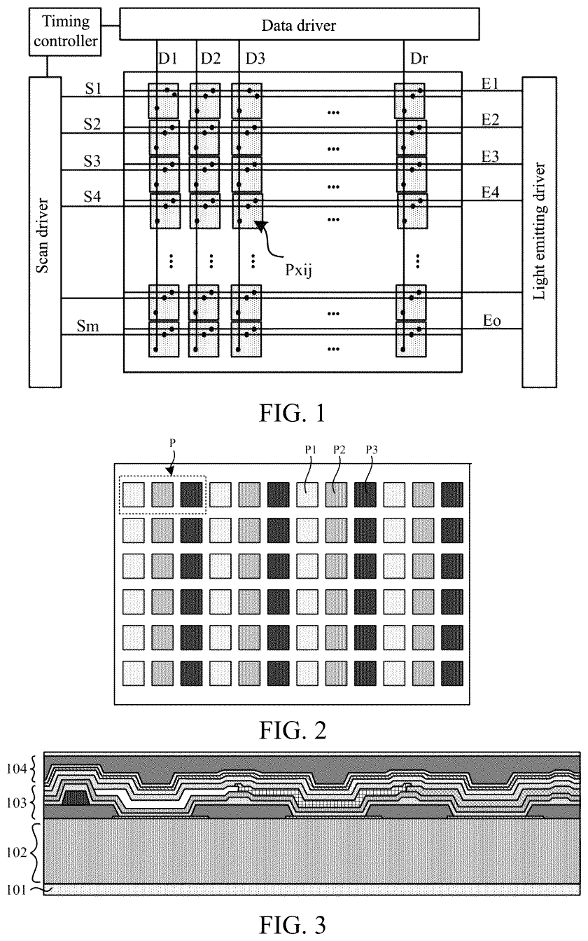

FIG. 1 is a schematic diagram of a structure of a display apparatus. In some examples, as shown in FIG. 1, the display apparatus may include a timing controller, a data driver, a scan driver, a light emitting driver, and a pixel array. The timing controller may be connected with the data driver, the scan driver, and the light emitting driver, respectively. The data driver is respectively connected with a plurality of data signal lines (e.g., D1 to Dr), the scan driver may be respectively connected with a plurality of scan signal lines (e.g., S1 to Sm), and the light emitting driver may be respectively connected with a plurality of light emitting signal lines (e.g., E1 to Eo). The pixel array may include a plurality of sub-pixels Pxij, wherein i and j may be natural numbers. At least one sub-pixel Pxij may include a circuit unit and a light emitting unit, wherein the circuit unit may include at least a pixel circuit which may be respectively connected with a scan signal line, a light emitting signal line, and a data signal line, and the light emitting unit may include a light emitting device which may be electrically connected with the pixel circuit of the circuit unit.

In some examples, the timing controller may provide a gray-scale value and a control signal which are suitable for a specification of the data driver to the data driver, provide a clock signal, a scan start signal, and the like which are suitable for a specification of the scan driver to the scan driver, and provide a clock signal, an emission stop signal, and the like which are suitable for a specification of the light emitting driver to the light emitting driver. The data driver may generate a data voltage to be provided to the data signal lines D1, D2, D3, ..., and Dr using the grayscale value and the control signal that are received from the timing controller. For example, the data driver may sample the grayscale value using the clock signal and apply a data voltage corresponding to the grayscale value to the data signal lines D1 to Dr by taking a pixel row as a unit, wherein r may be a natural number. The scan driver may generate a scan signal to be provided to the scan signal lines S1, S2, S3, ..., and Sm by receiving the clock signal, the scan start signal, and the like from the timing controller. For example, the scan driver may provide sequentially a scan signal with an on-level pulse to the scan signal lines S1 to Sm, where m may be a nature number. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, ..., and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In some examples, the pixel array may be disposed on the display substrate.

FIG. 2 is a schematic diagram of a planar structure of a display substrate. In some examples, the display substrate may include a display region and a bezel region located around the display region. As shown in FIG. 2, the display region of the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit, the circuit unit may at least include a pixel circuit which is connected with a scan signal line, a data signal line, and a light emitting signal line respectively, and the pixel circuit may be configured to receive a data voltage transmitted by the data signal line and output a corresponding current to the light emitting unit under control of the scan signal line and the light emitting signal line. The light emitting unit may at least include a light emitting device, the light emitting device may be electrically connected with a pixel circuit of a sub-pixel where the light emitting device is located, and the light emitting device may be configured to emit light with corresponding brightness in response to a current output by the pixel circuit of the sub-pixel where the light emitting device is located.

In some examples, the pixel circuit may include multiple transistors and at least one capacitor. For example, the pixel circuit may have a 3T1C, 4T1C, 5T1C, 5T2C, 6T1C, 7T1C, or 8T1C structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In some examples, a shape of the light emitting device may be a rectangle, a rhombus, a pentagon, or a hexagon. When one pixel unit includes three sub-pixels, light emitting devices of the three sub-pixels may be arranged side by side horizontally, side by side vertically, or in a manner like a Chinese character “ [symbol] ”. When one pixel unit includes four sub-pixels, light emitting devices of the four sub-pixels may be arranged side by side horizontally, side by side vertically, or in a manner to form a square. However, the embodiment is not limited thereto.

FIG. 3 is a schematic partial cross-sectional view of a display substrate. FIG. 3 illustrates a structure of three sub-pixels of the display substrate. In some examples, as shown in FIG. 3, in a direction perpendicular to the display substrate, a display region of the display substrate may include a base substrate 101, a drive circuit layer 102 disposed on the base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementation modes, the display substrate may include another film layer such as a touch structure layer. The present disclosure is not limited here.

In some examples, the base substrate 101 may be a flexible base substrate or may be a rigid base substrate. The drive circuit layer 101 may include multiple circuit units, a circuit unit may at least include a pixel circuit, and the pixel circuit may include multiple transistors and at least one capacitor. The light emitting structure layer 103 may include a plurality of light emitting units, and a light emitting unit may include at least a light emitting device. The encapsulation structure layer 104 may include a first encapsulation layer, a second encapsulation layer, and a third encapsulation layer which are stacked. The first encapsulation layer and the third encapsulation layer may be made of an inorganic material, and the second encapsulation layer may be made of an organic material. The second encapsulation layer may be disposed between the first encapsulation layer and the third encapsulation layer to form a laminated structure of an inorganic material/an organic material/an inorganic material, which may ensure that external water vapor cannot enter the light emitting structure layer 103.

In some examples, the light emitting device may be any of a Light Emitting Diode (LED), an Organic Light Emitting Diode (OLED), a Quantum dot Light Emitting Diode (QLED), a micro LED (including: a mini-LED or a micro-LED), and the like. For example, the light emitting device may be an OLED, and the light emitting device may emit red light, green light, blue light, or white light, etc. under drive of a pixel circuit corresponding to the light emitting element. A color of light emitted from the light emitting device may be determined as required. In some examples, the light emitting device may include an anode, a cathode, and an organic emitting layer disposed between the anode and the cathode. The anode of the light emitting device may be electrically connected with a corresponding pixel circuit, the organic emitting layer is connected with the anode, the cathode is connected with the organic emitting layer, and the organic emitting layer may emit light of a corresponding color under drive of the anode and the cathode. However, the embodiment is not limited thereto.

In some examples, the organic emitting layer may include: an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL) and an Electron Injection Layer (EIL). |

The present embodiment provides a display substrate, including: a base substrate and a drive circuit layer disposed on the base substrate. The drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor. A first end of the first capacitor is electrically connected with a gate electrode of the drive transistor, a second end of the first capacitor is electrically connected with a second end of the second capacitor, and a first end of the second capacitor is electrically connected with a first signal line. A gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor. A gate electrode of the first light emitting control transistor is electrically connected with a first light emitting signal line, a first electrode of the first light emitting control transistor is electrically connected with a first power supply line, and a second electrode of the first light emitting control transistor is electrically connected with the first electrode of the drive transistor. The first signal line and the first power supply line are configured to provide different constant voltage signals.

In the display substrate provided by the present embodiment, a constant voltage signal provided by the first signal line may be used as a voltage stabilizing signal of the second capacitor, and a constant voltage signal provided by the first power supply line may be used to drive light emission and compensate a threshold voltage of the drive transistor. By disposing the first signal line and the first power supply line to provide different constant voltage signals, the first power supply line and the first signal line may be arranged separately, which is beneficial to improving a storage capacity of the second capacitor and slowing down an attenuation speed of a data signal.

In some exemplary implementation modes, the pixel circuit may further include a first reference transistor. A gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor. The first signal line and the first reference signal line may output a same signal. The first end of the second capacitor may be connected with the first reference signal line. The first end of the second capacitor is disposed to receive a first reference signal, which is beneficial to improving the storage capacity of the second capacitor and slowing down an attenuation speed of a written data signal; and is beneficial to a wiring design of the display substrate and saves occupied space.

In some exemplary implementation modes, the display substrate may further include a light emitting structure layer disposed at a side of the drive circuit layer away from the base substrate, wherein the light emitting structure layer includes at least a plurality of light emitting units, at least one of the plurality of light emitting units includes a cathode, and the cathode is connected with a second power supply line. The first signal line and the second power supply line may output a same signal. The first end of the second capacitor may be connected with the second power supply line. By disposing the first end of the second capacitor to receive a second power supply signal, a voltage difference between two ends of the second capacitor may be increased, which is beneficial to improving the storage capacity of the second capacitor and slowing down the attenuation speed of the written data signal; and is beneficial to the wiring design of the display substrate and may save the occupied space.

The display substrate of the present embodiment will now be described through some examples.

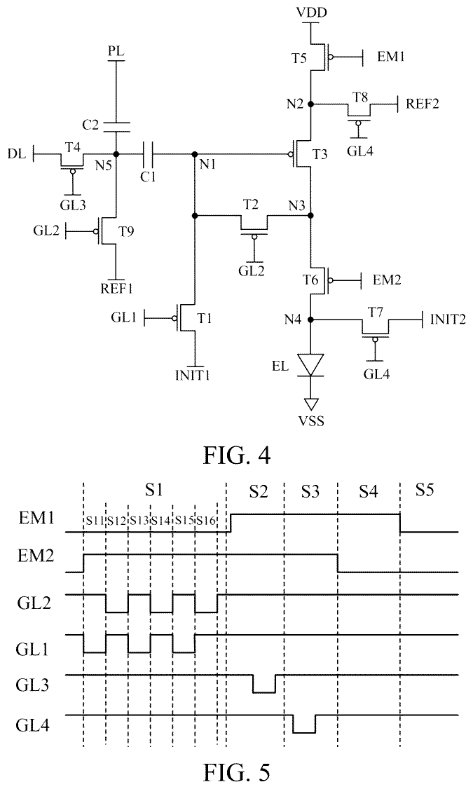

FIG. 4 is an equivalent circuit diagram of a pixel circuit according to at least one embodiment of the present disclosure. The pixel circuit of this example may be a 9T2C structure and may include nine transistors (e.g., including a first transistor T1 to a ninth transistor T9) and two capacitors (e.g., including a first capacitor C1 and a second capacitor C2). The pixel circuit may be electrically connected with 13 signal lines, respectively (for example, including a first scan signal line GL1, a second scan signal line GL2, a third scan signal line GL3, a fourth scan signal line GL4, a first light emitting signal line EM1, a second light emitting signal line EM2, a first initial signal line INIT1, a second initial signal line INIT2, a first reference signal line REF1, a second reference signal line REF2, a data signal line DL, a first power supply line VDD, and a first signal line PL). The first signal line PL may continuously provide a constant first voltage. The first power supply line VDD may continuously provide a first power supply signal. A first voltage provided by the first signal line PL may be different from the first power supply signal provided by the first power supply line VDD. For example, the first voltage provided by the first signal line PL may be less than the first power supply signal provided by the first power supply line VDD.

In some examples, as shown in FIG. 4, the pixel circuit may include a first node N1, a second node N2, a third node N3, a fourth node N4, and a fifth node N5. Wherein, the first node N1 may be connected with a second electrode of the first transistor T1, a first electrode of a second transistor T2, a gate electrode of a third transistor T3, and a first end of the first capacitor C1, respectively. The second node N2 may be connected with a first electrode of the third transistor T3, a second electrode of a eighth transistor T8, and a second electrode of a fifth transistor T5, respectively. The third node N3 may be connected with a second electrode of the second transistor T2, a second electrode of the third transistor T3, and a first electrode of a sixth transistor T6 respectively. The fourth node N4 may be connected with a second electrode of the sixth transistor T6 and a second electrode of the seventh transistor T7, respectively. The fifth node N5 may be connected with a second electrode of the fourth transistor T4, a second electrode of the ninth transistor T9, a second end of the first capacitor C1, and a second end of the second capacitor C2, respectively. The fourth node N4 may also be connected with an anode of a light emitting device EL.

In some examples, the first end (e.g., lower electrode plate) of the first capacitor C1 is connected with the first node N1, and the second end (e.g., upper electrode plate) of the first capacitor C1 is connected with the fifth node N5. A first end of the second capacitor C2 (e.g., upper electrode plate) is connected with the first signal line PL, and the second end of the second capacitor C2 (e.g., lower electrode plate) is connected with the fifth node N5. In some examples, the first signal line PL may continuously provide a constant voltage signal.

In some examples, a gate electrode of the first transistor T1 is connected with the first scan signal line GL1, a first electrode of the first transistor T1 is connected with the first initial signal line INIT1, and the second electrode of the first transistor T1 is connected with the first node N1. When an ON level signal is applied to the first scan signal line GL1, the first transistor T1 transmits a first initial voltage to the gate electrode of the third transistor T3 and the first end of the first capacitor C1 to release charge accumulated in the first capacitor C1, thereby achieving initialization.

In some examples, a gate electrode of the second transistor T2 is connected with the second scan signal line GL2, the first electrode of the second transistor T2 is connected with the first node N1, and the second electrode of the second transistor T2 is connected with the third node N3. When an ON level signal is applied to the second scan signal line GL2, the second transistor T2 enables the gate electrode of the third transistor T3 to be connected with the second electrode of the third transistor T3.

In some examples, the gate electrode of the third transistor T3 is connected with the first node N1, namely the gate electrode of the third transistor T3 is connected with the first end of the first capacitor C, the first electrode of the third transistor T3 is connected with the second node N2, and the second electrode of the third transistor T3 is connected with the third node N3. The third transistor T3 may be referred to as a drive transistor and the third transistor T3 determines a magnitude of a drive current according to a potential difference between the gate electrode and the first electrode of the third transistor T3.

In some examples, a gate electrode of the fourth transistor T4 is connected with the third scan signal line GL3, a first electrode of the fourth transistor T4 is connected with the data signal line DL, and a second electrode of the fourth transistor T4 is connected with the fifth node N5. When an ON level signal is applied to the third scan signal line GL3, the fourth transistor T4 enables a data voltage of the data signal line DL to be input to the fifth node N5 (i.e., the second end of the first capacitor C1 and the second end of the second capacitor C2).

In some examples, a gate electrode of the fifth transistor T5 is connected with the first light emitting signal line EM1, a first electrode of the fifth transistor T5 is connected with the first power supply line VDD, and a second electrode of the fifth transistor T5 is connected with the second node N2. A gate electrode of the sixth transistor T6 is connected with the second light emitting signal line EM2, a first electrode of the sixth transistor T6 is connected with the third node N3, and a second electrode of the sixth transistor T6 is connected with the fourth node N4. When an ON level signal is applied to the first light emitting signal line EM1 and the second light emitting signal line EM2, the fifth transistor T5 and the sixth transistor T6 form a drive current path between the first power supply line VDD and the second power supply line VSS to enable the light emitting device EL to emit light.

In some examples, a gate electrode of the seventh transistor T7 is connected with the fourth scan signal line GL4, a first electrode of the seventh transistor T7 is connected with the second initial signal line INIT2, and a second electrode of the seventh transistor T7 is connected with the fourth node N4. When an ON level signal is applied to the fourth scan signal line GL4, the seventh transistor T7 transmits a second initial voltage to a first electrode of the light emitting device EL to release charge accumulated in the first electrode of the light emitting device EL, thereby achieving initialization.

In some examples, a gate electrode of the eighth transistor T8 is connected with the fourth scan signal line GL4, a first electrode of the eighth transistor T8 is connected with the second reference signal line REF2, and a second electrode of the eighth transistor T8 is connected with the second node N2. When an ON level signal is applied to the fourth scan signal line GL4, the eighth transistor T8 transmits a second reference signal to the second node N2.

In some examples, a gate electrode of the ninth transistor T9 is connected with the second scan signal line GL2, a first electrode of the ninth transistor T9 is connected with the first reference signal line REF1, and a second electrode of the ninth transistor T9 is connected with the fifth node N5. When an ON level signal is applied to the second scan signal line GL2, the ninth transistor T9 transmits a first reference signal to the fifth node N5.

In some examples, the light emitting device EL may be an OLED including a first electrode (anode), an organic emitting layer, and a second electrode (cathode), which are stacked, or may be a QLED including a first electrode (anode), a quantum dot emitting layer, and a second electrode (cathode), which are stacked. The first electrode of the light emitting device EL is connected with the fourth node N4, and a second electrode of the light emitting device EL is connected with the second power supply line VSS. In some examples, a signal of the second power supply line VSS may be a continuously provided low level signal, and a signal of the first power supply line VDD may be a continuously provided high level signal. The first power supply signal provided by the first power supply line VDD may be different from a constant voltage signal provided by the first signal line PL.

In some examples, the first transistor T1 to the ninth transistor T9 of the pixel circuit may be P-type transistors or may be N-type transistors. Using a same type of transistors in the pixel circuit may simplify a process flow, reduce process difficulties of a display panel, and improve a yield of products. In some possible implementation modes, the first transistor T1 to the ninth transistor T9 may include a P-type transistor and an N-type transistor.

In some examples, for the first transistor T1 to the ninth transistor T9 of the pixel circuit, low temperature poly silicon film transistors may be used, oxide film transistors may be used, or both of a low temperature poly silicon film transistor and an oxide film transistor may be used. Low Temperature Poly Silicon (LTPS) is used for an active layer of a low temperature poly silicon thin film transistor and an oxide semiconductor (Oxide) is used for an active layer of an oxide thin film transistor. The low temperature poly silicon thin film transistor has advantages, such as a high mobility and fast charging, and the oxide thin film transistor has advantages, such a low leakage current. The low temperature poly silicon thin film transistor and the oxide thin film transistor are integrated on one display substrate, that is, an LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

FIG. 5 is an example diagram of working timing of the pixel circuit shown in FIG. 4. In some examples, taking a case that the first transistor T1 to the ninth transistor T9 in the pixel circuit shown in FIG. 4 are all P-type transistors as an example, a working process of the pixel circuit may include following stages.

In a first stage S1, a signal of the first light emitting signal line EM1 is a low level signal, and signals of the second light emitting signal line EM2, the third scan signal line GL3, and the fourth scan signal line GL4 are high level signals. The low level signal of the first light emitting signal line EM1 may enable the fifth transistor T5 to be turned on, and the first power supply signal of the first power supply line VDD may be provided to the second node N2. The signals of the second light emitting signal line EM2, the third scan signal line GL3, and the fourth scan signal line GL4 are high level signals so that the sixth transistor T6, the fourth transistor T4, the seventh transistor T7, and the eighth transistor T8 are all turned off.

The first stage S1 may include a first sub-stage S11, a second sub-stage S12, a third sub-stage S13, a fourth sub-stage S14, a fifth sub-stage S15, and a sixth sub-stage S16. In the first sub-stage S11, a signal of the first scan signal line GL1 is a low level signal so that the first transistor T1 is turned on; a signal of the second scan signal line GL2 is a high level signal so that the second transistor T2 and the ninth transistor T9 are turned off. The first transistor T1 is turned on so that a first initial signal of the first initial signal line INIT1 may be provided to the first node N1 to initialize the first node N1. In the second sub-stage S12, a signal of the first scan signal line GL1 is a high level signal so that the first transistor T1 is turned off; a signal of the second scan signal line GL2 is a low level signal so that the second transistor T2 and the ninth transistor T9 are turned on. The second transistor T2 is turned on, so that the first node N1 and the third node N3 may be connected, threshold compensation may be performed on the third transistor T3, and a threshold voltage of the third transistor T3 may be written into the first node N1. The ninth transistor T9 is turned on, and a first reference signal of the first reference signal line REF1 may be provided to the fifth node N5 to initialize the fifth node N5. The third sub-stage S13 and the fifth sub-stage S15 are the same as the first sub-stage S11, and the fourth sub-stage S14 and the sixth sub-stage S16 are the same as the second sub-stage S12, thus will not be repeated here.

When the drive transistor (i.e., the third transistor T3) is in a state for a long time, electrons are trapped in traps, which will cause a hysteresis. Therefore, in this stage, initialization of the first node N1 and a threshold voltage writing process are performed for many times (e.g., three times), so that the hysteresis of the drive transistor may be reduced, and potential stability of the first node N1 may be ensured.

The second stage S2 may be called a data writing stage. Signals of the first light emitting signal line EM1, the second light emitting signal line EM2, the first scan signal line GL1, the second scan signal line GL2, and the fourth scan signal line GL4 are high level signals so that the fifth transistor T5, the sixth transistor T6, the first transistor T1, the ninth transistor T9, the second transistor T2, the seventh transistor T7, and the eighth transistor T8 are all turned off. A signal of the third scan signal line GL3 is a low level signal so that the fourth transistor T4 is turned on, a data voltage provided by the data signal line DL is written into the fifth node N5, and the data voltage is written into the first node N1 through the first capacitor C1.

In the third stage S3, signals of the first light emitting signal line EM1, the second light emitting signal line EM2, the first scan signal line GL1, the second scan signal line GL2, and the third scan signal line GL3 are high level signals, so that the fifth transistor T5, the sixth transistor T6, the first transistor T1, the second transistor T2, the ninth transistor T9, and the fourth transistor T4 are all turned off. A signal of the fourth scan signal line GL4 is a low level signal so that both the seventh transistor T7 and the eighth transistor T8 are turned on. The seventh transistor T7 is turned on, a second initial signal of the second initial signal line INIT2 may be written into the fourth node N4, and the fourth node N4 is initialized to avoid a residual signal of a previous frame affecting display of a present frame; the eighth transistor T8 is turned on, and a second reference signal of the second reference signal line REF2 may be written into the second node N2, which is helpful to reduce the hysteresis of the drive transistor.

In the fourth stage S4, signals of the first light emitting signal line EM1, the first scan signal line GL1, the second scan signal line GL2, the third scan signal line GL3, and the fourth scan signal line GL4 are high level signals, so that the fifth transistor T5, the first transistor T1, the second transistor T2, the ninth transistor T9, the fourth transistor T4, the seventh transistor T7, and the eighth transistor T8 are all turned off. A signal of the second light emitting signal line EM2 is a low level signal, so that the sixth transistor T6 is turned on, and the third node N3 and the fourth node N4 are connected, so that potentials of the third node N3 and the fourth node N4 are the same. By connecting the fourth node N4 and the third node N3, it is helpful to improve a potential of the fourth node N4 and reduce a time length required to reach a turn-on voltage of a light emitting device.

In the fifth stage S5, signals of the first light emitting signal line EM1 and the second light emitting signal line EM2 are low level signals, so that the fifth transistor T5 and the sixth transistor T6 are turned on, and a first power supply signal of the first power supply line VDD may provide a drive signal to a light emitting device EL through the turned-on fifth transistor T5, the third transistor T3, and the sixth transistor T6 to drive the light emitting device EL to emit light. Signals of the first scan signal line GL1, the second scan signal line GL2, the third scan signal line GL3, and the fourth scan signal line GL4 are high level signals so that the first transistor T1, the second transistor T2, the ninth transistor T9, the fourth transistor T4, the seventh transistor T7, and the eighth transistor T8 are all turned off.

The pixel circuit of this example may improve the hysteresis of the drive transistor, which is beneficial to improve a display effect.

In some examples, a constant voltage signal provided by the first signal line may serve as a voltage stabilizing signal of the second capacitor, and a first power supply signal provided by the first power supply line may be configured to perform compensation of the threshold voltage of the drive transistor and to drive light emission. For example, the constant voltage signal provided by the first signal line may be smaller than the first power supply signal provided by the first power supply line. Compared with a design in which the first power supply line is connected with the first end of the second capacitor, the first signal line is connected with the first end of the second capacitor in this example, which may increase a voltage difference between two ends of the second capacitor, thereby improving a storage capacity of the second capacitor and further reducing an attenuation speed of a written data signal.

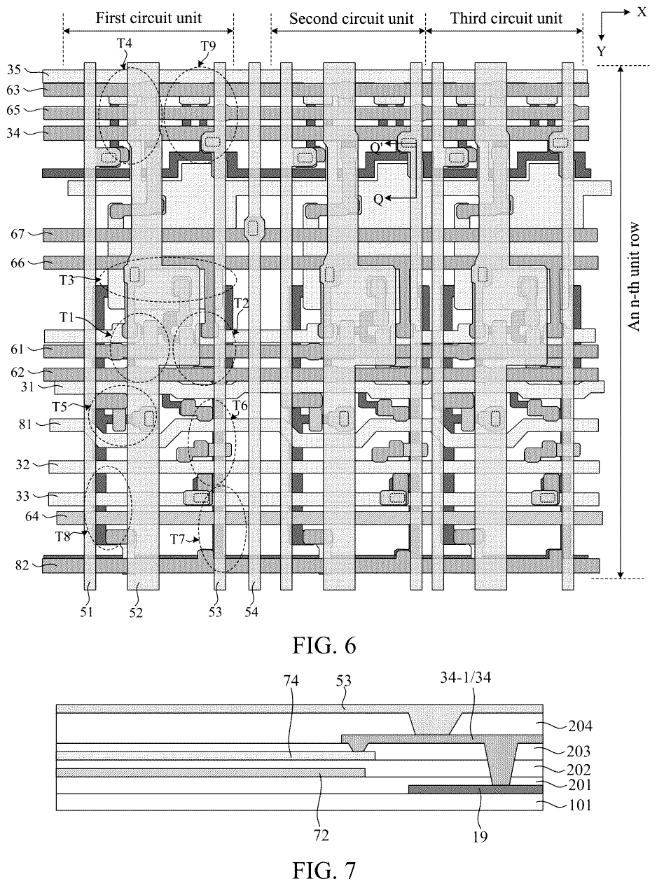

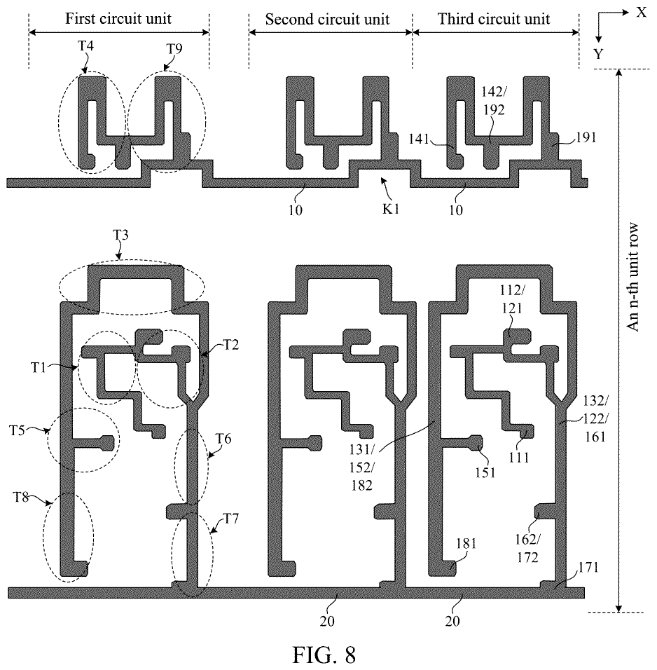

FIG. 6 is a schematic diagram of a planar structure of a display substrate according to at least one embodiment of the present disclosure. A structure of a pixel circuit in three circuit units (i.e., a first circuit unit, a second circuit unit, and a third circuit unit) of the display substrate is schematically illustrated in FIG. 6. FIG. 7 is a schematic partial cross-sectional view along a Q-Q′ direction in FIG. 6. In this example, a first signal line and a first reference signal line transmit the same signal, in other words, the first reference signal line of this example may serve as the first signal line.

In some examples, the display substrate may include a drive circuit layer disposed on a base substrate and a light emitting structure layer disposed at a side of the drive circuit layer away from the base substrate. The drive circuit layer may include at least a plurality of circuit units, the light emitting structure layer may include at least a plurality of light emitting units, at least one circuit unit may include a pixel circuit, and at least one light emitting unit may include a light emitting device. The light emitting device may include at least an anode, an organic emitting layer, and a cathode, and the anode of the light emitting device may be connected with a pixel circuit in a corresponding circuit unit.

The circuit unit described in the present disclosure refers to a region divided according to a pixel circuit; the light emitting unit described in the present disclosure refers to a region divided according to a light emitting device. In some examples, a position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

In some examples, a plurality of circuit units sequentially disposed along a first direction X may be referred to as a unit row, and a plurality of circuit units sequentially disposed along a second direction Y may be referred to as a unit column, and the plurality of unit rows and the plurality of unit columns may constitute an array of circuit units arranged in an array. Wherein the first direction X intersects with the second direction Y, for example, the first direction X may be perpendicular to the second direction Y.

In some examples, as shown in FIGS. 6 and 7, in a direction perpendicular to the display substrate, the drive circuit layer may include a semiconductor layer, a first conductive layer, a second conductive layer, a third conductive layer, and a fourth conductive layer sequentially disposed on a base substrate 101. A first insulation layer 201 may be disposed between the semiconductor layer and the first conductive layer, a second insulation layer 202 may be disposed between the first conductive layer and the second conductive layer, a third insulation layer 203 may be disposed between the second conductive layer and the third conductive layer, and a fourth insulation layer 204 may be disposed between the third conductive layer and the fourth conductive layer. In some examples, the first insulation layer 201, the second insulation layer 202, and the third insulation layer 203 may be inorganic insulation layers, and the fifth insulation layer 204 may be an organic insulation layer. However, the embodiment is not limited thereto. In other examples, a buffer layer may be disposed between the base substrate 101 and the semiconductor layer. In other examples, a passivation layer located at a side of the fourth insulation layer close to the base substrate may also be disposed between the third conductive layer and the fourth conductive layer.

In some examples, as shown in FIG. 6, at least one pixel circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, a seventh transistor T7 as a second initialization transistor, an eighth transistor T8 as a second reference transistor, a ninth transistor T9 as a first reference transistor, a first capacitor, and a second capacitor.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some examples, taking three circuit units (i.e., a first circuit unit, a second circuit unit, and a third circuit unit) in an n-th unit row as an example, the preparation process of the display substrate of the present embodiment may include following operations.

(1-1) A semiconductor layer is formed. In some examples, a semiconductor thin film is deposited on the base substrate, and the semiconductor thin film is patterned through a patterning process to form a semiconductor layer, as shown in FIG. 8. FIG. 8 is a schematic diagram of the display substrate after the semiconductor layer is formed in FIG. 6.

In some examples, the semiconductor layer of each circuit unit in the display substrate may include at least a first active layer 11 of the first transistor T1, a second active layer 12 of the second transistor T2, a third active layer 13 of the third transistor T3, a fourth active layer 14 of the fourth transistor T4, a fifth active layer 15 of the fifth transistor T5, a sixth active layer 16 of the sixth transistor T6, a seventh active layer 17 of the seventh transistor T7, an eighth active layer 18 of the eighth transistor T8, and a ninth active layer 19 of the ninth transistor T9. Wherein, the first active layer 11 to the third active layer 13 and the fifth active layer 15 to the eighth active layer 18 may be of an interconnected integral structure, and the fourth active layer 14 and the ninth active layer 19 may be of an interconnected integral structure.

In some examples, the fourth active layer 14 and the ninth active layer 19 of the n-th unit row may be located at a side of the third active layer 13 close to an (n−1)-th unit row, that is, the fourth active layer 14 and the ninth active layer 19 of a circuit unit may be located at a side of the third active layer 13 of the present circuit unit in an opposite direction of the second direction Y. The first active layer 11, the second active layer 12, and the fifth active layer 15 to the eighth active layer 18 of the n-th unit row may be located at a side of the third active layer 13 close to an (n+1)-th unit row, that is, the first active layer 11, the second active layer 12, and the fifth active layer 15 to the eighth active layer 18 of the circuit unit may be located at a side of the third active layer 13 of the present circuit unit in the second direction Y.

In some examples, the first active layer 11 may be located at a side of the third active layer 13 of the present circuit unit in the second direction Y, the fifth active layer 15 may be located at a side of the first active layer 11 of the present circuit unit in the second direction Y, and the eighth active layer 18 may be located at a side of the fifth active layer 15 of the present circuit unit in the second direction Y. The second active layer 12 may be located at a side of the third active layer 13 of the present circuit unit in the second direction Y, the sixth active layer 16 may be located at a side of the second active layer 12 of the present circuit unit in the second direction Y, and the seventh active layer 17 may be located at a side of the sixth active layer 16 of the present circuit unit in the second direction Y.

In some examples, the first active layer 11, the fourth active layer 14, the fifth active layer 15, and the eighth active layer 18 may be located at one side of the present circuit unit in the first direction X (e.g., a side in an opposite direction of the first direction X), and the second active layer 12, the sixth active layer 16, the seventh active layer 17, and the ninth active layer 19 may be located at the other side of the present circuit unit in the first direction X (e.g., a side in the first direction X).

In some examples, the first active layer 11 may have a substantially stepped shape, the second active layer 12 may have a substantially “L” shape, the third active layer 13 may have a substantially “C” shape, the fourth active layer 14 and the ninth active layer 19 may have a substantially “n” shape, and the fifth active layer 15, the sixth active layer 16, the seventh active layer 17, and the eighth active layer 18 may have a substantially “I” shape.

In some examples, an active layer of each transistor may include a first region, a second region, and a channel region located between the first region and the second region. In some examples, a second region 112 of the first active layer 11 and a first region 121 of the second active layer 12 may be connected with each other, and the second region 112 of the first active layer 11 may serve as the first region 121 of the second active layer 12. A first region 131 of the third active layer 13, a second region 152 of the fifth active layer 15, and a second region 182 of the eighth active layer 18 may be connected with each other, and the first region 131 of the third active layer 13 may simultaneously serve as the second region 152 of the fifth active layer 15 and the second region 182 of the eighth active layer 18, forming a second node N2 of the pixel circuit. A second region 122 of the second active layer 12, a second region 132 of the third active layer 13, and a first region 161 of the sixth active layer 16 may be connected with each other, and the second region 132 of the third active layer 13 may simultaneously serve as the second region 122 of the second active layer 12 and the first region 161 of the sixth active layer 16, forming a third node N3 of the pixel circuit. A second region 142 of the fourth active layer 14 and a second region 192 of the ninth active layer 19 may be connected with each other, and the second region 142 of the fourth active layer 14 may serve as the second region 192 of the ninth active layer 19. A second region 162 of the sixth active layer 16 and a second region 172 of the seventh active layer 17 may be connected with each other, and the second region 162 of the sixth active layer 16 may serve as the second region 172 of the seventh active layer 17, forming a fourth node N4 of the pixel circuit. A first region 111 of the first active layer 11, a first region 141 of the fourth active layer 14, a first region 151 of the fifth active layer 15, and a first region 181 of the seventh active layer 18 are disposed separately. The first region 111 of the first active layer 11 may be located at a side of a channel region of the first active layer 11 close to a channel region of the fifth active layer 15. At least a portion of the first region 111 of the first active layer 11 may be located at a side of the first region 151 of the fifth active layer 15 in the first direction X. The first region 141 of the fourth active layer 14 may be located at a side of a channel region of the fourth active layer 14 close to the third active layer 13, and the first region 191 of the ninth active layer 19 may be located at a side of the channel region of the ninth active layer 19 close to the third active layer 13.

In some examples, in at least one unit row, semiconductor layers in circuit units adjacent in the first direction X may be connected with each other. For example, a semiconductor layer of a first circuit unit of the n-th unit row may be connected with a semiconductor layer of a second circuit unit of the n-th unit row, and the semiconductor layer of the second circuit unit of the n-th unit row may be connected with a semiconductor layer of a third circuit unit of the n-th unit row. In the n-th unit row, semiconductor layers of circuit units adjacent in the first direction X may be connected through a first active connection line 10 and a second active connection line 20. For example, first regions 191 of ninth active layers 19 of ninth transistors T9 of circuit units adjacent in the first direction X may be connected with each other through the first active connection line 10, and first regions 171 of seventh active layers 17 of seventh transistors T7 may be connected with each other through the second active connection line 20. The first active connection line 10 and the second active connection line 20 may extend at least along the first direction X. The first active connection line 10 may be located at a side of the fourth active layer 14 close to the third active layer 13, and the second active connection line 20 may be located at a side of the eighth active layer 18 away from the fifth active layer 15.

In some examples, a shape of the first active connection line 10 may be a polygonal line shape in which a main body portion extends along the first direction X. The first active connection line 10 and ninth active layers of a plurality of circuit units may be of an interconnected integral structure. Since first regions 191 of the ninth active layers 19 are connected with a first reference signal line formed subsequently, the first active connection line 10 may be multiplexed as the first reference signal line extending along the first direction X, which may not only ensure that first regions 191 of a plurality of ninth active layers 19 in one unit row have a same potential, but also reduce a voltage drop of a first reference signal, which is beneficial to improve uniformity of the base substrate, avoid poor display of the display substrate, and may ensure a display effect of the display substrate.

In some examples, a shape of the second active connection line 20 may be a straight line shape in which a main body portion extends along the first direction X. The second active connection line 20 and seventh active layers of a plurality of circuit units may be of an interconnected integral structure. Since first regions of the seventh active layers 17 are connected with a second initial signal line 171 formed subsequently, the second active connection line 20 may be multiplexed as the second initial signal line extending along the first direction X, which may not only ensure that first regions 171 of a plurality of seventh active layers 17 in one unit row have a same potential, but also reduce a voltage drop of the second initial signal, which is beneficial to improve the uniformity of the base substrate, avoid the poor display of the display substrate, and may ensure the display effect of the display substrate.

In some examples, edges, close to each other, of two first active connection lines 10 adjacent in the first direction X and an edge of the first region 191 of the ninth active layer 19 may form a first groove K1. The first groove K1 may be configured to accommodate a first protrusion of a second electrode plate of the second capacitor, which is beneficial to increase setting space of the second capacitor.

In some examples, in at least one unit column, semiconductor layers in circuit units adjacent in the second direction Y may be spaced from each other. For example, a semiconductor layer of a first circuit unit of the (n−1)-th unit row may not be connected with a semiconductor layer of a first circuit unit of the n-th unit row, and the semiconductor layer of the first circuit unit of the n-th unit row may not be connected with a semiconductor layer of a first circuit unit of the (n+1)-th unit row.

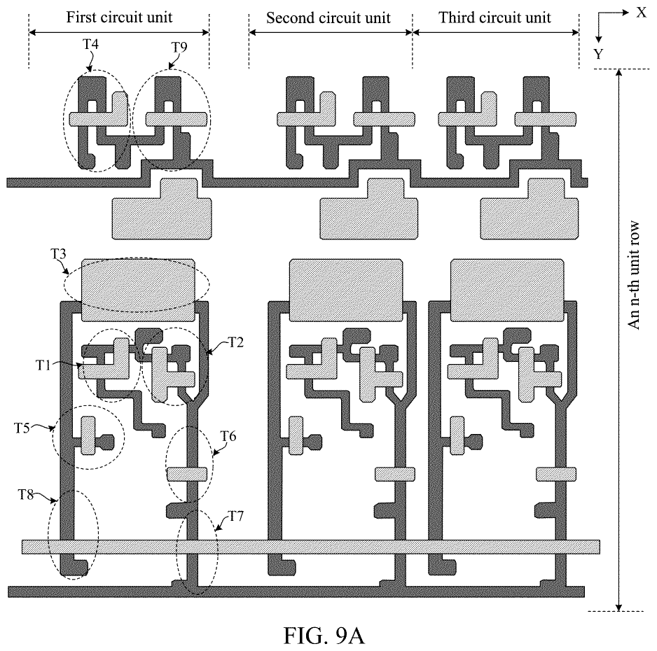

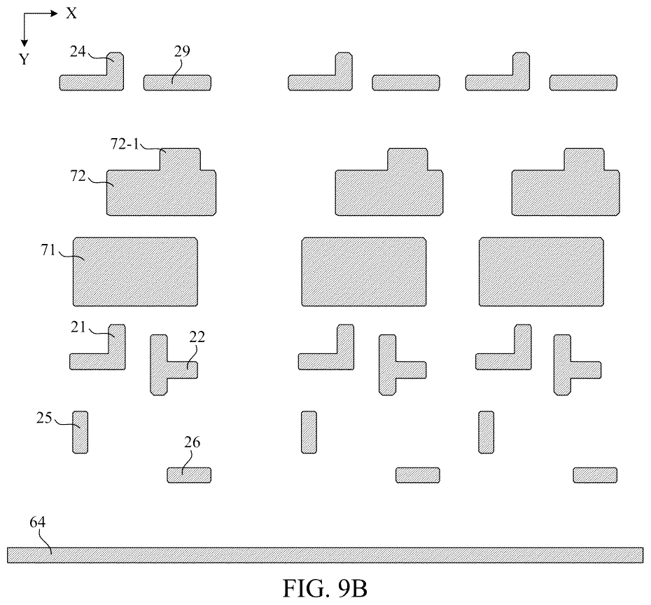

(1-2) A first conductive layer is formed. In some examples, a first insulation thin film and a first conductive thin film are sequentially deposited on the base substrate on which the aforementioned pattern is formed, and the first conductive thin film is patterned through a patterning process to form a first insulation layer covering the semiconductor layer and a first conductive layer disposed on the first insulation layer, as shown in FIGS. 9A and 9B. FIG. 9A is a schematic diagram of the display substrate after the first conductive layer is formed in FIG. 6. FIG. 9B is a schematic diagram of the first conductive layer in FIG. 9A. In some examples, the first conductive layer may be referred to as a first gate metal (GATE1) layer.

In some examples, the first conductive layer of each circuit unit in the display substrate may include at least a first gate electrode 21 of the first transistor T1, a second gate electrode 22 of the second transistor T2, a fourth gate electrode 24 of the fourth transistor T4, a fifth gate electrode 25 of the fifth transistor T5, a sixth gate electrode 26 of the sixth transistor T6, a ninth gate electrode 29 of the ninth transistor T9, a fourth scan signal line 64, a first electrode plate 71 of the first capacitor, and a second electrode plate 72 of the second capacitor.

In some examples, the first gate electrode 21 may have a substantially “L” shape, the first gate electrode 21 may be located at a side of the first electrode plate 71 of the first capacitor in the second direction Y, and a region where the first gate electrode 21 is overlapped with the first active layer may serve as a gate electrode of a first transistor T1 with a double-gate structure.

In some examples, the second gate electrode 22 may have a substantially “T” shape, the second gate electrode 22 may be located at a side of the first electrode plate 71 of the first capacitor in the second direction Y, and a region where the second gate electrode 22 is overlapped with the second active layer may serve as a gate electrode of a second transistor T2 with a double-gate structure.

In some examples, the fourth gate electrode 24 may have a substantially “L” shape, the fourth gate electrode 24 may be located at a side of the second electrode plate 72 of the second capacitor in an opposite direction of the second direction Y, and a region where the fourth gate electrode 24 is overlapped with the fourth active layer may serve as a gate electrode of a fourth transistor T4 with a double-gate structure.

In some examples, the fifth gate electrode 25 may have a substantially strip shape extending along the second direction Y, the fifth gate electrode 25 may be located at a side of the first gate electrode 21 in the second direction Y, and a region where the fifth gate electrode 25 is overlapped with the fifth active layer may serve as a gate electrode of the fifth transistor T5.

In some examples, the sixth gate electrode 26 may have a substantially strip shape extending along the first direction X, the sixth gate electrode 26 may be located at a side of the second gate electrode 22 in the second direction Y, and a region where the sixth gate electrode 26 is overlapped with the sixth active layer may serve as a gate electrode of the sixth transistor T6.

In some examples, the ninth gate electrode 29 may have a substantially strip shape extending along the first direction X, the ninth gate electrode 29 may be located at a side of the second electrode plate 72 of the second capacitor in the opposite direction of the second direction Y, and a region where the ninth gate electrode 29 is overlapped with the ninth active layer may serve as a gate electrode of a ninth transistor T9 with a double-gate structure.

In some examples, the fourth scan signal line 64 may have a straight line shape in which a main body portion extends along the first direction X, and the fourth scan signal line 64 may be located at a side of the fifth gate electrode 25 and the sixth gate electrode 26 in the second direction Y. A region where the fourth scan signal line 64 is overlapped with the seventh active layer may serve as a gate electrode of the fourth transistor T7, and a region where the fourth scan signal line 64 is overlapped with the eighth active layer may serve as a gate electrode of the seventh transistor T8.

In some examples, the first electrode plate 71 of the first capacitor may have a rectangular shape, corners of the rectangular shape may be provided with chamfers, an orthographic projection of the first electrode plate 71 on the base substrate may be at least partially overlapped with an orthographic projection of the third active layer of the third transistor T3 on the base substrate, and the first electrode plate 71 may simultaneously serve as a lower electrode plate of the first capacitor and a gate electrode of the third transistor T3.

In some examples, the second electrode plate 72 of the second capacitor may have a rectangular shape, corners of the rectangular shape may be provided with chamfers, the second electrode plate 72 may be located at a side of the first electrode plate 71 in the opposite direction of the second direction Y, and at a side of the fourth gate electrode 24 and the ninth gate electrode 29 in the second direction Y, that is, in the second direction Y, the second electrode plate 72 may be located between the first electrode plate 71 and the fourth gate electrode 24 (or the ninth gate electrode 29), and an orthographic projection of the second electrode plate 72 on the base substrate may be not overlapped with an orthographic projection of the semiconductor layer on the base substrate. The second electrode plate 72 may serve as a lower electrode plate of the second capacitor.

In some examples, a first protrusion 72-1 may be disposed at a side of the second electrode plate 72 close to the ninth gate electrode 29, and the first protrusion 72-1 may have a substantially rectangular shape. A first end of the first protrusion 72-1 is connected with the second electrode plate 72, and a second end of the first protrusion 72-1 extends toward a direction to the ninth gate electrode 29 and into the first groove K1 formed by the first active connection line 10. The second electrode plate 72 and the first protrusion 72-1 may be of an interconnected integral structure. In this example, by providing the first groove K1 formed by the first active connection line 10 and the first protrusion 72-1 of the second electrode plate 72, an area of the second electrode plate 72 may be effectively increased, thereby effectively increasing a capacitance of the second capacitor.

In some examples, a first side edge (e.g., a right side edge) of the first electrode plate 71 in the first direction X and a first side edge (e.g., a right side edge) of the second electrode plate 72 in the first direction X may be misaligned in the second direction Y, for example, the right side edge of the second electrode plate 72 in the first direction X may be located at a side of the right side edge of the first electrode plate 71 in the first direction X. A second side edge (e.g., a left side edge) of the first electrode plate 71 in the first direction X and a second side edge (e.g., a left side edge) of the second electrode plate 72 in the first direction X may be misaligned, for example, the left side edge of the second electrode plate 72 in the first direction X may be located at a side of the left side edge of the first electrode plate 71 in the first direction X. The right side edge of the second electrode plate 72 in the first direction X may be located at a side of a right edge of the first protrusion 72-1 in the first direction X. A shape of an integral structure into which the second electrode plate 72 and the first protrusion 72-1 are interconnected may have a substantially “T” shape.

In some examples, areas of orthographic projections of the first electrode plate 71 and the second electrode plate 72 on the base substrate may be the same or may be different. For example, an area of an orthographic projection of the second electrode plate 72 on the base substrate may be smaller than an area of an orthographic projection of the first electrode plate 71 on the base substrate.

In some examples, after a pattern of the first conductive layer is formed, a conductive processing may be performed on the semiconductor layer by using the first conductive layer as a shield, the semiconductor layer in a region shielded by the first conductive layer forms channel regions of the first transistor T1 to the ninth transistor T9, and the semiconductor layer in a region not shielded by the first conductive layer is made to be conductive. That is, first regions and second regions of the first active layer to the ninth active layer, the first active connection line 10, and the second active connection line 20 may all be made to be conductive.

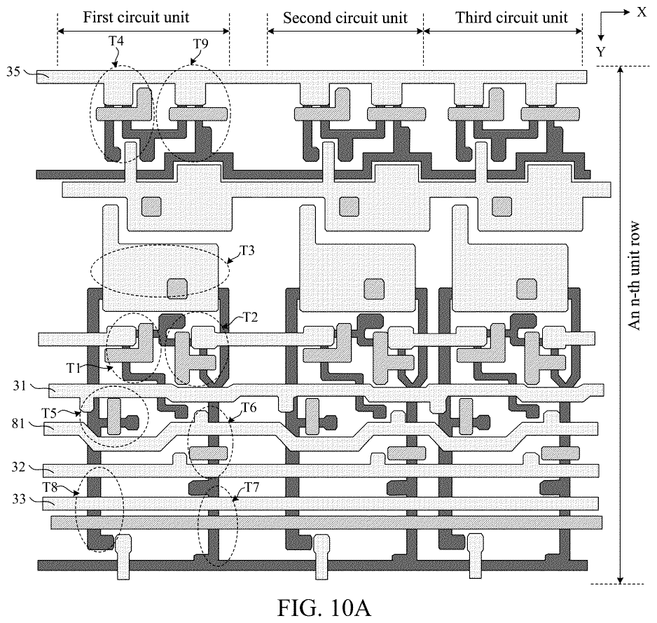

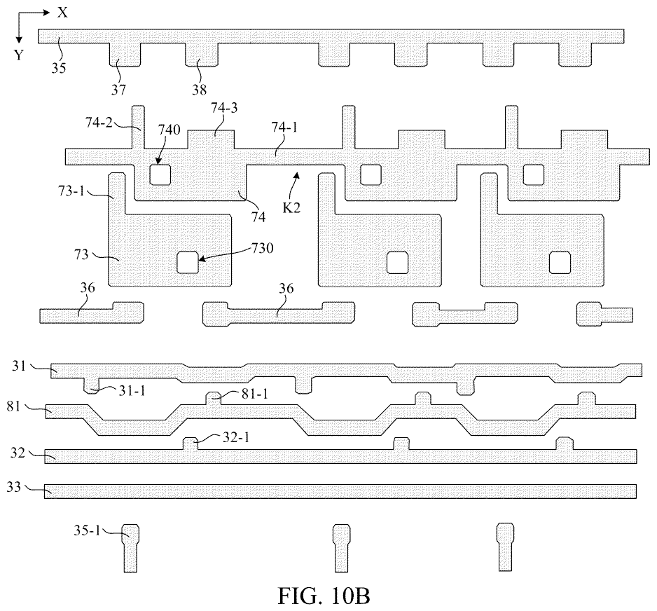

(1-3) A second conductive layer is formed. In some examples, a second insulation thin film and a second conductive thin film are sequentially deposited on the base substrate on which the aforementioned patterns are formed, and the second conductive thin film is patterned through a patterning process to form a second insulation layer covering the first conductive layer and the second conductive layer disposed on the second insulation layer, as shown FIGS. 10A and 10B. FIG. 10A is a schematic diagram of the display substrate after the second conductive layer is formed in FIG. 10. FIG. 10B is a schematic diagram of the second conductive layer in FIG. 10A. In some examples, the second conductive layer may be referred to as a second gate metal (GATE2) layer.

In some examples, the second conductive layer of each circuit unit in the display substrate may include at least a first light emitting signal line 31, a second light emitting signal line 32, a repair line 33, a second reference signal line 35, a first initial signal line 81, a first shield electrode 36, a second shield electrode 37, a third shield electrode 38, a third electrode plate 73 of the first capacitor, and a fourth electrode plate 74 of the second capacitor.

In some examples, shapes of the first light emitting signal line 31 and the first initial signal line 81 may be a polygonal line shape in which a main body portion extends along the first direction X, and shapes of the second light emitting signal line 32, the repair line 33, and the second reference signal line 35 may be a straight line shape in which a main body portion extends along the first direction X. The first light emitting signal line 31, the second light emitting signal line 32, the first initial signal line 81, and the repair line 33 may be located between the first gate electrode 21 and the fourth scan signal line 64, and the second reference signal line 35 may be located at a side of the fourth gate electrode 24 in the opposite direction of the second direction Y.

In some examples, the first light emitting signal line 31 may be located at a side of the first gate electrode 21 of the present circuit unit in the second direction Y, the first initial signal line 81 may be located at a side of the first light emitting signal line 31 in the second direction Y, the second light emitting signal line 32 may be located at a side of the first initial signal line 81 in the second direction Y, and the repair line 33 may be located at a side of the second light emitting signal line 32 in the second direction Y. The first initial signal line 81 may be located between the first light emitting signal line 31 and the second light emitting signal line 32, and the second light emitting signal line 32 may be located between the first initial signal line 81 and the repair line 33. An orthographic projection of the first light emitting signal line 31 on the base substrate is partially overlapped with an orthographic projection of a first region of a first active layer of the first transistor on the base substrate.

In some examples, a first light emitting connection block 31-1 may be disposed at a side of the first light emitting signal line 31 close to the first initial signal line 81, the first light emitting connection block 31-1 may be disposed in each circuit unit, a first end of the first light emitting connection block 31-1 is connected with the first light emitting signal line 31, a second end of the first light emitting connection block 31-1 extends toward a direction to the first initial signal line 81, and the first light emitting connection block 31-1 may be configured to be connected with the fifth gate electrode 25 through a seventh connection electrode formed subsequently. In some examples, the first light emitting signal line 31 and a plurality of first light emitting connection blocks 31-1 may be of an interconnected integral structure.

In some examples, a second light emitting connection block 32-1 may be disposed at a side of the second light emitting signal line 32 close to the first initial signal line 81, the second light emitting connection block 32-1 may be disposed in each circuit unit, a first end of the second light emitting connection block 32-1 is connected with the second light emitting signal line 32, a second end of the second light emitting connection block 32-1 extends toward a direction to the first initial signal line 81, and the second light emitting connection block 32-1 may be configured to be connected with the sixth gate electrode 26 through an eighth connection electrode formed subsequently. In some examples, the second light emitting signal line 32 and a plurality of second light emitting connection blocks 32-1 may be of an interconnected integral structure.

In some examples, a second reference connection block 35-1 may be disposed at a side of the second reference signal line 35 of the n-th unit row away from the second electrode plate 72 of the n-th unit row, the second reference connection block 35-1 may be disposed in each circuit unit, a first end of the second reference connection block 35-1 is connected with the second reference signal line 35, and a second end of the second reference connection block 35-1 may extend toward a direction away from the second electrode plate 72, that is, toward a direction to the (n−1)-th unit row. In some examples, the second reference connection block 35-1 of the second reference signal line 35 in the n-th unit row may be configured to be connected with a first region of an eighth active layer in the (n−1)-th unit row through a sixth connection electrode formed subsequently to provide a second reference signal to a first electrode of an eighth transistor T8 in the (n−1)-th unit row. In some examples, the second reference signal line 35 and a plurality of second reference connection blocks 35-1 may be of an interconnected integral structure.

In some examples, a first initial connection block 81-1 may be disposed at a side of the first initial signal line 81 close to the first light emitting signal line 31, the first initial connection block 81-1 may be disposed in each circuit unit, a first end of the first initial connection block 81-1 is connected with the first initial signal line 81, a second end of the first initial connection block 81-1 extends toward a direction to the first light emitting signal line 31, and the first initial connection block 81-1 may be configured to be connected with the first region of the first active layer of the first transistor through a ninth connection electrode formed subsequently to provide a first initial signal to a first electrode of the first transistor T1. In some examples, the first initial signal line 81 and a plurality of first initial connection blocks 81-1 may be of an interconnected integral structure.

In some examples, a contour shape of the third electrode plate 73 of the first capacitor may be a rectangular shape, corners of the rectangular shape may be provided with chamfers, the third electrode plate 73 may be located between the first light emitting signal line 31 and the second reference signal line 35 of the present circuit unit, an orthographic projection of the third electrode plate 73 on the base substrate may be at least partially overlapped with an orthographic projection of the first electrode plate 71 on the base substrate, the third electrode plate 73 may serve as an upper electrode plate of the first capacitor (i.e., a second end of the first capacitor C1), and the first electrode plate 71 and the third electrode plate 73 may form the first capacitor C1 of the pixel circuit.

In some examples, a contour shape of the fourth electrode plate 74 of the second capacitor may be a rectangular shape, corners of the rectangular shape may be provided with chamfers, the fourth electrode plate 74 may be located between the second reference signal line 35 and the third electrode plate 73 of the present circuit unit, an orthographic projection of the fourth electrode plate 74 on the base substrate may be at least partially overlapped with an orthographic projection of the second electrode plate 72 on the base substrate, the fourth electrode plate 74 may serve as an upper electrode plate of the second capacitor (i.e., a first end of the second capacitor C2), and the second electrode plate 72 and the fourth electrode plate 74 may form the second capacitor C2 of the pixel circuit.

In some examples, areas of orthographic projections of the third electrode plate 73 and the fourth electrode plate 74 on the base substrate may be the same or may be different. For example, an area of an orthographic projection of the fourth electrode plate 74 on the base substrate may be smaller than an area of an orthographic projection of the third electrode plate 73 on the base substrate.

In some examples, a second electrode plate connection line 73-1 may be disposed at a side of the third electrode plate 73 close to the fourth electrode plate 74, a first end of the second electrode plate connection line 73-1 is connected with the third electrode plate 73, and a second end of the second electrode plate connection line 73-1 extends toward a direction to the second reference signal line 35. The second electrode plate connection line 73-1 may be configured to be connected with the second region of the fourth active layer (also the second region of the ninth active layer) and the second electrode plate 72 through a third connection electrode formed subsequently, so that the second region of the fourth transistor T4, the second region of the ninth transistor T9, the third electrode plate 73, and the second electrode plate 72 may have a same potential.

In some examples, a first electrode plate connection line 74-1 may be disposed at a side of the fourth electrode plate 74 in the first direction X or in an opposite direction of the first direction X, a first end of the first electrode plate connection line 74-1 is connected with the fourth electrode plate 74 of the present circuit unit, and a second end of the first electrode plate connection line 74-1 may extend along the first direction X or the opposite direction of the first direction X and then be connected with a fourth electrode plate 74 of an adjacent circuit unit, so that fourth electrode plates 74 of adjacent circuit units in one unit row may be connected with each other. In some examples, a plurality of fourth electrode plates 74 and a plurality of first electrode plate connection lines 74-1 may be of an interconnected integral structure. For example, a length of the first electrode plate connection line 74-1 in the second direction Y may be smaller than a length of the fourth electrode plate 74 in the second direction Y. Since the fourth electrode plate 74 is connected with a first reference signal line formed subsequently, fourth electrode plates 74 of an integral structure of a plurality of circuit units may be multiplexed as a transverse first reference signal line extending along the first direction X, which may not only ensure that a plurality of fourth electrode plates 74 in one unit row have a same potential, but also reduce a voltage drop of a first reference signal, which is beneficial to improve uniformity of the display substrate, avoid poor display of the display substrate, and ensure a display effect of the display substrate.

In some examples, edges, close to each other, of two fourth electrode plates 74 adjacent in the first direction X and an edge of the first electrode plate connection line 74-1 form a second groove K2, and the second groove K2 may be configured to accommodate the second electrode plate connection line 73-1. The second electrode plate connection line 73-1 of the third electrode plate 73, within the second groove K2, may extend toward a direction to the second reference signal line 35, so that a twelfth via formed subsequently may move up as much as possible and be as close as possible to the second region of the fourth active layer (that is, the second region of the ninth active layer). The twelfth via may be configured such that a third connection electrode form subsequently may be connected with the second electrode plate connection line 73-1 through the via, the third connection electrode may be connected with the second region of the fourth active layer (that is, the second region of the ninth active layer) simultaneously through the via, and also be connected with the second electrode plate 72 through the via, so that a second electrode of the fourth transistor T4, a second electrode of the ninth transistor T9, the third electrode plate 73, and the second electrode plate 72 may have a same potential.

In some examples, a first opening 730 may be disposed on a third electrode plate 73 of each circuit unit, the first opening 730 may be located in a middle of the third electrode plate 73, and the first opening 730 may be rectangular, so that the third electrode plate 73 forms an annular structure. The first opening 730 may expose the second insulation layer covering the first electrode plate 71, and an orthographic projection of the first electrode plate 71 on the base substrate may contain an orthographic projection of the first opening 730 on the base substrate. In some examples, the first opening 730 may be configured to accommodate a tenth via formed subsequently, and the tenth via may be located within the first opening 730 and expose a portion of a surface of the first electrode plate 71 to enable a first connection electrode formed subsequently to be connected with the first electrode plate 71.

In some examples, a second opening 740 may be disposed on a fourth electrode plate 74 of each circuit unit, the second opening 740 may be located in a middle of the fourth electrode plate 74, and the second opening 740 may be rectangular, so that the fourth electrode plate 74 forms an annular structure. The second opening 740 may expose the second insulation layer covering the second electrode plate 72, and an orthographic projection of the second electrode plate 72 on the base substrate may contain an orthographic projection of the second opening 740 on the base substrate. In some examples, the second opening 740 may be configured to accommodate an eleventh via formed subsequently, and the eleventh via may be located within the second opening 740 and expose a portion of a surface of the second electrode plate 72 to enable a third connection electrode formed subsequently to be connected with the second electrode plate 72. In some examples, the second opening 740 and the first opening 730 may not be aligned in the second direction Y.

In some examples, a second protrusion 74-2 may be disposed at a side of the fourth electrode plate 74 close to the second reference signal line 35, and the second protrusion 74-2 may be disposed in each circuit unit. The second protrusion 74-2 may be located at a side of the second opening 740 in the opposite direction of the second direction Y. A first end of the second protrusion 74-2 is connected with the fourth electrode plate 74, and a second end of the second protrusion 74-2 extends toward a direction to the second reference signal line 35. An orthographic projection of the second protrusion 74-2 on the base substrate may be located between a first region and a second region of the fourth active layer of the present circuit unit. The second protrusion 74-2 of the present example may be configured to shield an influence of a data voltage jump on a fifth node, thereby preventing signal crosstalk, preventing the data voltage jump from affecting a normal operation of the pixel circuit, and improving a display effect. In some examples, the fourth electrode plate 74 and the second protrusion 74-2 may be of an interconnected integral structure.

In some examples, a third protrusion 74-3 may be disposed at a side of the fourth electrode plate 74 close to the second reference signal line 35. The third protrusion 74-3 may be disposed in each circuit unit. The second protrusion 74-2 and the third protrusion 74-3 may be adjacent in the first direction X. For example, the third protrusion 74-3 may be located at a side of the second protrusion 74-2 in the first direction X. A first end of the third protrusion 74-3 is connected with the fourth electrode plate 74, and a second end of the third protrusion 74-3 extends toward a direction to the second reference signal line 35 and into the first groove K1. An orthographic projection of the third protrusion 74-3 on the base substrate may be at least partially overlapped with an orthographic projection of the first protrusion 72-1 of the second electrode plate 72 on the base substrate, for example, they may be overlapped with each other. For example, a length of the second protrusion 74-2 in the second direction Y may be greater than a length of the third protrusion 74-3 in the second direction Y, and a length of the second protrusion 74-2 in the first direction X may be less than a length of the third protrusion 74-3 in the first direction X. In this example, by setting the third protrusion 74-3 to be at least partially overlapped with the first protrusion 72-1, an area of the second capacitor may be increased and a total capacity of the second capacitor may be effectively increased, thereby improving working performance of the pixel circuit and improving the display effect. In some examples, the fourth electrode plate 74 and the third protrusion 74-3 may be of an interconnected integral structure.

In some examples, a shape of the first shield electrode 36 may be substantially a strip shape extending along the first direction X, the first shield electrode 36 may be located at a side of the third electrode plate 73 close to the first light emitting signal line 31, and the first shield electrode 36 may be disposed in each circuit unit. The first shield electrode 36 with the strip shape may include a first shield end located within the present circuit unit and a second shield end extending into an adjacent circuit unit along an opposite direction of the first direction X. An orthographic projection of the first shield end on the base substrate is at least partially overlapped with an orthographic projection of a first active layer between two gate electrodes of first transistors T1 in the present circuit unit on the base substrate, and an orthographic projection of the second shield end on the base substrate is at least partially overlapped with an orthographic projection of a second active layer between two gate electrodes of second transistors T2 in the adjacent circuit unit on the base substrate. In some examples, the first shield electrode 36 may be configured to shield an influence of a data voltage jump on a first transistor T1 and a second transistor T2 to avoid the data voltage jump affecting the normal operation of the pixel circuit and improve the display effect.

In some examples, an orthographic projection of a first shield end of the first shield electrode 36 in the present circuit unit on the base substrate is partially overlapped with an orthographic projection of a first region of the third active layer (also the second region of the fifth active layer and the second region of the eighth active layer) of the third transistor T3 in the present circuit unit on the base substrate. Since the first region of the third active layer 13 (also the second region of the fifth active layer and the second region of the eighth active layer) is a conductor layer subjected to a conductive processing, and the first shield electrode 36 is also a conductor layer, the first region of the third active layer 13 (also the second region of the fifth active layer and the second region of the eighth active layer) in one circuit unit and the first shield end of the first shield electrode 36 of the present circuit unit may form a first voltage stabilizing capacitor. The first region of the third active layer 13 (also the second region of the fifth active layer and the second region of the eighth active layer) of the circuit unit may serve as a lower electrode plate of the first voltage stabilizing capacitor, and the first shield end of the first shield electrode 36 may serve as an upper electrode plate of the first voltage stabilizing capacitor. Since the first shield electrode 36 may be connected with the first power supply connection line to receive a stable first power supply signal with constant voltage, the first voltage stabilizing capacitor may be configured to stabilize a potential of a second node N2, which may prevent signal crosstalk and avoid an influence of a data voltage jump on the second node N2, thereby ensuring the normal operation of the pixel circuit and improving the display effect.

In some examples, an orthographic projection of the second shield end of the first shield electrode 36 in the present circuit unit on the base substrate is partially overlapped with an orthographic projection of a second region of a third active layer (also a first region of a sixth active layer and a second region of a second active layer) of a third transistor T3 in an adjacent circuit unit on the base substrate. Since a second region of a third active layer 13 (also a first region of a sixth active layer and a second region of a second active layer) is a conductor layer subjected to a conductive processing, and the first shield electrode 36 is also a conductor layer, a second region of a third active layer 13 (also the first region of the sixth active layer and the second region of the second active layer) in one circuit unit and a second shield end of a first shield electrode 36 in an adjacent circuit unit may form a voltage stabilizing second capacitor. The second region of the third active layer 13 (also the first region of the sixth active layer and the second region of the second active layer) of the circuit unit may serve as a lower electrode plate of the second voltage stabilizing capacitor, and the second shield end of the first shield electrode 36 may serve as an upper electrode plate of the second voltage stabilizing capacitor. Since the first shield electrode 36 may be connected with the first power supply connection line to receive a stable first power supply signal with constant voltage, the second voltage stabilizing capacitor may be configured to stabilize a potential of the third node N3, which may prevent signal crosstalk and avoid an influence of a data voltage jump on the third node N3, thereby ensuring the normal operation of the pixel circuit and improving the display effect.

In some examples, the second shield electrode 37 and the third shield electrode 38 may have a rectangular shape, may be located at a side of the second reference signal line 35 close to the fourth electrode plate 74, and may be disposed in each circuit unit. First ends of the second shield electrode 37 and the third shield electrode 38 are connected with the second reference signal line 35, and second ends of the second shield electrode 37 and the third shield electrode may extend toward a direction to the fourth electrode plate 74. An orthographic projection of the second shield electrode 37 on the base substrate may be at least partially overlapped with an orthographic projection of a fourth active layer between two gate electrodes of fourth transistors T4 in the present circuit unit on the base substrate, and an orthographic projection of the third shield electrode 38 on the base substrate may be at least partially overlapped with an orthographic projection of a ninth active layer between two gate electrodes of ninth transistors T9 in the present circuit unit on the base substrate. In some examples, the second shield electrode 37 may be configured to shield an influence of a data voltage jump on a fourth transistor T4, and the third shield electrode 38 may be configured to shield an influence of the data voltage jump on a ninth transistor T9, so as to avoid the data voltage jump affecting the normal operation of the pixel circuit and improve the display effect.

In some examples, the repair line 33 may be located at a side of the second light emitting control line 32 away from the first light emitting control line 31. For example, the repair line 33 may be configured such that when the display substrate has a defective bright spot, a signal is input to an anode of a sub-pixel with the defective bright spot through the repair line 33 and the defective bright spot is repaired as a dark spot.

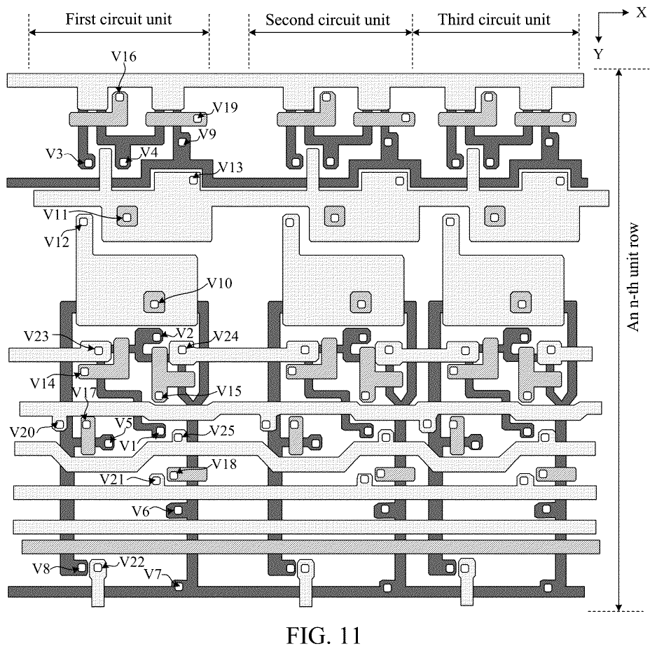

(1-4) A third insulation layer is formed. In some examples, a third insulation thin film is deposited on the base substrate on which the aforementioned patterns are formed, and the third insulation thin film is patterned through a patterning process to form a third insulation layer, and a plurality of vias are disposed in the third insulation layer of each circuit unit, as shown FIG. 11. FIG. 11 is a schematic diagram of the display substrate after a third insulation layer is formed in FIG. 6.

In some examples, the plurality of vias in each circuit unit in the display substrate may include at least a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, a twenty-third via V23, a twenty-fourth via V24, and a twenty-fifth via V25.

In some examples, an orthographic projection of the first via V1 on the base substrate may be within a range of an orthographic projection of a first region of the first active layer on the base substrate. The third insulation layer, the second insulation layer, and the first insulation layer within the first via V1 may be etched away to expose a portion of a surface of the first region of the first active layer, and the first via V1 may be configured such that a first initial signal line formed subsequently is connected with the first region of the first active layer through the via.

In some examples, an orthographic projection of the second via V2 on the base substrate is within a range of an orthographic projection of a second region of the first active layer (also a first region of the second active layer) on the base substrate. The third insulation layer, the second insulation layer, and the first insulation layer within the second via V2 are etched away to expose a portion of a surface of the second region of the first active layer (also the first region of the second active layer), and the second via V2 may be configured such that a first connection electrode subsequently formed is connected with the second region of the first active layer (also the first region of the second active layer) through the via.

In some examples, an orthographic projection of the third via V3 on the base substrate may be within a range of an orthographic projection of a first region of the fourth active layer on the base substrate. The third insulation layer, the second insulation layer, and the first insulation layer within the third via V3 may be etched away to expose a portion of a surface of the first region of the fourth active layer, and the third via V3 may be configured such that a second connection electrode subsequently formed is connected with the first region of the fourth active layer through the via.

In some examples, an orthographic projection of the fourth via V4 on the base substrate may be within an orthographic projection of a second region of the fourth active layer (also a second region of the ninth active layer) on the base substrate. The third insulation layer, the second insulation layer, and the first insulation layer within the fourth via V4 may be etched away to expose a portion of a surface of the second region of the fourth active layer (also the second region of the ninth active layer), and the fourth via V4 may be configured such that a third connection electrode subsequently formed is connected with the second region of the fourth active layer (also the second region of the ninth active layer) through the via.

In some examples, an orthographic projection of the fifth via V5 on the base substrate may be within a range of an orthographic projection of a first region of the fifth active layer on the base substrate. The third insulation layer, the second insulation layer, and the first insulation layer within the fifth via V5 may be etched away to expose a portion of a surface of the first region of the fifth active layer, and the fifth via V5 may be configured such that a fourth connection electrode subsequently formed is connected with the first region of the fifth active layer through the via.

In some examples, an orthographic projection of the sixth via V6 on the base substrate is within a range of an orthographic projection of a second region of the sixth active layer (also a second region of the seventh active layer) on the base substrate. The third insulation layer, the second insulation layer, and the first insulation layer within the sixth via V6 are etched away to expose a portion of a surface of the second region of the sixth active layer (also the second region of the seventh active layer), and the sixth via V6 is configured such that a fifth connection electrode subsequently formed is connected with the second region of the sixth active layer (also the second region of the seventh active layer) through the via.

In some examples, an orthographic projection of the seventh via V7 on the base substrate may be within a range of an orthographic projection of a first region of the seventh active layer on the base substrate. The third insulation layer, the second insulation layer, and the first insulation layer within the seventh via V7 may be etched away to expose a portion of a surface of the first region of the seventh active layer, and the seventh via V7 may be configured such that a second initial signal line subsequently formed is connected with the first region of the seventh active layer through the via.

In some examples, an orthographic projection of the eighth via V8 on the base substrate is within a range of an orthographic projection of a first region of the eighth active layer on the base substrate. The third insulation layer, the second insulation layer, and the first insulation layer within the eighth via V8 are etched away to expose a portion of a surface of the first region of the eighth active layer, and the eighth via V8 is configured such that a sixth connection electrode subsequently formed is connected with the first region of the first active layer through the via.

In some examples, an orthographic projection of the ninth via V9 on the base substrate may be within a range of an orthographic projection of a first region of the ninth active layer on the base substrate. The third insulation layer, the second insulation layer, and the first insulation layer within the ninth via V9 may be etched away to expose a portion of a surface of the first region of the ninth active layer, and the ninth via V9 may be configured such that a first reference signal line subsequently formed is connected with the first region of the ninth active layer through the via.

In some examples, an orthographic projection of the tenth via V10 on the base substrate may be within a range of an orthographic projection of the first opening 730 of the third electrode plate 73 on the base substrate. The third insulation layer and the second insulation layer within the tenth via V10 may be etched away to expose a portion of a surface of the first electrode plate 71, and the tenth via V10 may be configured such that a first connection electrode subsequently formed is connected with the first electrode plate 71 through the via.

In some examples, an orthographic projection of the eleventh via V11 on the base substrate may be within a range of an orthographic projection of the second opening 740 of the fourth electrode plate 74 on the base substrate. The third insulation layer and the second insulation layer within the eleventh via V11 may be etched away to expose a portion of a surface of the second electrode plate 72, and the eleventh via V11 is configured such that a third connection electrode subsequently formed is connected with the second electrode plate 72 through the via.

In some examples, an orthographic projection of the twelfth via V12 on the base substrate may be within a range of an orthographic projection of the second electrode plate connection line 73-1 of the third electrode plate 73 on the base substrate. The third insulation layer within the twelfth via V12 may be etched away to expose a portion of a surface of the second electrode plate connection line 73-1, and the twelfth via V12 may be configured such that a third connection electrode subsequently formed is connected with the second electrode plate connection line 73-1 through the via.

In some examples, an orthographic projection of the thirteenth via V13 on the base substrate may be within a range of an orthographic projection of the fourth electrode plate 74 on the base substrate. The third insulation layer within the thirteenth via V13 may be etched away to expose a portion of a surface of the fourth electrode plate 74, and the thirteenth via V13 may be configured such that a first reference connection block subsequently formed is connected with the fourth electrode plate 74 through the via.

In some examples, an orthographic projection of the fourteenth via V14 on the base substrate may be within a range of an orthographic projection of the first gate electrode 21 on the base substrate. The third insulation layer and the second insulation layer within the fourteenth via V14 may be etched away to expose a portion of a surface of the first gate electrode 21, and the fourteenth via V14 may be configured such that a first scan signal line subsequently formed is connected with the first gate electrode 21 through the via.

In some examples, an orthographic projection of the fifteenth via V15 on the base substrate may be within a range of an orthographic projection of the second gate electrode 22 on the base substrate. The third insulation layer and the second insulation layer within the fifteenth via V15 may be etched away to expose a portion of a surface of the second gate electrode 22, and the fifteenth via V15 may be configured such that a second scan signal line subsequently formed is connected with the second gate electrode 22 through the via.

In some examples, an orthographic projection of the sixteenth via V16 on the base substrate may be within a range of an orthographic projection of the fourth gate electrode 24 on the base substrate. The third insulation layer and the second insulation layer within the sixteenth via V16 may be etched away to expose a portion of a surface of the fourth gate electrode 24, and the sixteenth via V16 may be configured such that a third scan signal line subsequently formed is connected with the fourth gate electrode 24 through the via.

In some examples, an orthographic projection of the seventeenth via V17 on the base substrate may be within a range of an orthographic projection of the fifth gate electrode 25 on the base substrate. The third insulation layer and the second insulation layer within the seventeenth via V17 may be etched away to expose a portion of a surface of the fifth gate electrode 25, and the seventeenth via V17 may be configured such that a seventh connection electrode subsequently formed is connected with the fifth gate electrode 25 through the via.

In some examples, an orthographic projection of the eighteenth via V18 on the base substrate may be within a range of an orthographic projection of the sixth gate electrode 26 on the base substrate. The third insulation layer and the second insulation layer within the eighteenth via V18 may be etched away to expose a portion of a surface of the sixth gate electrode 26, and the eighteenth via V18 may be configured such that an eighth connection electrode subsequently formed is connected with the sixth gate electrode 26 through the via.

In some examples, an orthographic projection of the nineteenth via V19 on the base substrate may be within a range of an orthographic projection of the ninth gate electrode 29 on the base substrate. The third insulation layer and the second insulation layer within the nineteenth via V19 may be etched away to expose a portion of a surface of the ninth gate electrode 29, and the nineteenth via V19 may be configured such that a fifth scan signal line subsequently formed is connected with the ninth gate electrode 29 through the via.

In some examples, an orthographic projection of the twentieth via V20 on the base substrate may be within a range of an orthographic projection of the first light emitting connection block 31-1 of the first light emitting signal line 31 on the base substrate. The third insulation layer within the twentieth via V20 may be etched away to expose at least part of a surface of the first light emitting connection block 31-1, and the twentieth via V20 may be configured such that a seventh connection electrode subsequently formed is connected with the first light emitting connection block 31-1 through the via.

In some examples, an orthographic projection of the twenty-first via V21 on the base substrate may be within a range of an orthographic projection of the second light emitting connection block 32-1 of the second light emitting signal line 32 on the base substrate. The third insulation layer within the twenty-first via V21 may be etched away to expose at least part of a surface of the second light emitting connection block 32-1, and the twenty-first via V21 may be configured such that an eighth connection electrode subsequently formed is connected with the second light emitting connection block 32-1 through the via.

In some examples, an orthographic projection of the twenty-second via V22 on the base substrate may be within a range of an orthographic projection of the second reference connection block 35-1 of the second reference signal line 35 on the base substrate. The third insulation layer within the twenty-second via V22 is etched away to expose a portion of a surface of the second reference connection block 35-1, and the twenty-second via V22 may be configured such that a sixth connection electrode subsequently formed is connected with the second reference connection block 35-1 through the via.

In some examples, an orthographic projection of the twenty-third via V23 on the base substrate may be located behind a range of an orthographic projection of the first shield electrode 36 of the present circuit unit on the base substrate. The third insulation layer within the twenty-third via V23 may be etched away to expose a portion of a surface of the first shield end of the first shield electrode 36, and the twenty-third via V23 may be configured such that a first power supply connection line subsequently formed is connected with the first shield electrode 36 of the present circuit unit through the via.

In some examples, an orthographic projection of the twenty-fourth via V24 on the base substrate may be located behind a range of an orthographic projection of the first shield electrode 36 of the adjacent circuit unit on the base substrate. The third insulation layer within the twenty-fourth via V24 may be etched away to expose a portion of a surface of the second shield end of the first shield electrode 36 of the adjacent circuit unit, and the twenty-fourth via V24 may be configured such that a first power supply connection line subsequently formed is connected with the first shield electrode 36 of the adjacent circuit unit through the via.

In some examples, an orthographic projection of the twenty-fifth via V25 on the base substrate may be within a range of an orthographic projection of the first initial connection block 81-1 of the first initial signal line 81 on the base substrate. The third insulation layer within the twenty-fifth via V25 may be etched away to expose at least part of a surface of the first initial connection block 81-1, and the twenty-fifth via V25 may be configured such that a ninth connection electrode subsequently formed is connected with the first initial connection block 81-1 through the via.

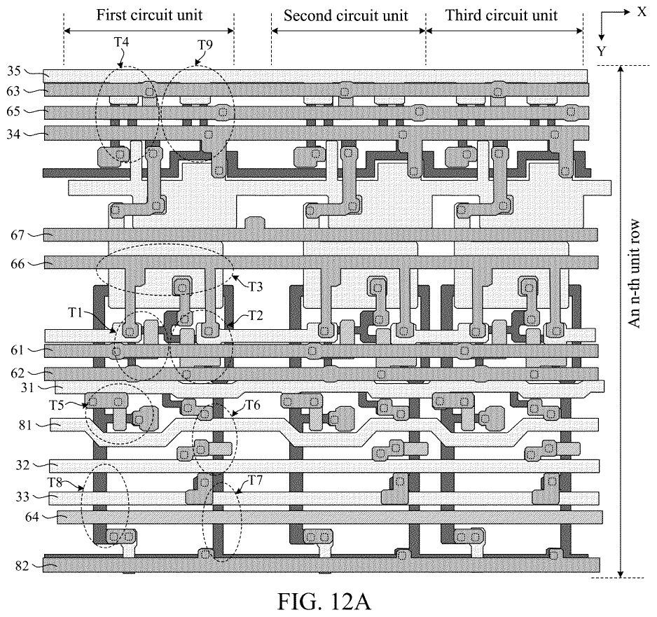

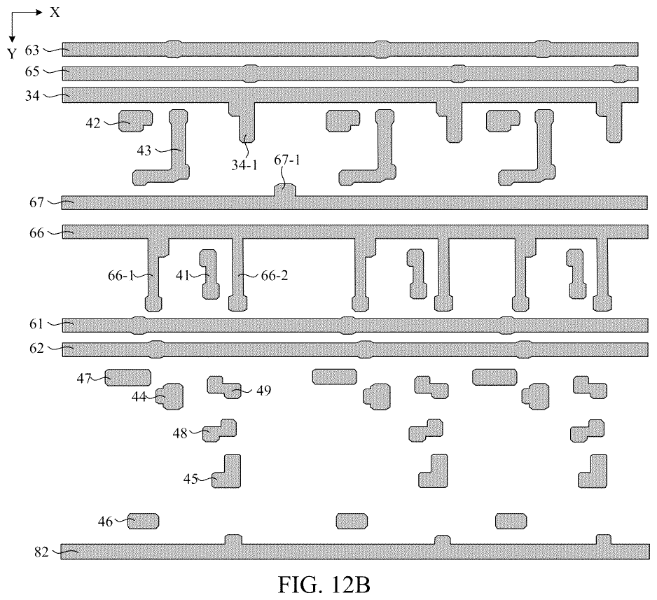

(1-5) A third conductive layer is formed. In some examples, a third conductive thin film is deposited on the base substrate on which the aforementioned patterns are formed, and the third conductive thin film is patterned through a patterning process to form a third conductive layer disposed on the third insulation layer, as shown in FIGS. 12A and 12B. FIG. 12A is a schematic diagram of the display substrate after the third conductive layer is formed in FIG. 6. FIG. 12B is a schematic diagram of the third conductive layer in FIG. 12A. In some examples, the third conductive layer may be referred to as a first source-drain metal (SD1) layer.

In some examples, the third conductive layer of each circuit unit in the display substrate may include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a first scan signal line 61, a second scan signal line 62, a third scan signal line 63, a fifth scan signal line 65, a first power supply connection line 66, a second power supply connection line 67, a second initial signal line 82, and a first reference signal line 34.

In some examples, shapes of the first scan signal line 61, the second scan signal line 62, the third scan signal line 63, the fifth scan signal line 65, the first power supply connection line 66, the second power supply connection line 67, the first initial signal line 81, the second initial signal line 82, and the first reference signal line 34 may be straight line shapes in which main body portions extend along the first direction X. The third scan signal line 63, the fifth scan signal line 65, and the first reference signal line 34 may be located at a side of the fourth electrode plate 74 in the opposite direction of the second direction Y. The first scan signal line 61, the second scan signal line 62, the first initial signal line 81, and the second initial signal line 82 may be located at a side of the third electrode plate 73 in the second direction Y. The second power supply connection line 67 may be located at a side of the first reference signal line 34 in the second direction Y. The first power supply connection line 66 may be located at a side of the second power supply connection line 67 in the second direction Y.

In some examples, the first reference signal line 34 may be located at a side of the fourth electrode plate 74 in the opposite direction of the second direction Y. The fifth scan signal line 65 may be located at a side of the first reference signal line 34 in the opposite direction of the second direction Y. The third scan signal line 63 may be located at a side of the fifth scan signal line 65 in the opposite direction of the second direction Y.

In some examples, the first scan signal line 61 may be located at a side of the third electrode plate 73 in the second direction Y. The second scan signal line 62 may be located at a side of the first scan signal line 61 in the second direction Y. The second initial signal line 82 may be located at a side of the second scan signal line 62 in the second direction Y.

In some examples, the first power supply connection line 66 may be located at a side of the fourth electrode plate 74 close to the third electrode plate 73. An orthographic projection of the first power supply connection line 66 on the base substrate may be partially overlapped with an orthographic projection of the third electrode plate 73 on the base substrate. The first power supply connection line 66 may be configured to be connected with a first power supply line formed subsequently to form a high voltage power supply grid structure of a mesh communication structure on the display substrate.

In some examples, the second power supply connection line 67 may be located between the fourth electrode plate 74 and the third electrode plate 73. For example, an orthographic projection of the second power supply connection line 67 on the base substrate may be not overlapped with orthographic projections of the third electrode plate 73 and the fourth electrode plate 74 on the base substrate. By setting that the second power supply connection line 67 is not overlapped with another signal, signal interference may be effectively prevented. The second power supply connection line 67 may be configured to be connected with a second power supply line formed subsequently to form a low voltage power supply grid structure of a mesh communication structure on the display substrate.

In some examples, the fifth scan signal line 65 may be connected with the ninth gate electrode 29 in each circuit unit through the nineteenth via V19, thereby achieving that the fifth scan signal line 65 is connected with the ninth gate electrode 29 of the ninth transistor T9, and the fifth scan signal line 65 may control turn-on and turn-off of the ninth transistor T9.

In some examples, the second scan signal line 62 may be connected with the second gate electrode 22 in each circuit unit through the fifteenth via V15, thereby achieving that the second scan signal line 62 is connected with the second gate electrode 22 of the second transistor T2, and the second scan signal line 62 may control turn-on and turn-off of the second transistor T2.

In some examples, the second scan signal line 62 and the fifth scan signal line 65 may be connected with a same gate drive circuit after extending to a bezel region, so as to achieve output of a same scan signal. That is, the second scan signal line 62 and the fifth scan signal line 65 output a same second scan signal.

In some examples, the first scan signal line 61 may be connected with the first gate electrode 21 in each circuit unit through the fourteenth via V14, thereby achieving that the first scan signal line 61 is connected with the first gate electrode 21 of the first transistor T1, and the first scan signal line 61 may control turn-on and turn-off of the first transistor T1.

In some examples, the third scan signal line 63 may be connected with the fourth gate electrode 24 in each circuit unit through the sixteenth via V16, thereby achieving that the third scan signal line 63 is connected with the fourth gate electrode 24 of the fourth transistor T4, and the third scan signal line 63 may control turn-on and turn-off of the fourth transistor T4.

In some examples, the second initial signal line 82 may be connected with a first region of a seventh active layer in each circuit unit through the seventh via V7, thereby achieving that the second initial signal line 82 is connected with a first electrode of the seventh transistor T7, and the second initial signal line 82 may write a second initial signal into the first electrode of the seventh transistor T7.

In some examples, the first reference signal line 34 may be connected with a first region of a ninth active layer in each circuit unit through the ninth via V9, thereby achieving that the first reference signal line 34 is connected with a first electrode of the ninth transistor T9, and the first reference signal line 34 may write a first reference signal into the first electrode of the ninth transistor T9.

In some examples, a first reference connection block 34-1 may be disposed at a side of the first reference signal line 34 close to the first power supply connection line 66. The first reference connection block 34-1 may be disposed in each circuit unit. A first end of the first reference connection block 34-1 is connected with the first reference signal line 34, and a second end of the first reference connection block 34-1 extends toward a direction to the second power supply connection line 67. The first reference connection block 34-1 may be configured to be connected with the fourth electrode plate 74 through the thirteenth via V13 on one hand, and to be connected with a reference signal connection line formed subsequently on the other hand. The first reference signal line 34 may write a first reference signal into the fourth electrode plate 74 of the second capacitor (i.e., the first end of the second capacitor). In some examples, the first reference signal line 34 and a plurality of first reference connection blocks 34-1 may be of an interconnected integral structure.

In some examples, a third power supply connection block 67-1 may be disposed at a side of the second power supply connection line 67 away from the first power supply connection line 66. The third power supply connection block 67-1 may be located between two adjacent circuit units within at least one unit row. A first end of the third power supply connection block 67-1 is connected with the second power supply connection line 67, a second end of the third power supply connection block 67-1 extends toward a direction to the first reference signal line 34, and the third power supply connection block 67-1 may be configured to be connected with a second power supply line formed subsequently.

In some examples, a first power supply connection block 66-1 may be disposed at a side of the first power supply connection line 66 away from the second power supply connection line 67, and the first power supply connection block 66-1 may be disposed in each circuit unit. A first end of the first power supply connection block 66-1 is connected with the first power supply connection line 66, and a second end of the first power supply connection block 66-1 extends toward a direction away from the second power supply connection line 67. In some examples, the first power supply connection block 66-1 may be configured, on one hand, to be connected with the first shield end of the first shield electrode 36 of the present circuit unit through the twenty-third via V23, and, on the other hand, to be connected with a first power supply line formed subsequently. Since the first power supply connection block 66-1 is connected with the first power supply line formed subsequently, a first power supply signal may be written into an upper electrode plate of the first voltage stabilizing capacitor. In some examples, the first power supply connection line 66 and a plurality of first power supply connection blocks 66-1 may be of an interconnected integral structure.

In some examples, a second power supply connection block 66-2 may be disposed at a side of the first power supply connection line 66 away from the second power supply connection line 67, and the second power supply connection block 66-2 may be disposed in each circuit unit. A first end of the second power supply connection block 66-2 is connected with the first power supply connection line 66, and a second end of the second power supply connection block 66-2 extends toward a direction away from the second power supply connection line 67. In each circuit unit, the second power supply connection block 66-2 may be located at a side of the first power supply connection block 66-1 in the first direction X. The second power supply connection block 66-2 may be configured to be connected with a second shield end of a first shield electrode 36 of an adjacent circuit unit through the twenty-fourth via V24. In some examples, a length of the second power supply connection block 66-2 along the second direction Y may be substantially the same as a length of the first power supply connection block 66-1 along the second direction Y. Since the first power supply connection line 66 is connected with a first power supply line formed subsequently, a first power supply signal may be written into an upper electrode plate of the second voltage stabilizing capacitor. In some examples, the first power supply connection line 66 and a plurality of second power supply connection blocks 66-2 may be of an interconnected integral structure.

In some examples, a shape of the first connection electrode 41 may be a strip shape in which a main body portion extends along the second direction Y, and the first connection electrode 41 may be located between the first scan signal line 61 and the first power supply connection line 66. For example, the first connection electrode 41 may be located between the first power supply connection block 66-1 and the second power supply connection block 66-2 in the first direction X. A first end of the first connection electrode 41 may be connected with the second region of the first active layer (also the first region of the second active layer) through the second via V2, and a second end of the first connection electrode 41 may be connected with the first electrode plate 71 through the tenth via V10. In some examples, the first connection electrode 41 may enable the second electrode of the first transistor T1, the first electrode of the second transistor T2, the gate electrode of the third transistor T3, and the first electrode plate 71 of the first capacitor (i.e., the first end of the first capacitor) to have a same potential, and the first connection electrode 41 may serve as a first node N1 of the pixel circuit. In some examples, a shape of the second connection electrode 42 may be substantially a rectangular shape, and the second connection electrode 42 may be located between the first reference signal line 34 and the second power supply connection line 67. The second connection electrode 42 may be connected with the first region of the fourth active layer through the third via V3. In some examples, the second connection electrode 42 may serve as the first electrode of the fourth transistor T4, and is configured to be connected with a data signal line formed subsequently.

In some examples, the third connection electrode 43 may have a polygonal line shape in which a main body portion extends along the second direction Y. The third connection electrode 43 may be located between the first reference signal line 34 and the second power supply connection line 67. A first end of the third connection electrode 43 may be connected with the second region of the fourth active layer (also the second region of the ninth active layer) through the fourth via V4. A second end of the third connection electrode 43 may be connected with the second electrode plate connection line 73-1 through the twelfth via V12. A third end between the first end and the second end may be connected with the second electrode plate 72 through the eleventh via V11. In some examples, the third connection electrode 43 may enable the second electrode of the fourth transistor T4, the second electrode of the ninth transistor T9, the third electrode plate 73 of the first capacitor (i.e. the second end of the first capacitor) and the second electrode plate 72 of the second capacitor (i.e. the second end of the second capacitor) to have a same potential, and the third connection electrode 43 may serve as a fifth node N5 of the pixel circuit.

In some examples, the fourth connection electrode 44 may have a substantially rectangular shape, and may be located between the second scan signal line 62 and the second initial signal line 82. The fourth connection electrode 44 may be connected with the first region of the fifth active layer through the fifth via V5. In some examples, the fourth connection electrode 44 may serve as the first electrode of the fifth transistor T5, and is configured to be connected with a first power supply line formed subsequently.

In some examples, the fifth connection electrode 45 may have a substantially “L” shape, and the fifth connection electrode 45 may be located between the second scan signal line 62 and the second initial signal line 82. The fifth connection electrode 45 may be connected with the second region of the sixth active layer (also the second region of the seventh active layer) through the sixth via V6. In some examples, the fifth connection electrode 45 may serve as the second electrode of the sixth transistor T6 and the second electrode of the seventh transistor T7, and is configured to be connected with an anode connection electrode formed subsequently.

In some examples, the sixth connection electrode 46 may have a strip shape in which a main body portion extends along the first direction X, and the sixth connection electrode 46 may be located between the second scan signal line 62 and the second initial signal line 82. A first end of the sixth connection electrode 46 may be connected with the first region of the eighth active layer through the eighth via V8, and a second end of the sixth connection electrode 46 may be connected with a second reference connection block 35-1 through the twenty-second via V22. In some examples, the sixth connection electrode 46 may serve as the first electrode of the eighth transistor T8, and since the second reference connection block 35-1 is connected with the second reference signal line 35, it is achieved that the second reference signal line 35 is connected with the first electrode of the eighth transistor T8, and a second reference signal line 35 in the n-th unit row may write a second reference signal into a first electrode of an eighth transistor T8 in the (n−1)-th unit row.

In some examples, the seventh connection electrode 47 may have a strip shape in which a main body portion extends along the first direction X, and the seventh connection electrode 47 may be located between the second scan signal line 62 and the second initial signal line 82. A first end of the seventh connection electrode 47 may be connected with the fifth gate electrode 25 through the seventeenth via V17, and a second end of the seventh connection electrode 47 may be connected with the first light emitting connection block 31-1 through the twentieth via V20. Since the first light emitting connection block 31-1 is connected with the first light emitting signal line 31, it is achieved that the first light emitting signal line 31 is connected with the fifth gate electrode 25 of the fifth transistor T5, and the first light emitting signal line 31 may control turn-on and turn-off of the fifth transistor T5.

In some examples, the eighth connection electrode 48 may have a strip shape in which a main body portion extends along the first direction X and the eighth connection electrode 48 may be located between the second scan signal line 62 and the second initial signal line 82. A first end of the eighth connection electrode 48 may be connected with the sixth gate electrode 26 through the eighteenth via V18, and a second end of the eighth connection electrode 48 may be connected with the second light emitting connection block 32-1 through the twenty-first via V21. Since the second light emitting connection block 32-1 is connected with the second light emitting signal line 32, it is achieved that the second light emitting signal line 32 is connected with the sixth gate electrode 26 of the sixth transistor T6, and the second light emitting signal line 32 may control turn-on and turn-off of the sixth transistor T6.

In some examples, the ninth connection electrode 49 may have a strip shape in which a main body portion extends along the first direction X, and the ninth connection electrode 49 may be located between the second scan signal line 62 and the second initial signal line 82. A first end of the ninth connection electrode 49 may be connected with the first region of the first active layer through the first via, and a second end of the ninth connection electrode 49 may be connected with a first initial connection block 81-1 of the first initial signal line 81 through the twenty-fifth via V25. Since the first initial connection block 81-1 is connected with the first initial signal line 81, it is achieved that the first initial signal line 81 is connected with the first electrode of the first transistor T1, and the first initial signal line 81 may write a first initial signal into the first electrode of the first transistor T1.

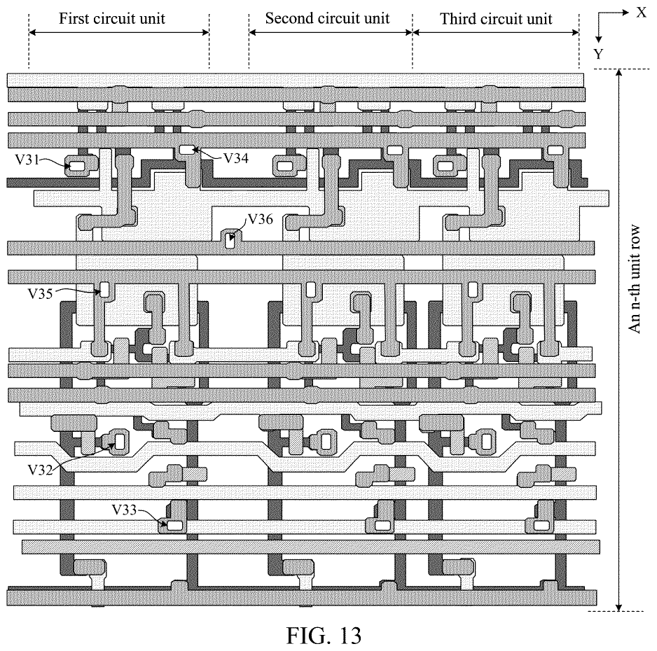

(1-6) A fourth insulation layer is formed. In some examples, a fourth insulation thin film is coated on the base substrate on which the aforementioned patterns are formed, and the fourth insulation thin film is patterned through a patterning process to form a fourth insulation layer covering the third conductive layer, and the fourth insulation layer in each circuit unit may be provided with a plurality of vias, as shown in FIG. 13. FIG. 13 is a schematic diagram of the display substrate after the fourth insulation layer is formed in FIG. 6. In some examples, the fourth insulation layer may also be referred to as a first planarization layer.

In some examples, the plurality of vias in each circuit unit in the display substrate may include at least a thirty-first via V31, a thirty-second via V32, a thirty-third via V33, a thirty-fourth via V34, and a thirty-fifth via V35.

In some examples, an orthographic projection of the thirty-first via V31 on the base substrate is located within a range of an orthographic projection of the second connection electrode 42 on the base substrate. The fourth insulation layer within the thirty-first via V31 is removed to expose a portion of a surface of the second connection electrode 42, and the thirty-first via V31 may be configured such that a data signal line formed subsequently is connected with the second connection electrode 42 through the via.

In some examples, an orthographic projection of the thirty-second via V32 on the base substrate is located within a range of an orthographic projection of the fourth connection electrode 44 on the base substrate. The fourth insulation layer within the thirty-second via V32 is removed to expose a portion of a surface of the fourth connection electrode 44, and the thirty-second via V32 may be configured such that a first power supply line formed subsequently is connected with the fourth connection electrode 44 through the via.

In some examples, an orthographic projection of the thirty-third via V33 on the base substrate is located within a range of an orthographic projection of the fifth connection electrode 45 on the base substrate. The fourth insulation layer within the thirty-third via V33 is removed to expose a portion of a surface of the fifth connection electrode 45, and the thirty-third via V33 may be configured such that an anode connection electrode formed subsequently is connected with the fifth connection electrode 45 through the via.

In some examples, an orthographic projection of the thirty-fourth via V34 on the base substrate may be within a range of an orthographic projection of the first reference connection block 34-1 of the first reference signal line 34 on the base substrate. The fourth insulation layer within the thirty-fourth via V34 may be removed to expose a portion of a surface of the first reference connection block 34-1, and the thirty-fourth via V34 may be configured such that a reference signal connection line formed subsequently is connected with the first reference connection block 34-1 through the via.

In some examples, an orthographic projection of the thirty-fifth via V35 on the base substrate may be within a range of an orthographic projection of the first power supply connection block 66-1 on the base substrate. The fourth insulation layer within the thirty-fifth via V35 may be removed to expose a portion of a surface of the first power supply connection block 66-1, and the thirty-fifth via V35 may be configured such that a first power supply line formed subsequently is connected with the first power supply connection block 66-1 through the via.

In some examples, a thirty-sixth via V36 may also be included in at least one circuit unit. An orthographic projection of the thirty-sixth via V36 on the base substrate may be within a range of an orthographic projection of the third power supply connection block 67-1 of the second power supply connection line 67 on the base substrate. The fourth insulation layer within the thirty-sixth via V36 is removed to expose a portion of a surface of the third power supply connection block 67-1, and the thirty-sixth via V36 may be configured such that a second power supply line formed subsequently is connected with the third power supply connection block 67-1 through the via. In some examples, the thirty-sixth via V36 may be located between a first circuit unit and a second circuit unit.

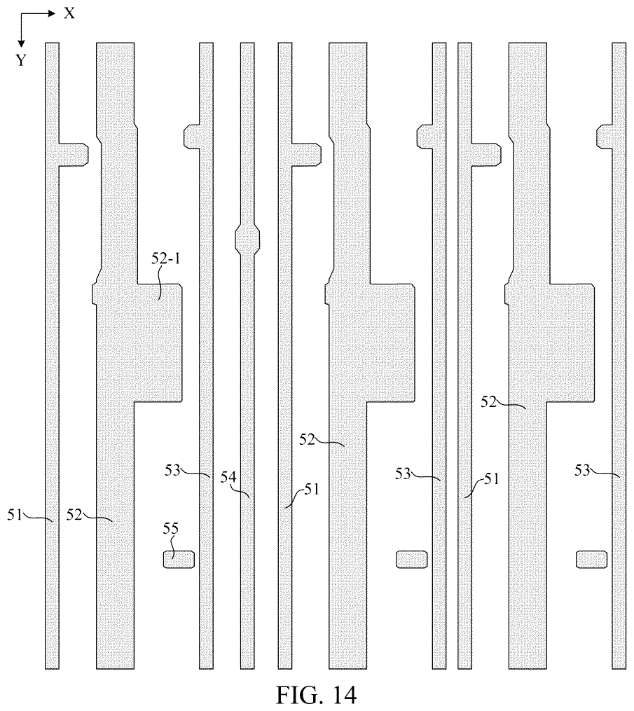

(1-7) A fourth conductive layer is formed. In some examples, a fourth conductive thin film is deposited on the base substrate on which the aforementioned patterns are formed, and the fourth conductive thin film is patterned through a patterning process to form a fourth conductive layer disposed on the fourth insulation layer, as shown in FIGS. 6 and 14. FIG. 14 is a schematic diagram of the fourth conductive layer in FIG. 6. In some examples, the fourth conductive layer may be referred to as a second source-drain metal (SD2) layer.

In some examples, the fourth conductive layer of each circuit unit in the display substrate may include a data signal line 51, a first power supply line 52, a reference signal connection line 53, and an anode connection electrode 55.

In some examples, the data signal line 51, the first power supply line 52, and the reference signal connection line 53 may have a strip shape in which a main body portion extends along the second direction Y. The first power supply line 52 may be located at a side of the data signal line 51 in the first direction X, and the reference signal connection line 53 may be located at a side of the first power supply line 52 in the first direction X, that is, the first power supply line 52 may be located between the data signal line 51 and the reference signal connection line 53.

In some examples, the data signal line 51 may have a straight line shape in which a main body portion extends along the second direction Y, and the data signal line 61 is connected with the second connection electrode 42 through the thirty-first via V31. Since the second connection electrode 42 is connected with the first region of the fourth active layer through a via, it is achieved that the data signal line 51 writes a data signal into the first electrode of the fourth transistor T4.

In some examples, the first power supply line 52 may have a polygonal line shape in which a main body portion extends along the second direction Y. The first power supply line 51 may be connected with the fourth connection electrode 44 through the thirty-second via V32 on one hand, and connected with the first power supply connection block 66-1 through the thirty-fifth via V35 on the other hand. Since the fourth connection electrode 44 is connected with the first region of the fifth active layer through a via, it is achieved that the first power supply line 51 writes a first power supply signal into the first electrode of the fifth transistor T5. Since the first power supply connection block 66-1 is connected with the first power supply connection line 66, it is achieved that the first power supply connection line 66 in which a main body portion extends along the first direction X and the first power supply line 52 in which a main body portion extends along the second direction Y are connected with each other, so that the first power supply line 52 and the first power supply connection line 66 form a mesh-like structure for transmitting the first power supply signal on the display substrate, which may not only effectively reduce a resistance of the first power supply line 52 and reduce a voltage drop of the first power supply signal, but also effectively improve uniformity of the first power supply signal in the display substrate, effectively improve uniformity of display, and improve display quality.

In some examples, a power supply shield block 52-1 is disposed at a side of the first power supply line 52 close to the reference signal connection line 53, a first end of the power supply shield block 52-1 is connected with the first power supply line 52, and a second end of the power supply shield block 52-1 extends toward a direction to the reference signal connection line 53. The power supply shield block 52-1 may have a substantially rectangular shape, an orthographic projection of the power supply shield block 52-1 on the base substrate is at least partially overlapped with an orthographic projection of the first connection electrode 41 on the base substrate, for example, the orthographic projection of the power supply shield block 52-1 on the base substrate may cover the orthographic projection of the first connection electrode 41 on the base substrate. Since the first connection electrode 41 serves as the first node N1 in the pixel circuit, the power supply shield block 52-1 with constant voltage may effectively shield an influence of another signal in the pixel circuit on the first node N1, thereby preventing the another signal (such as data voltage jump) from affecting a potential of the first node N1 in the pixel circuit, and improving a display effect. In some examples, the first power supply line 52 and the power supply shield block 52-1 may be of an interconnected integral structure.

In some examples, an orthographic projection of the first power supply line 52 on the base substrate may be partially overlapped with an orthographic projection of the third connection electrode 43 on the base substrate. Since the third connection electrode 43 serves as the fifth node N5 in the pixel circuit, the first power supply line 52 with constant voltage may effectively shield an influence of another signal in the pixel circuit on the fifth node N5, thereby avoiding an influence of another signal on a potential of the fifth node N5 in the pixel circuit, and improving a display effect.

In some examples, the first power supply line 52 may have an unequal width design, and the first power supply line 52 with the unequal width design may not only facilitate a layout of a pixel structure, but also reduce a parasitic capacitance between the first power supply line 52 and the data signal line 51.

In some examples, the reference signal connection line 53 may have a straight line shape in which a main body portion extends along the second direction Y, and the reference signal connection line 53 may be connected with the first reference connection block 34-1 through the thirty-fourth via V34. Since the first reference connection block 34-1 is connected with the first reference signal line 34, it is achieved that the first reference signal line 34 in which a main body portion extends along the first direction X and the reference signal connection line 53 in which a main body portion extends along the second direction Y are connected with each other, so that the first reference signal line 34 and the reference signal connection line 53 form a mesh-like structure for transmitting a first reference signal on the display substrate, which may not only effectively reduce a resistance of the first reference signal line and reduce a voltage drop of the first reference signal, but also effectively improve uniformity of the first reference signal in the display substrate, effectively improve uniformity of display and improve display quality.

In some examples, the anode connection electrode 55 may have a substantially rectangular shape. The anode connection electrode 55 may be located between the first power supply line 52 and the reference signal connection line 53. The anode connection electrode 55 may be connected with the fifth connection electrode 45 through the thirty-third via V33. Since the fifth connection electrode 45 is connected with the second region of the sixth active layer (also the second region of the seventh active layer) through a via, it is achieved that the anode connection electrode 55 is connected with the second electrode of the sixth transistor T6 and the second electrode of the seventh transistor T7. In some examples, the anode connection electrode 55 may be configured to be connected with an anode formed subsequently, so that it is achieved that a pixel circuit drives a light emitting device.

In some examples, an orthographic projection of the anode connection electrode 55 on the base substrate may be at least partially overlapped with an orthographic projection of the repair line 33 on the base substrate.

In some examples, the at least one circuit unit may further include a second power supply line 54. The second power supply line 54 may have a straight line shape in which a main body portion extends along the second direction Y, and the second power supply line 54 may be connected with the third power supply connection block 67-1 through the thirty-sixth via V36. Since the third power supply connection block 67-1 is connected with the second power supply connection line 67, it is achieved that the second power supply connection line 67 in which a main body portion extends along the first direction X and the second power supply line 54 in which a main body portion extends along the second direction Y are connected with each other, so that the second power supply line 54 and the second power supply connection line 67 form a mesh-like structure for transmitting a second power supply signal on the display substrate, which may not only effectively reduce a resistance of the second power supply line 67 and reduce a voltage drop of the second power supply signal, but also effectively improve uniformity of the second power supply signal in the display substrate, effectively improve uniformity of display and improve display quality. In some examples, the second power supply line 54 may be located between a reference signal connection line 53 of a first circuit unit and a data signal line 51 of a second circuit unit.

In some examples, a first power supply connection line 66 of the third conductive layer may be disposed in each unit row, a first power supply line 52 of the fourth conductive layer may be disposed in each unit column, and a plurality of first power supply lines 52 may be respectively connected with a plurality of first power supply connection lines 66 to form a mesh-like structure for transmitting a first power supply signal.

In some examples, a first reference signal line 34 of the third conductive layer may be disposed in each unit row, a reference signal connection line 53 of the fourth conductive layer may be disposed in each unit column, and a plurality of first reference signal lines 34 are respectively connected with a plurality of reference signal connection lines 53 to form a mesh-like structure for transmitting a first reference signal.

In some examples, a second power supply connection line 67 of the third conductive layer may be disposed in each unit row, and a second power supply line 54 of the fourth conductive layer may be disposed every two unit columns, and a plurality of second power supply lines 54 are respectively connected with a plurality of second power supply connection lines 67 to form a mesh-like structure for transmitting a second power supply signal.

A subsequent preparation process may include forming a pattern of a second planarization layer, a plurality of anode vias are disposed on the second planarization layer, an orthographic projection of an anode via on the base substrate may be within a range of an orthographic projection of the anode connection electrode on the base substrate. The second planarization layer within the anode via is removed to expose at least a portion of a surface of the anode connection electrode, and the anode via is configured such that an anode formed subsequently is connected with the anode connection electrode through the via.

At this point, a drive circuit layer in the embodiment is prepared on the base substrate. In an exemplary embodiment, after the drive circuit layer is prepared, a light emitting structure layer and an encapsulation structure layer may be sequentially prepared on the drive circuit layer, which will not be repeated here.

In some examples, the base substrate may be a flexible base substrate or may be a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In some examples, the flexible base substrate may include a first flexible material layer, a first inorganic material layer, a semiconductor layer, a second flexible material layer, and a second inorganic material layer which are stacked. The first flexible material layer and the second flexible material layer may be made of Polyimide (PI), Polyethylene Terephthalate (PET) or a surface-treated polymer soft film, or the like; and the first inorganic material layer and the second inorganic material layer may be made of Silicon Nitride (SiNx) or Silicon Oxide (SiOx), etc., thereby improving water-resistance and oxygen-resistance of the base substrate. A material of the semiconductor layer may be amorphous silicon (a-si).

In some examples, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo and Ti/Al/Ti. For example, the first conductive layer and the second conductive layer may be made of a single-layer molybdenum metal, and the third conductive layer and the fourth conductive layer may be made of a three-layer stacked structure of Ti/Al/Ti. A resistivity of traces of the third conductive layer and the fourth conductive layer may be less than a resistivity of traces of the first conductive layer and the second conductive layer.

In some examples, the first insulation layer 201, the second insulation layer 202, and the third insulation layer 203 may be made of any one or more of Silicon Oxide (SiOx), Silicon Nitride (SiNx), and Silicon Oxynitride (SiON), and may be a single layer, a multi-layer, or a composite layer. The first insulation layer 201 and the second insulation layer 202 may also be referred to as Gate Insulation (GI) layers, and the third insulation layer 203 may also be referred to as an Interlayer Dielectric (ILD) layer. The fourth insulation layer 204 may also be referred to as a first planarization layer. The fourth insulation layer 204 and the second planarization layer may be made of an organic material, such as polyimide, acrylic, or polyethylene terephthalate, or the like. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

A structure and a preparation process of the display substrate of the embodiment are merely illustrative. In some examples, a corresponding structure may be changed and a patterning process may be added or reduced according to actual needs. The preparation process of the example may be implemented using an existing mature preparation device, and may be compatible well with an existing preparation process, simple in process implementation, easy to implement, high in a production efficiency, low in a production cost, and high in a yield.

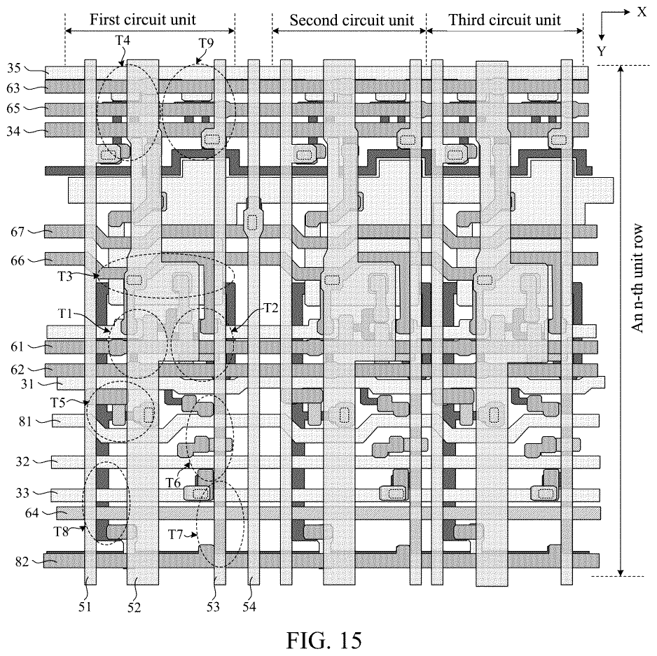

FIG. 15 is a schematic diagram of a planar structure of another display substrate according to at least one embodiment of the present disclosure. A structure of a pixel circuit in three circuit units (i.e., a first circuit unit, a second circuit unit, and a third circuit unit) in the display substrate is illustrated in FIG. 15. In the example, a first signal line and a second power supply line transmit a same signal, in other words, the second power supply line of the example may serve as the first signal line, and a fourth electrode plate (i.e., an upper electrode plate) of a second capacitor of the pixel circuit is connected with a second power supply line VSS. Rest of a structure of the pixel circuit of the example may be substantially the same as that of the aforementioned embodiments.

In some examples, a second power supply line 54 extending along a second direction Y and a second power supply connection line 67 extending along a first direction X are connected with each other to form a mesh-like structure for transmitting a second power supply signal. The second power supply connection line 67 is connected with a fourth electrode plate 74 of the second capacitor to transmit a second power supply signal to the fourth electrode plate 74. A first power supply line 52 extending along the second direction Y and a first power supply connection line 66 extending along the first direction X are connected with each other to form a mesh-like structure for transmitting a first power supply signal. A reference signal connection line 53 extending along the second direction Y and a first reference signal line 34 extending along the first direction X are connected with each other to form a mesh-like structure for transmitting a first reference signal.

In some examples, a preparation process of the display substrate of the example may include following operations.

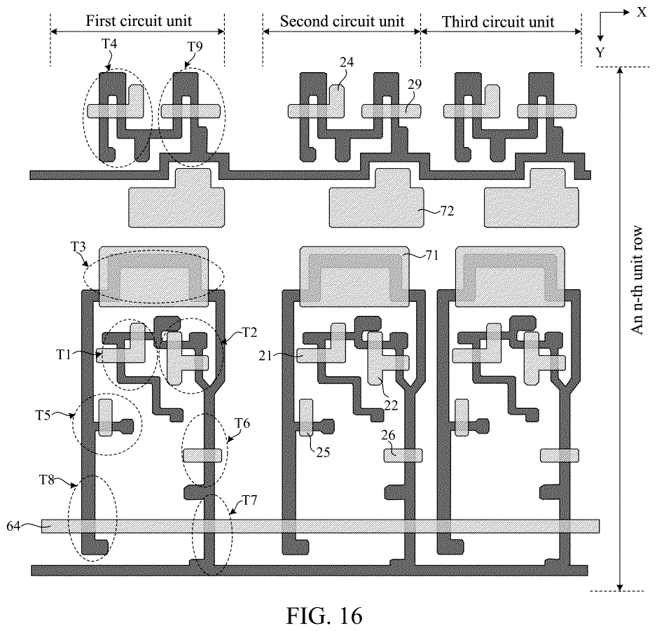

(2-1) A semiconductor layer is formed. In some examples, a semiconductor thin film is deposited on a base substrate, and the semiconductor thin film is patterned through a patterning process to form a semiconductor layer, as shown in FIG. 16. FIG. 16 is a schematic diagram of a display substrate after a semiconductor layer and a first conductive layer are formed in FIG. 15. The semiconductor layer of the display substrate of the example has a same structure as the semiconductor layer of the display substrate of the aforementioned embodiment, so it will not be repeated here.

(2-2) A first conductive layer is formed. In some examples, a first insulation thin film and a first conductive thin film are sequentially deposited on the base substrate on which the aforementioned pattern is formed, and the first conductive thin film is patterned through a patterning process to form a first insulation layer covering the semiconductor layer and a first conductive layer on the first insulation layer, as shown in FIG. 16. The first conductive layer of the display substrate of the example has a same structure as the first conductive layer of the display substrate of the aforementioned embodiment, so it will not be repeated here.

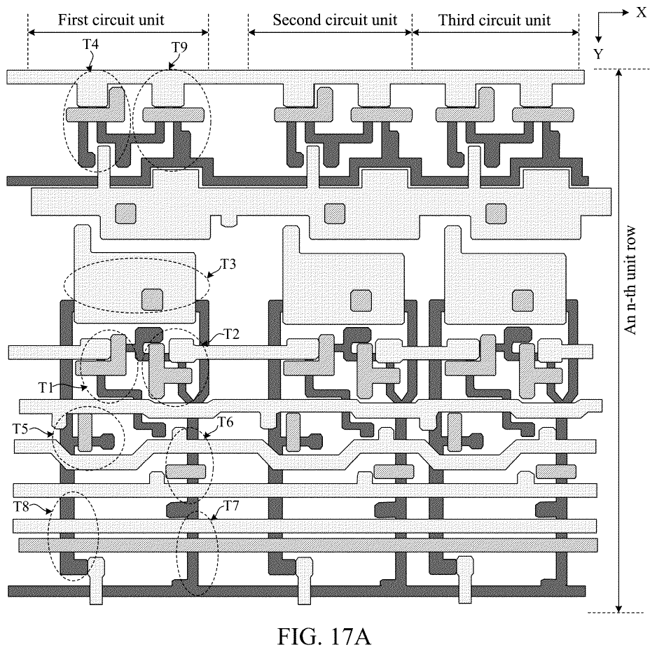

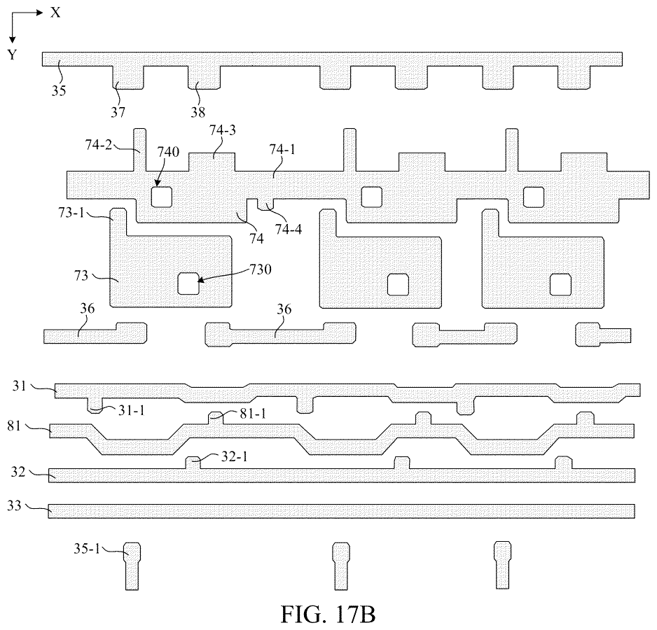

(2-3) A second conductive layer is formed. In some examples, a second insulation thin film and a second conductive thin film are sequentially deposited on the base substrate on which the aforementioned patterns are formed, and the second conductive thin film is patterned through a patterning process to form a second insulation layer covering the first conductive layer and a second conductive layer covering the second insulation layer, as shown in FIG. 17A and FIG. 17B. FIG. 17A is a schematic diagram of the display substrate after the second conductive layer is formed in FIG. 15. FIG. 17B is a schematic diagram of the second conductive layer in FIG. 17A.

In some examples, the second conductive layer of each circuit unit in the display substrate may include at least a first light emitting signal line 31, a second light emitting signal line 32, a repair line 33, a second reference signal line 35, a first initial signal line 81, a first shield electrode 36, a second shield electrode 37, a third shield electrode 38, a third electrode plate 73 of a first capacitor, and a fourth electrode plate 74 of a second capacitor.

In some examples, a first electrode plate connection line 74-1 may be disposed at a side of the fourth electrode plate 74 in the first direction X or in a direction opposite to the first direction X. A first end of the first electrode plate connection line 74-1 is connected with a fourth electrode plate 74 of a present circuit unit, and a second end of the first electrode plate connection line 74-1 is connected with a fourth electrode plate 74 of an adjacent circuit unit after extending along the first direction X or the direction opposite to the first direction X, so that fourth electrode plates 74 of adjacent circuit units in one unit row are connected with each other. In some examples, a length of the first electrode plate connection line 74-1 along the second direction Y may be less than a length of the fourth electrode plate 74 along the second direction Y.

In some examples, an electrode plate connection block 74-4 may be disposed at a side of the first electrode plate connection line 74-1 in the second direction Y. The electrode plate connection block 74-4 may be located between at least two adjacent circuit units within at least one unit row, for example, one electrode plate connection block 74-4 may be disposed every three circuit units. A first end of the electrode plate connection block 74-4 is connected with the first electrode plate connection line 74-1, the electrode plate connection block 74-4 may extend toward a direction to the first light emitting signal line 31, and the electrode plate connection block 74-4 may be configured to be connected with a second power supply connection line formed subsequently. In some examples, the fourth electrode plate 74, the first electrode plate connection line 74-1, and the electrode plate connection block 74-4 may be of an interconnected integral structure. Since the electrode plate connection block 74-4 is connected with the second power supply connection line formed subsequently, fourth electrode plates 74 of an integral structure of a plurality of circuit units may be multiplexed as a transverse power supply line extending along the first direction X, which may not only ensure that a plurality of fourth electrode plates 74 in one unit row have a same potential, but also reduce a voltage drop of a second power supply signal, which is beneficial to improving uniformity of the display substrate, avoiding poor display of the display substrate and ensuring a display effect of the display substrate. Rest of a structure of the second conductive layer of the display substrate of the example is similar to a structure of the second conductive layer of the display substrate of the aforementioned embodiment, thus will not be repeated here.

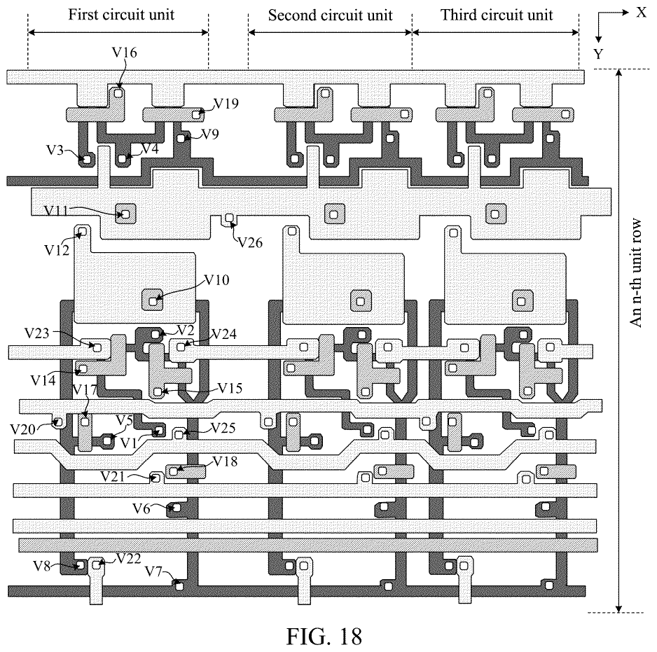

(2-4) A third insulation layer is formed. In some examples, a third insulation thin film is deposited on the base substrate on which the aforementioned patterns are formed, and the third insulation thin film is patterned through a patterning process to form a third insulation layer. A plurality of vias are disposed in the third insulation layer of each circuit unit, as shown in FIG. 18. FIG. 18 is a schematic diagram of the display substrate after a third insulation layer is formed in FIG. 15.

In some examples, the plurality of vias of each circuit unit in the display substrate may include at least a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, a twenty-third via V23, a twenty-fourth via V24, a twenty-fifth via 25, and a twenty-sixth via 26.

In some examples, an orthographic projection of the twenty-sixth via V26 on the base substrate may be within a range of an orthographic projection of the electrode plate connection block 74-4 on the base substrate. The third insulation layer within the twenty-sixth via V26 may be removed to expose a portion of a surface of the electrode plate connection block 74-4, and the twenty-sixth via V26 may be configured such that the second power supply connection line formed subsequently is connected with the electrode plate connection block 74-4 through the via. Rest of a structure of the third insulation layer of the display substrate of the example is similar to a structure of the third insulation layer of the display substrate of the aforementioned embodiment, thus will not be repeated here.

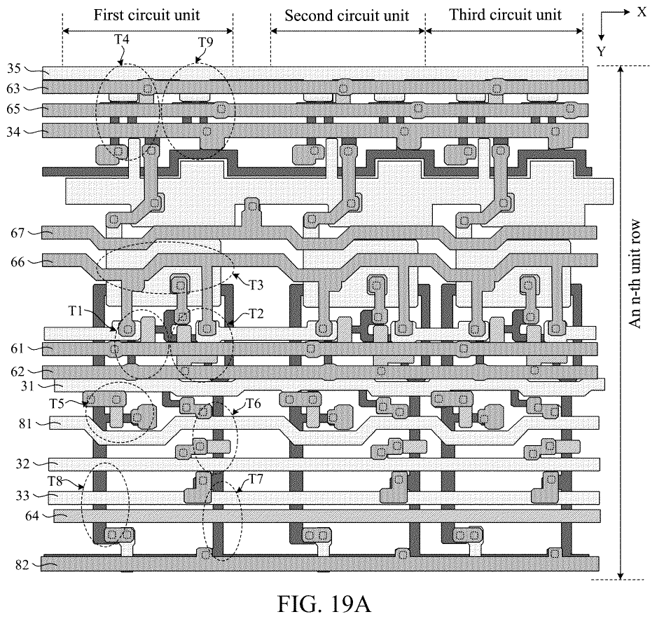

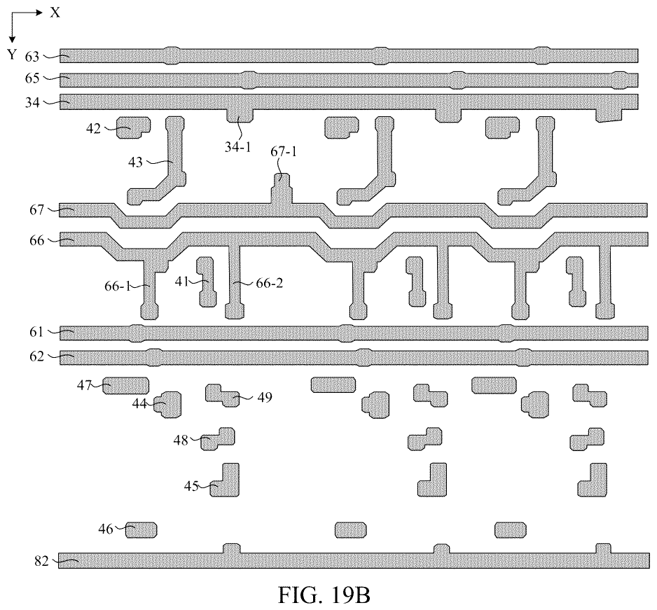

(2-5) A third conductive layer is formed. In some examples, a third conductive thin film is deposited on the base substrate on which the aforementioned patterns are formed, and the third conductive thin film is patterned through a patterning process to form a third conductive layer disposed on the third insulation layer, as shown in FIGS. 19A and 19B. FIG. 19A is a schematic diagram of the display substrate after the third conductive layer is formed in FIG. 15. FIG. 19B is a schematic diagram of the third conductive layer in FIG. 19A.

In some examples, third conductive layers of a plurality of circuit units in the display substrate may each include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a first scan signal line 61, a second scan signal line 62, a third scan signal line 63, a fifth scan signal line 65, a first power supply connection line 66, a second power supply connection line 67, a first initial signal line 81, a second initial signal line 82, and a first reference signal line 34.

In some examples, the first scan signal line 61, the second scan signal line 62, the third scan signal line 63, the fifth scan signal line 65, the first initial signal line 81, the second initial signal line 82, and the first reference signal line 34 may have substantially a straight line shape in which a main body portion extends along the first direction X. The first power supply connection line 66 and the second power supply connection line 67 may have a substantially polygonal line shape in which a main body portion extends along the first direction X. The third scan signal line 63, the fifth scan signal line 65, and the first reference signal line 34 may be located at a side of the fourth electrode plate 74 in a direction opposite to the second direction Y. The first scan signal line 61, the second scan signal line 62, the first initial signal line 81, and the second initial signal line 82 may be located at a side of the third electrode plate 73 in the second direction Y, the second power supply connection line 67 may be located at a side of the fourth electrode plate 74 in the second direction Y, and the first power supply connection line 66 may be located at a side of the second power supply connection line 67 in the second direction Y. An orthographic projection of the first power supply connection line 66 on the base substrate is partially overlapped with an orthographic projection of the third electrode plate 73 on the base substrate. An orthographic projection of the second power supply connection line 67 on the base substrate is partially overlapped with the orthographic projection of the third electrode plate 73 on the base substrate, and may be not overlapped with an orthographic projection of the fourth electrode plate 74 on the base substrate.

In some examples, a third power supply connection block 67-1 may be disposed at a side of the second power supply connection line 67 away from the first power supply connection line 66, and the third power supply connection block 67-1 may be located between two adjacent circuit units within at least one unit row. A first end of the third power supply connection block 67-1 is connected with the second power supply connection line 67. A second end of the third power supply connection block 67-1 extends toward a direction to the first reference signal line 34. The third power supply connection block 67-1 may be connected with the electrode plate connection block 74-4 through the twenty-sixth via V26 on one hand, and may be configured to be connected with a second power supply line formed subsequently on the other hand. In the example, three adjacent circuit units within one unit row may be connected with the second power supply connection line 67 through one electrode plate connection block 74-4 to achieve a connection with a second power supply line formed subsequently. By disposing a plurality of circuit units (for example, three circuit units) to share the electrode plate connection block 74-4, ta quantity of vias required for a connection with the second power supply connection line and the second power supply line may be reduced, and space may be saved.

Rest of a structure of the third conductive layer of the display substrate of the example is similar to a structure of the third conductive layer of the display substrate of the aforementioned embodiment, thus will not be repeated here.

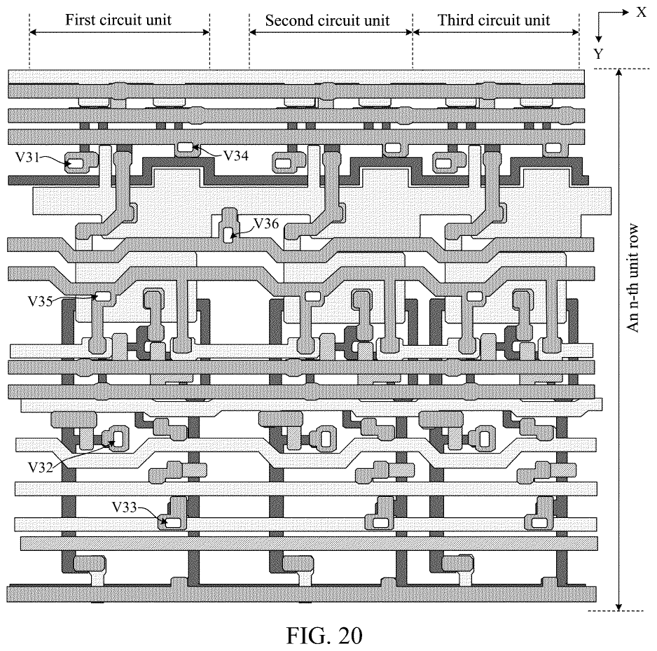

(2-6) A fourth insulation layer is formed. In some examples, a fourth insulation thin film is coated on the base substrate on which the aforementioned patterns are formed, and the fourth insulation thin film is patterned through a patterning process to form a fourth insulation layer covering the third conductive layer, and the fourth insulation layer in each circuit unit may be provided with a plurality of vias, as shown in FIG. 20. FIG. 20 is a schematic diagram of the display substrate after the fourth insulation layer is formed in FIG. 15.

In some examples, the plurality of vias of each circuit unit in the display substrate may include at least a thirty-first via V31, a thirty-second via V32, a thirty-third via V33, a thirty-fourth via V34, and a thirty-fifth via V35.

In some examples, a thirty-sixth via V36 may also be included in at least one circuit unit. An orthographic projection of the thirty-sixth via V36 on the base substrate may be within a range of an orthographic projection of the third power supply connection block 67-1 of the second power supply connection line 67 on the base substrate. The fourth insulation layer within the thirty-sixth via V36 is removed to expose a portion of a surface of the third power supply connection block 67-1, and the thirty-sixth via V36 may be configured such that a second power supply line formed subsequently is connected with the third power supply connection block 67-1 through the via. In some examples, the thirty-sixth via V36 may be located between the first circuit unit and the second circuit unit.

A structure of the fourth insulation layer of the display substrate of the example is similar to A structure of the fourth insulation layer of the display substrate of the aforementioned embodiment, thus will not be repeated here.

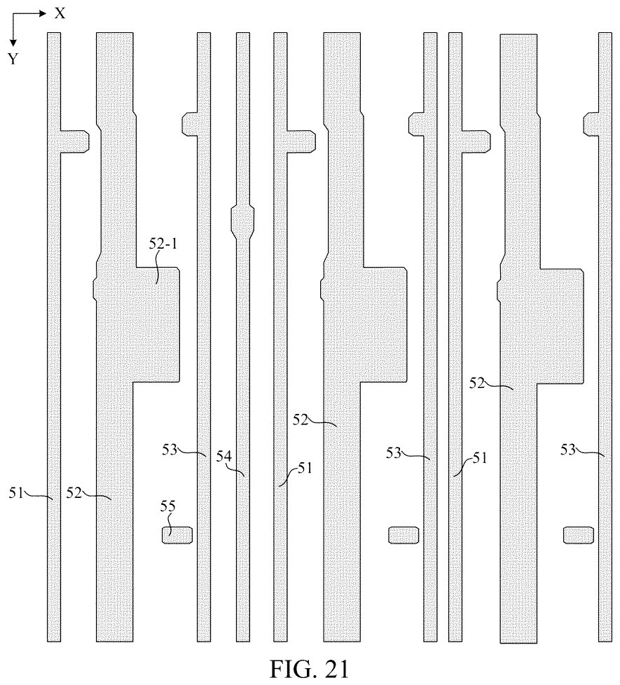

(2-7) A fourth conductive layer is formed. In some examples, a fourth conductive thin film is deposited on the base substrate on which the aforementioned patterns are formed, and the fourth conductive thin film is patterned through a patterning process to form a fourth conductive layer disposed on the fourth insulation layer, as shown in FIGS. 15 and 21. FIG. 21 is a schematic diagram of the fourth conductive layer in FIG. 15.

In some examples, a fourth conductive layer of each circuit unit in the display substrate may include a data signal line 51, a first power supply line 52, a reference signal connection line 53, and an anode connection electrode 55.

In some examples, the at least one circuit unit may further include a second power supply line 54. The second power supply line 54 may have a straight line in which a main body portion extends along the second direction Y, and the second power supply line 54 may be connected with the third power supply connection block 67-1 through the thirty-sixth via V36. Since the third power supply connection block 67-1 is connected with the second power supply connection line 67, it is achieved that the second power supply connection line 67 in which a main body portion extends along the first direction X and the second power supply line 54 in which a main body portion extends along the second direction Y are connected with each other, so that the second power supply line 54 and the second power supply connection line 67 form a mesh-like structure for transmitting a second power supply signal on the display substrate, which may not only effectively reduce a resistance of the second power supply line 67 and reduce a voltage drop of the second power supply signal, but also effectively improve uniformity of the second power supply signal in the display substrate, effectively improve uniformity of display and improve display quality. In some examples, a second power supply line 54 may be located between a reference signal connection line 53 of the first circuit unit and a data signal line 51 of the second circuit unit.

In some examples, a fourth electrode plate 74 of a second conductive layer may be disposed in each unit row, and fourth electrode plates 74 of an integral structure of a plurality of circuit units in one unit row may be multiplexed as a transmission line of a transverse second power supply signal extending along the first direction X; the second power supply connection line 67 of the third conductive layer may be disposed in each unit row to achieve transverse transmission of the second power supply signal. In the example, the second conductive layer and the third conductive layer are all provided with a transverse transmission path of a second power supply signal, which may effectively reduce a load of the second power supply line, optimize a voltage drop of the second power supply signal and improve a cross-voltage of the second power supply signal. A second power supply line 54 of the fourth conductive layer may be disposed every two unit columns, and a plurality of second power supply lines 54 may be respectively connected with a plurality of second power supply connection lines 67 to form a mesh-like structure for transmitting a second power supply signal, thereby reducing a voltage drop of a second power supply signal, effectively improving uniformity of the second power supply signal in the display substrate, effectively improving uniformity of display, and improving display quality.

A structure of the fourth conductive layer of the display substrate of the example is substantially the same as a structure of the fourth conductive layer of the display substrate of the aforementioned embodiment, thus will not be repeated here.

At this point, a drive circuit layer of the embodiment is prepared on the base substrate. In some exemplary implementation modes, after preparation of the drive circuit layer is completed, a light emitting structure layer and an encapsulation structure layer may be sequentially prepared on the drive circuit layer, which will not be repeated here.

In the display substrate of the example, by setting a fourth electrode plate of a second capacitor of a pixel circuit to be connected with a second power supply connection line and a second power supply line, to receive a stable second power supply with constant voltage, which is beneficial to improve a voltage difference at both ends of the second capacitor, thereby improving a storage capacity of the second capacitor and slowing down an attenuation speed of a stored data signal.

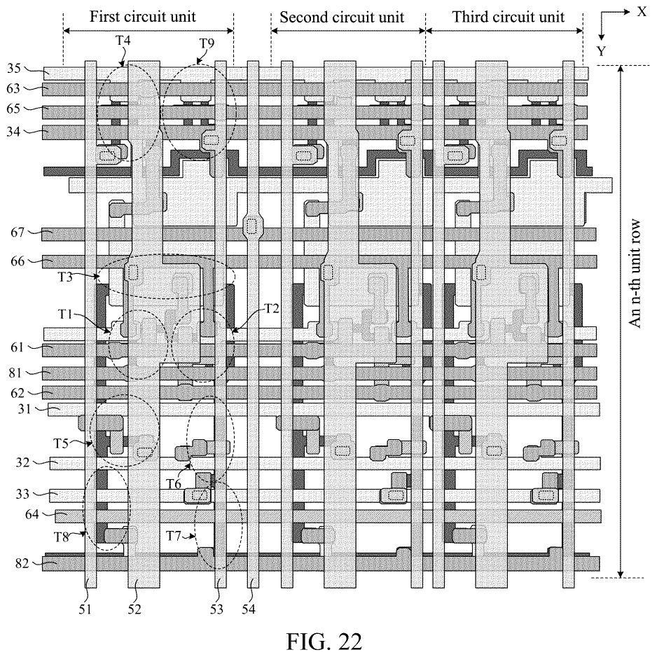

FIG. 22 is a schematic diagram of a planar structure of another display substrate according to at least one embodiment of the present disclosure. A structure of a pixel circuit in three circuit units (i.e., a first circuit unit, a second circuit unit, and a third circuit unit) of the display substrate is schematically illustrated in FIG. 22. In the example, a first signal line and a first reference signal line transmit a same signal, in other words, the first reference signal line of the example may serve as the first signal line, and a fourth electrode plate (i.e., the upper electrode plate) of a second capacitor of the pixel circuit is connected with the first reference signal line. Moreover, a first initial signal line in the example may be located between a first scan signal line and a second scan signal line. Rest of a structure of the pixel circuit of the example is similar to the embodiment shown in FIG. 6.

In some examples, the first initial signal line 81 may be located between the first scan signal line 61 and the second scan signal line 62. By disposing the first initial signal line 81 between the first scan signal line 61 and the second scan signal line 62, a distance between the first initial signal line 81 and a channel region of a first active layer of the first transistor T1 may be reduced. The first initial signal line 81 may provide a first initial signal for an initialization processing to the first transistor T1 through a shortest path, thereby facilitating reduction of a length of a first region of the first active layer, reducing a load of the first initial signal line and optimizing an initialization effect.

In some examples, the first initial signal line 81 is located in the third conductive layer, a resistance of the first initial signal line 81 may be reduced and a transmission effect of a first initial signal may be ensured. The second scan signal line 62 and the first initial signal line 81 may be of a same layer structure, and the second scan signal line 62 is located at a side of the first initial signal line 81 away from the first scan signal line 61, an overlapping capacitance between the second scan signal line 62 and the first initial signal line 81 may be reduced, and a load of the second scan signal line 62 may be reduced, thereby reducing a drive load of a scan driver with which the second scan signal line 62 is connected.

In some examples, the first light emitting signal line 31 may be located at a side of the second scan signal line 62 and the first initial signal line 81 in the second direction Y, and an orthographic projection of the second light emitting signal line 31 on the base substrate may be not overlapped with orthographic projections of the second scan signal line 62 and the first initial signal line 81 on the base substrate, an overlapping capacitance between the first light emitting signal line 31 and the first initial signal line 81 may be reduced, and a load of the first light emitting signal line 31 may be reduced, thereby reducing a drive load of a light emitting driver with which the first light emitting signal line 31 is connected.

In some examples, a preparation process of the display substrate may include following operations.

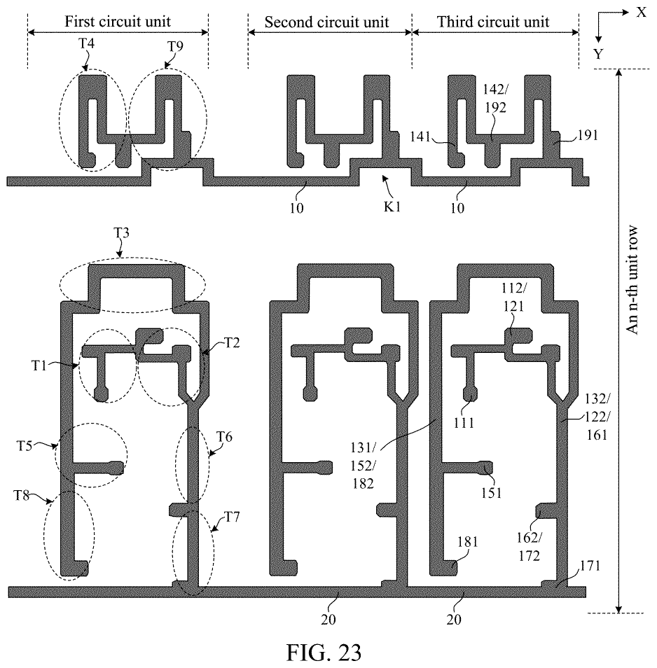

(3-1) A semiconductor layer is formed. In some examples, a semiconductor thin film is deposited on a base substrate, and the semiconductor thin film is patterned through a patterning process to form a semiconductor layer, as shown in FIG. 23. FIG. 23 is a schematic diagram of the display substrate after a semiconductor layer is formed in FIG. 22.

In some examples, a semiconductor layer in each circuit unit in the base substrate may include at least a first active layer 11 of the first transistor T1, a second active layer 12 of the second transistor T2, a third active layer 13 of the third transistor T3, a fourth active layer 14 of the fourth transistor T4, a fifth active layer 15 of the fifth transistor T5, a sixth active layer 16 of the sixth transistor T6, a seventh active layer 17 of the seventh transistor T7, an eighth active layer 18 of the eighth transistor T8, and a ninth active layer 19 of the ninth transistor T9. Wherein, the first active layer 11 to the third active layer 13 and the fifth active layer 15 to the eighth active layer 18 may be of an interconnected integral structure, and the fourth active layer 14 and the ninth active layer 19 may be of an interconnected integral structure.

In some examples, the first active layer 11 and the second active layer 12 may have a substantially “L” shape, the third active layer 13 may have a substantially “C” shape, the fourth active layer 14 and the ninth active layer 19 may have a substantially “n” shape, and the fifth active layer 15, the sixth active layer 16, the seventh active layer 17, and the eighth active layer 18 may have a substantially “I” shape. In some examples, a first region 111 of the first active layer 11 may be located at a side of the fifth active layer 15 in the second direction Y.

Rest of a structure of the semiconductor layer of the display substrate of the example is similar to a structure of the semiconductor layer of the display substrate of the aforementioned embodiments, thus will not be repeated here.

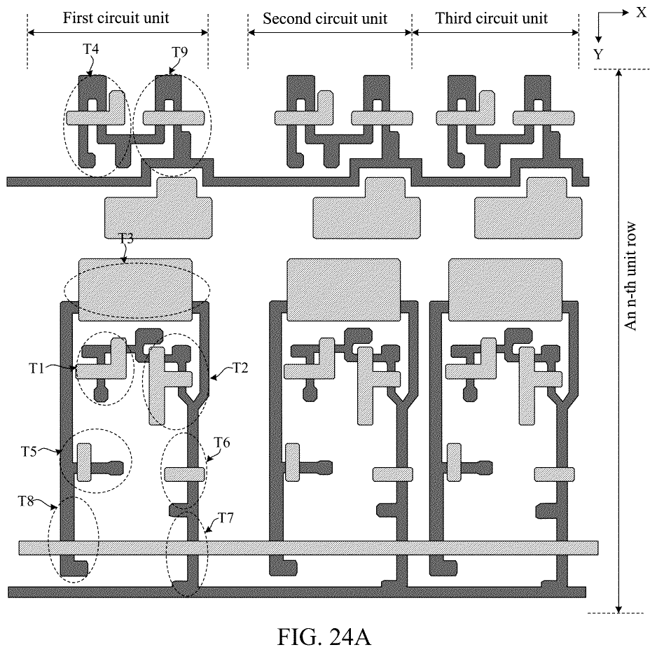

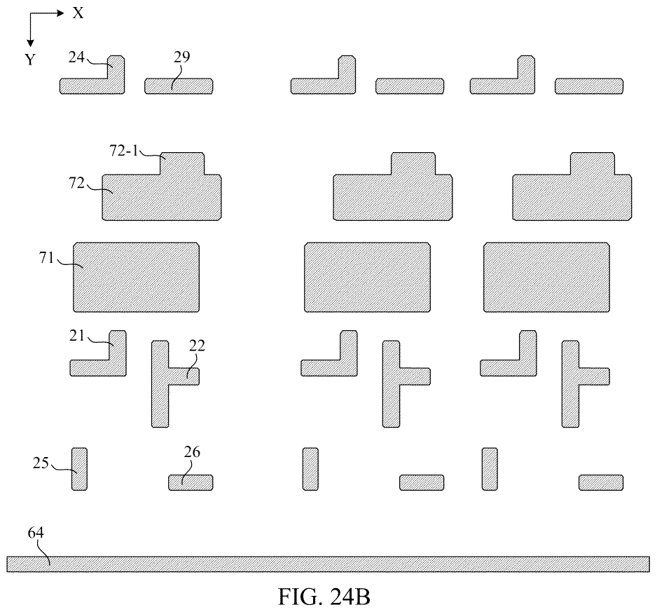

(3-2) A first conductive layer is formed. In some examples, a first insulation thin film and a first conductive thin film are sequentially deposited on the base substrate on which the aforementioned pattern is formed, and the first conductive thin film is patterned through a patterning process to form a first insulation layer covering the semiconductor layer and a first conductive layer disposed on the first insulation layer, as shown in FIGS. 24A and 24B. FIG. 24A is a schematic diagram of the display substrate after the first conductive layer is formed in FIG. 22. FIG. 24B is a schematic diagram of the first conductive layer in FIG. 24A.

In some examples, a first conductive layer of each circuit unit in the display substrate may include at least a first gate electrode 21 of the first transistor T1, a second gate electrode 22 of the second transistor T2, a fourth gate electrode 24 of the fourth transistor T4, a fifth gate electrode 25 of the fifth transistor T5, a sixth gate electrode 26 of the sixth transistor T6, a ninth gate electrode 29 of the ninth transistor T9, a fourth scan signal line 64, a first electrode plate 71 of a first capacitor, and a second electrode plate 72 of a second capacitor. A structure of the first conductive layer of the display substrate of the example is similar to a structure of the first conductive layer of the display substrate of the aforementioned embodiment, thus will not be repeated here.

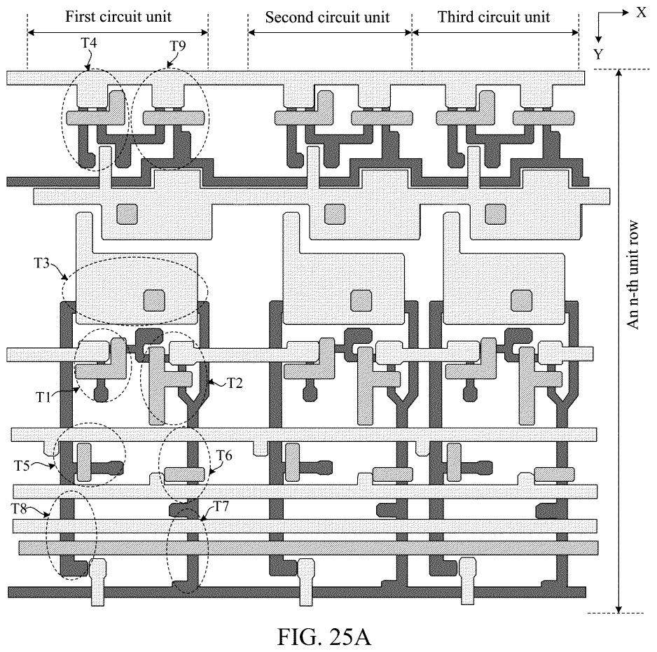

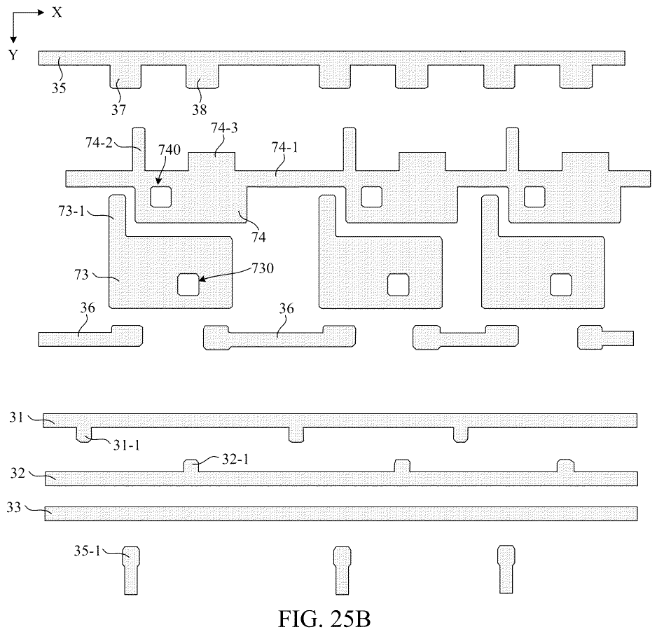

(3-3) A second conductive layer is formed. In some examples, a second insulation thin film and a second conductive thin film are sequentially deposited on the base substrate on which the aforementioned patterns are formed, and the second conductive thin film is patterned through a patterning process to form a second insulation layer covering the first conductive layer and a second conductive layer disposed on the second insulation layer, as shown in FIGS. 25A and 25B. FIG. 25A is a schematic diagram of the display substrate after the second conductive layer is formed in FIG. 22. FIG. 25B is a schematic diagram of the second conductive layer in FIG. 25A.

In some examples, a second conductive layer of each circuit unit in the display substrate may include at least a first light emitting signal line 31, a second light emitting signal line 32, a repair line 33, a second reference signal line 35, a first shield electrode 36, a second shield electrode 37, a third shield electrode 38, a third electrode plate 73 of the first capacitor, and a fourth electrode plate 74 of the second capacitor.

In some examples, the first light emitting signal line 31 is located at a side of the third electrode plate 73 in the second direction Y, the second light emitting signal line 32 is located at a side of the first light emitting signal line 31 in the second direction Y, and the repair line 33 is located at a side of the second light emitting signal line 32 in the second direction Y. The first light emitting signal line 31, the second light emitting signal line 32, and the repair line 33 may have substantially a straight line shape extending along the first direction X.

Rest of a structure of the second conductive layer of the display substrate of the example is similar to a structure of the second conductive layer of the display substrate of the aforementioned embodiments, thus will not be repeated here.

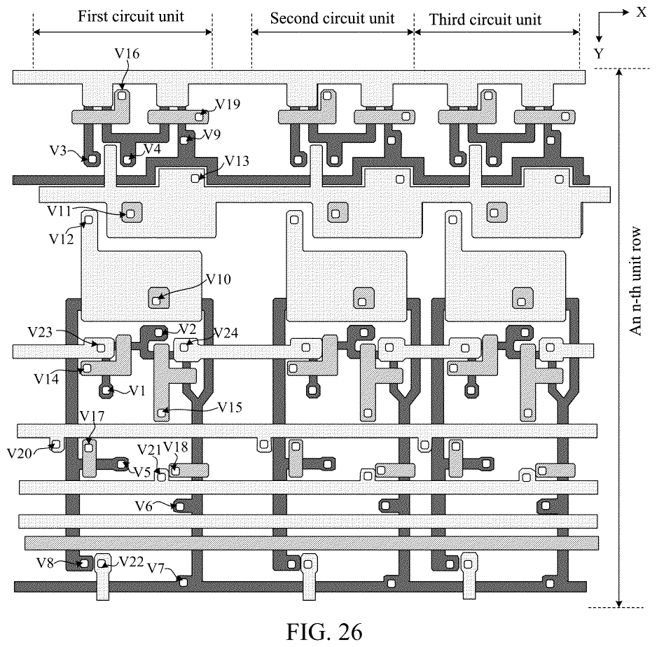

(3-4) A third insulation layer is formed. In some examples, a third insulation thin film is deposited on the base substrate on which the aforementioned patterns are formed, and the third insulation thin film is patterned through a patterning process to form a third insulation layer, a plurality of vias are disposed in the third insulation layer of each circuit unit, as shown in FIG. 26. FIG. 26 is a schematic diagram of the display substrate after a third insulation layer is formed in FIG. 22.

In some examples, the plurality of vias of each circuit unit in the display substrate may include at least a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, a twenty-third via V23, and a twenty-fourth via V24. A structure of the third insulation layer of the display substrate of the example is similar to a structure of the third insulation layer of the display substrate of the aforementioned embodiment, thus will not be repeated here.

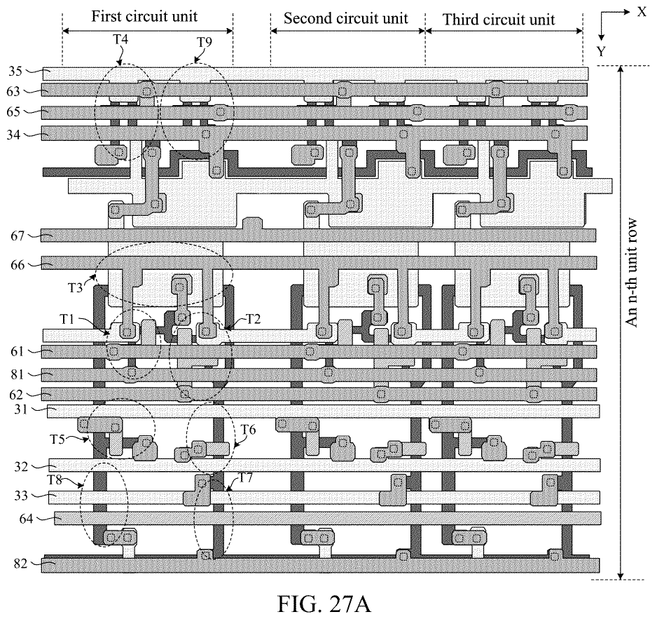

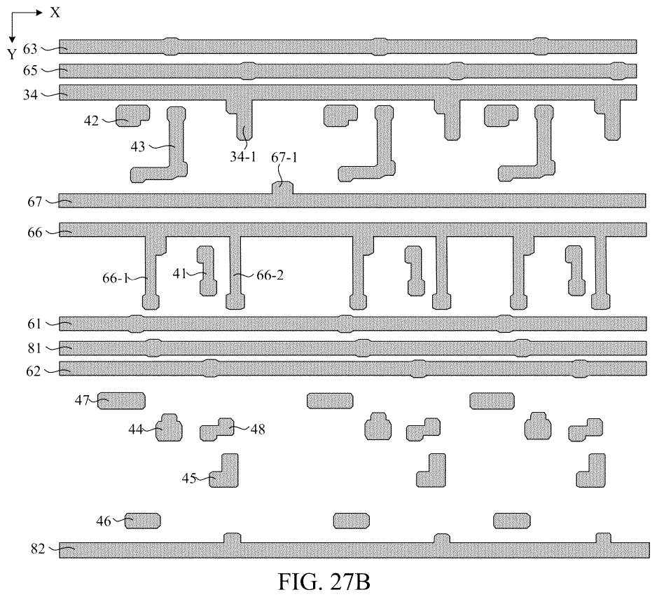

(3-5) A third conductive layer is formed. In some examples, a third conductive thin film is deposited on the base substrate on which the aforementioned patterns are formed, and the third conductive thin film is patterned through a patterning process to form a third conductive layer disposed on the third insulation layer, as shown in FIGS. 27A and 27B. FIG. 27A is a schematic diagram of the display substrate after a third conductive layer is formed in FIG. 22. FIG. 27B is a schematic diagram of the third conductive layer in FIG. 27A.

In some examples, a third conductive layer of each circuit unit in the display substrate may include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a first scan signal line 61, a second scan signal line 62, a third scan signal line 63, a fifth scan signal line 65, a first power supply connection line 66, a second power supply connection line 67, a first initial signal line 81, a second initial signal line 82, and a first reference signal line 34.

In some examples, the first scan signal line 61, the second scan signal line 62, the third scan signal line 63, the fifth scan signal line 65, the first initial signal line 81, the second initial signal line 82, the first reference signal line 34, the first power supply connection line 66, and the second power supply connection line 67 may have substantially a straight line shape in which a main body portion extends along the first direction X. The first scan signal line 61, the second scan signal line 62, and the first initial signal line 81 are located at a side of the third electrode plate 73 in the second direction Y. The first initial signal line 81 may be located at a side of the first scan signal line 61 in the second direction Y, and the second scan signal line 62 may be located at a side of the first initial signal line 81 in the second direction Y.

In some examples, the first initial signal line 81 is located between the first scan signal line 61 and the second scan signal line 62. By disposing the first initial signal line 81 between the first scan signal line 61 and the second scan signal line 62, a distance between the first initial signal line 81 and a channel region of the first active layer of the first transistor T1 may be reduced. The first initial signal line 81 may provide a first initial signal for an initialization processing to the first transistor T1 through a shortest path, thereby facilitating reduction of a length of the first region of the first active layer, reducing a load of the first initial signal line and optimizing an initialization effect. Furthermore, by disposing the first initial signal line 81 in the third conductive layer in the example, a resistance of the first initial signal line 81 may be reduced, and a transmission effect of the first initial signal may be ensured.

In the example, by disposing the second scan signal line 62 and the first initial signal line 81 to be of a same layer structure, and the second scan signal line 62 is located at a side of the first initial signal line 81 far away from the first scan signal line 61, an overlapping capacitance between the second scan signal line 62 and the first initial signal line 81 may be reduced, and a load of the second scan signal line 62 may be reduced, thereby reducing a drive load of a scan driver with which the second scan signal line 62 is connected.

The first light emitting signal line 31 of the example may be located at a side of the second scan signal line 62 and the first initial signal line 81 in the second direction Y, and an orthographic projections of the second light emitting signal line 31 on the base substrate may be not overlapped with orthographic projections of the second scan signal line 62 and the first initial signal line 81 on the base substrate, an overlapping capacitance between the first light emitting signal line 31 and the first initial signal line 81 may be reduced, and a load of the first light emitting signal line 31 may be reduced, thereby reducing a drive load of a light emitting driver with which the first light emitting signal line 31 is connected.

Rest of a structure of the third conductive layer of the display substrate of the example is similar to a structure of the third conductive layer of the display substrate of the aforementioned embodiment, thus will not be repeated here.

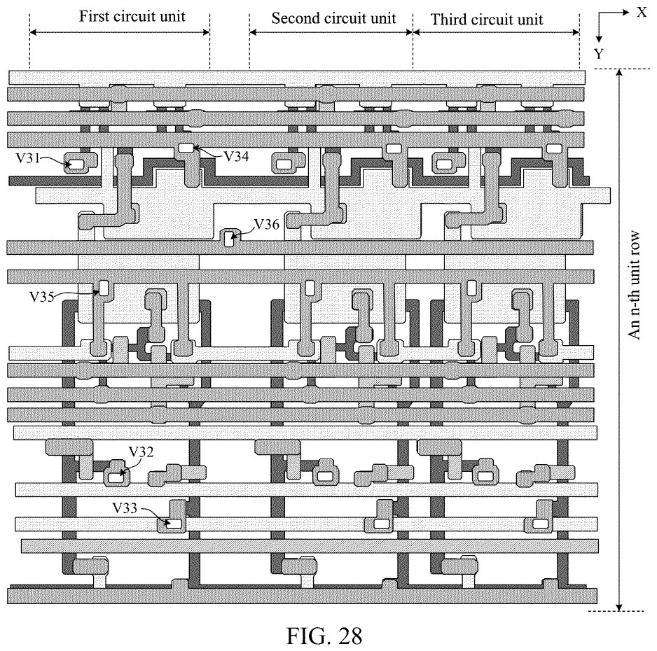

(3-6) A fourth insulation layer is formed. In some examples, a fourth insulation thin film is coated on the base substrate on which the aforementioned patterns are formed, and the fourth insulation thin film is patterned through a patterning process to form a fourth insulation layer covering the third conductive layer, and the fourth insulation layer in each circuit unit may be provided with a plurality of vias, as shown in FIG. 28. FIG. 28 is a schematic diagram of the display substrate after the fourth insulation layer is formed in FIG. 22.

In some examples, the plurality of vias of each circuit unit in the display substrate may include at least a thirty-first via V31, a thirty-second via V32, a thirty-third via V33, a thirty-fourth via V34, and a thirty-fifth via V35. A thirty-sixth via V36 may also be included in the at least one circuit. A structure of the fourth insulation layer of the display substrate of the example is similar to a structure of the fourth insulation layer of the display substrate of the aforementioned embodiment, thus will not be repeated here.

(3-7) A fourth conductive layer is formed. In some examples, a fourth conductive thin film is deposited on the base substrate on which the aforementioned patterns are formed, and the fourth conductive thin film is patterned through a patterning process to form a fourth conductive layer disposed on the fourth insulation layer, as shown in FIG. 22.

In some examples, a fourth conductive layer of each circuit unit in the display substrate may include a data signal line 51, a first power supply line 52, a reference signal connection line 53, and an anode connection electrode 55. A second power supply line 54 may also be included in the at least one circuit. A structure of the fourth conductive layer of the display substrate of the example is similar to a structure of the fourth conductive layer of the display substrate of the aforementioned embodiment, thus will not be repeated here.

At this point, a drive circuit layer of the embodiment is prepared on the base substrate. In some exemplary implementation modes, after preparation of the drive circuit layer is completed, a light emitting structure layer and an encapsulation structure layer may be sequentially prepared on the drive circuit layer, which will not be repeated here.

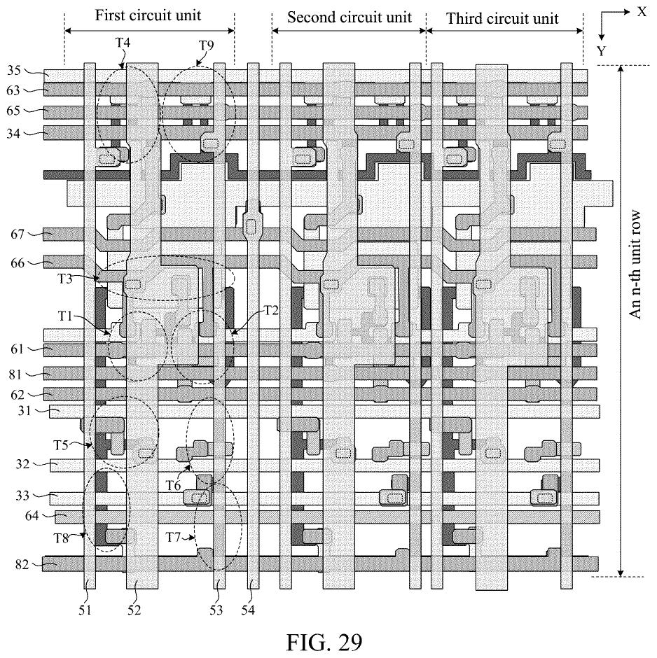

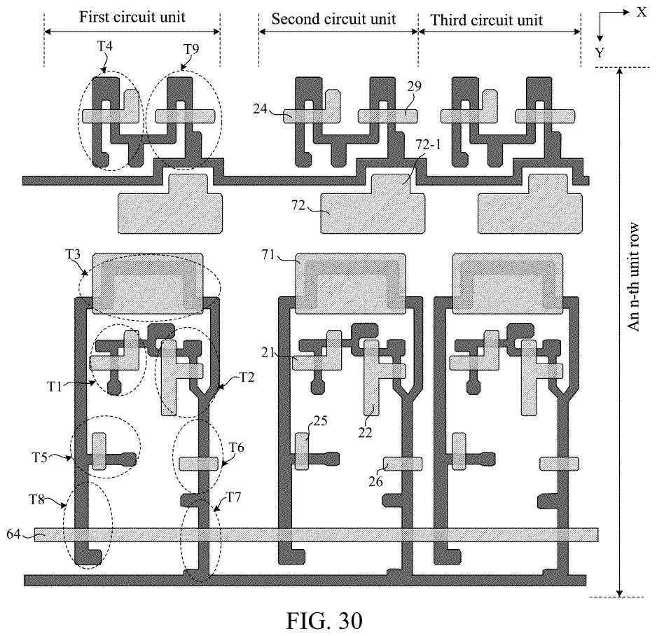

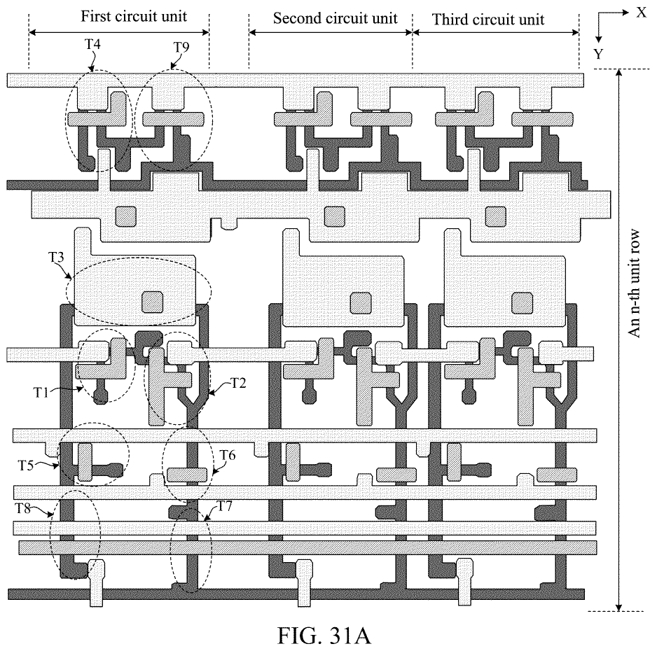

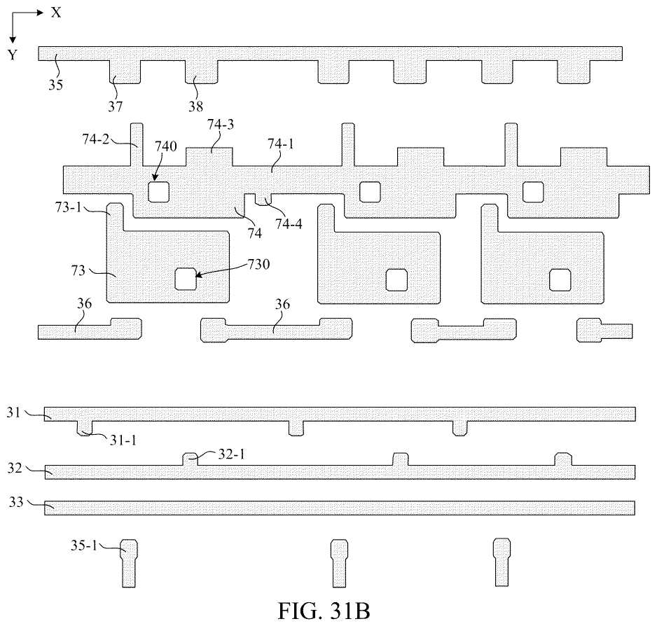

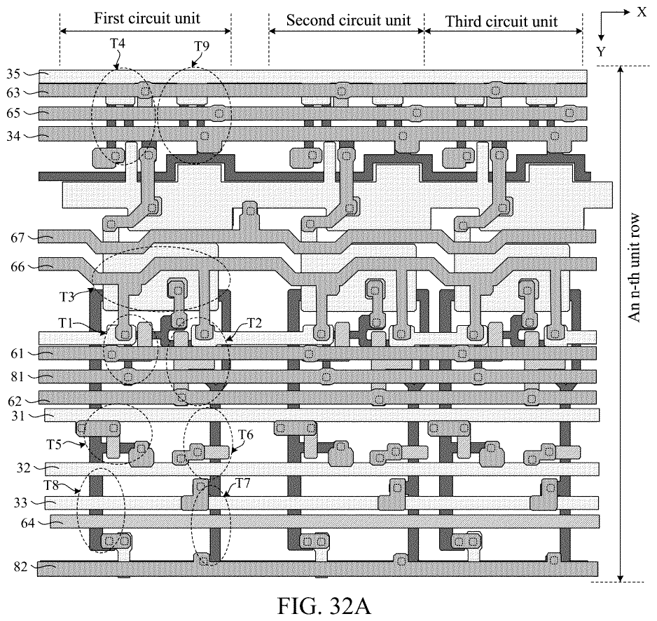

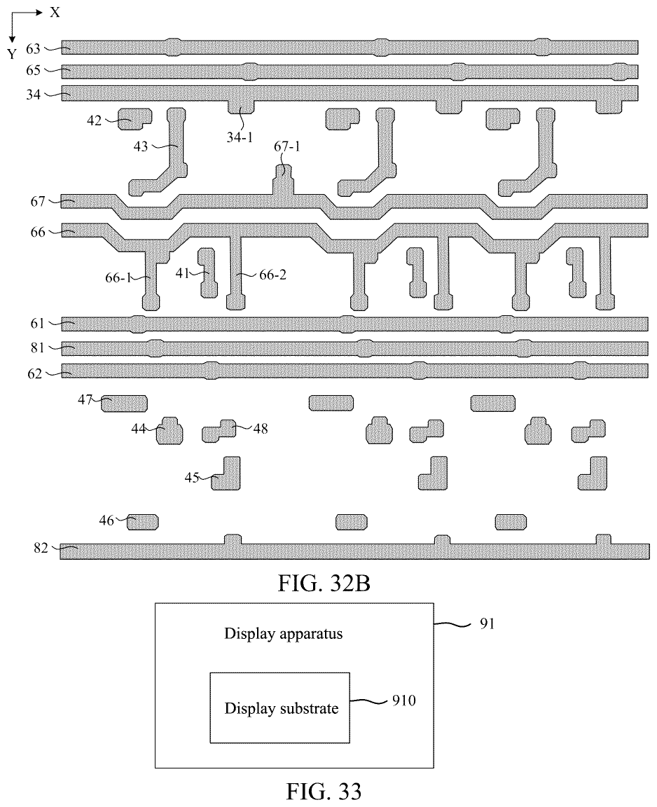

FIG. 29 is a schematic diagram of a planar structure of another display substrate according to at least one embodiment of the present disclosure. A structure of a pixel circuit in three circuit units (i.e., a first circuit unit, a second circuit unit, and a third circuit unit) of the display substrate is illustrated in FIG. 29. FIG. 30 is a schematic diagram of the display substrate after a first conductive layer is formed in FIG. 29. FIG. 31A is a schematic diagram of the display substrate after a second conductive layer is formed in FIG. 29. FIG. 31B is a schematic diagram of the second conductive layer in FIG. 31A. FIG. 32A is a schematic diagram of the display substrate after a third conductive layer is formed in FIG. 29. FIG. 32B is a schematic diagram of the third conductive layer in FIG. 32A.

In the example, a first signal line and a second power supply line transmit a same signal, in other words, the second power supply line of the example may serve as the first signal line, and a fourth electrode plate (i.e., an upper electrode plate) of a second capacitor of the pixel circuit is connected with the second power supply line. Moreover, a first initial signal line in the example may be located between a first scan signal line and a second scan signal line. Rest of a structure of the pixel circuit of the example is similar to the embodiment shown in FIG. 15.

In some examples, the second power supply line 54 extending along the second direction Y and the second power supply connection line 67 extending along the first direction X are connected with each other to form a mesh-like structure for transmitting a second power supply signal. The second power supply connection line 67 is connected with the electrode plate connection block 74-4, and the electrode plate connection block 74-4 and the fourth electrode plate 74 of the second capacitor are of an interconnected integral structure to transmit the second power supply signal to the fourth electrode plate 74.

In some examples, the first initial signal line 81 is located in the third conductive layer, so that a resistance of the first initial signal line 81 may be reduced and a transmission effect of a first initial signal may be ensured. The first initial signal line 81 has a same layer structure as the first scan signal line 61 and the second scan signal line 62, and the first initial signal line 81 is located between the first scan signal line 61 and the second scan signal line 62, so that a distance between the first initial signal line 81 and a channel region of a first active layer of the first transistor T1 may be reduced, and the first initial signal line 81 may provide a first initial signal for an initialization processing to the first transistor T1 through a shortest path, which is beneficial to reduce a length of a first region of the first active layer, reduce a load of the first initial signal line, and optimize an initialization effect.

Rest of a structure of the display substrate of the embodiment may be referred to related description of the aforementioned embodiments, thus will not be repeated here.

In other examples, the second power supply connection line and the second power supply line in the aforementioned embodiments may be replaced by a first signal connection line and a first signal line. The first signal connection line may have a line shape extending along the first direction X, and the first signal line may have a line shape extending along the second direction Y. The first signal line and the first signal connection line may be connected with each other, and the first signal connection line may be connected with the fourth electrode plate of the second capacitor to provide a constant voltage signal to the fourth electrode plate (i.e., the upper electrode plate) of the second capacitor. The constant voltage signal provided by the first signal line may be different from a first power supply signal so as to help improve a voltage difference between two ends of the second capacitor and improve a storage capacity of the second capacitor.

In other examples, the first signal line and a second initial signal line may transmit a same signal, in other words, the second initial signal line may serve as the first signal line, and the fourth electrode plate (i.e., the upper electrode plate) of the second capacitor of the pixel circuit is connected with the second initial connection line. The second initial connection line may have a substantially straight line shape extending along the second direction Y. The second power supply line in the aforementioned embodiments may be replaced by a second initial connection line. The second initial connection line may be connected with the second initial signal line located in the third conductive layer, and may also be connected with the fourth electrode plate of the second capacitor through a connection electrode disposed in the third conductive layer, so as to provide a stable second initial signal to the fourth electrode plate (i.e., the upper electrode plate) of the second capacitor. By providing a second initial signal to the fourth electrode plate of the second capacitor, a voltage difference between the two ends of the second capacitor may be improved, and the storage capacity of the second capacitor may be improved.

In the display substrate provided by the embodiment, it may help to increase a voltage difference between the two ends of the second capacitor by providing a constant voltage signal different from the first power supply signal to the upper electrode plate of the second capacitor as a voltage stabilizing signal, thereby improving the storage capacity of the second capacitor and further reducing an attenuation speed of a written data signal.

In the display substrate provided by the embodiment, a first power supply connection line in which a main body portion extends along the first direction and a first power supply line in which a main body portion extends along the second direction Y are disposed, and the first power supply line and the first power supply connection line are connected with each other, so that the first power supply line and the first power supply connection line form a mesh-like structure for transmitting a first power supply signal on the display substrate, which may not only effectively reduce a resistance of the first power supply line and reduce a voltage drop of the first power supply signal, but also effectively improve uniformity of the first power supply signal in the display substrate, effectively improve uniformity of display and improve display quality.

In the display substrate provided by the embodiment, a second power supply connection line in which a main body portion extends along the first direction X and a second power supply line in which a main body portion extends along the second direction Y are disposed, and the second power supply line and the second power supply connection line are connected with each other, so that the second power supply line and the second power supply connection line form a mesh-like structure for transmitting a second power supply signal on the display substrate, which may not only effectively reduce a resistance of the second power supply signal line and reduce a voltage drop of the second power supply signal, but also effectively improve uniformity of the second power supply signal in the display substrate, effectively improve uniformity of display and improve display quality. By disposing the second power supply connection line to be connected with the fourth electrode plate of the second capacitor, it is not only beneficial to improve performance of the second capacitor, but also beneficial to a wiring design.

In the display substrate provided by the embodiment, a first reference signal line in which a main body portion extends along the first direction X and a reference signal connection line in which a main body portion extends along the second direction Y are disposed, and the first reference signal line and the reference signal connection line are connected with each other, so that the first reference signal line and the reference signal connection line form a mesh-like structure for transmitting a first reference signal on the display substrate, which may not only effectively reduce a resistance of the first reference signal line and reduce a voltage drop of the first reference signal, but also effectively improve uniformity of the first reference signal in the display substrate, effectively improve uniformity of display and improve display quality. By disposing the first reference signal line to be connected with the fourth electrode plate of the second capacitor, it is not only beneficial to improve performance of the second capacitor, but also beneficial to a wiring design.

In the display substrate provided by the embodiment, an influence of a data voltage jump on the first transistor T1 and the second transistor T2 may be shielded by disposing the first shield electrode, so as to avoid an influence of the data voltage jump on a normal operation of the pixel circuit and improve a display effect.

In the display substrate provided by the embodiment, an influence of a data voltage jump on the fourth transistor T4, the ninth transistor T9, and the fifth node N5 may be shielded by disposing the second shield electrode and the third shield electrode, so as to avoid an influence of the data voltage jump on a normal operation of the pixel circuit and improves a display effect.

The present disclosure also provides a preparation method of a display substrate, for preparing the display substrate according to the aforementioned embodiments.

In some exemplary implementation modes, a preparation method of a display substrate may include: forming a drive circuit layer on a base substrate. Wherein, the drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor; a first end of the first capacitor is electrically connected with a gate electrode of the drive transistor, a second end of the first capacitor is electrically connected with a second end of the second capacitor, and a first end of the second capacitor is electrically connected with a first signal line; a gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor; a gate electrode of the first light emitting control transistor is electrically connected with a first light emitting signal line, a first electrode of the first light emitting control transistor is electrically connected with a first power supply line, and a second electrode of the first light emitting control transistor is electrically connected with the first electrode of the drive transistor; the first signal line and the first power supply line are configured to provide different constant voltage signals.

For the preparation method of the display substrate in the embodiment, reference may be made to description of the aforementioned embodiments, and thus will not be repeated here.

An embodiment of the present disclosure also provides a display substrate, including a base substrate and a drive circuit layer disposed on the base substrate, wherein the drive circuit layer includes at least a plurality of circuit units, at least one of the plurality of circuit units includes a pixel circuit, and the pixel circuit includes at least a first capacitor, a second capacitor, a data writing transistor, a drive transistor, and a first light emitting control transistor. A first end of the first capacitor is electrically connected with a gate electrode of the drive transistor, a second end of the first capacitor is electrically connected with a second end of the second capacitor, and a first end of the second capacitor is electrically connected with a first signal line. A gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor. A gate electrode of the first light emitting control transistor is electrically connected with a first light emitting signal line, a first electrode of the first light emitting control transistor is electrically connected with a first power supply line, and a second electrode of the first light emitting control transistor is electrically connected with the first electrode of the drive transistor. The first signal line and the first power supply line are configured to provide different constant voltage signals. The data writing transistor, the second capacitor, the first capacitor, and the first light emitting control transistor are sequentially disposed along a second direction, an orthographic projection of the first capacitor on the base substrate is partially overlapped with an orthographic projection of the drive transistor on the base substrate.

In some exemplary implementation modes, the pixel circuit further includes a first reference transistor, wherein a gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor. The first reference signal line is located at a side of the second capacitor away from the first capacitor.

In some exemplary implementation modes, the first signal line and the first reference signal line transmit a same signal. The first capacitor includes at least a first electrode plate as the first end of the first capacitor and a third electrode plate as the second end of the first capacitor, wherein an orthographic projection of the first electrode plate on the base substrate is at least partially with an orthographic projection of the third electrode plate on the base substrate The second capacitor includes at least a second electrode plate as the second end of the second capacitor and a fourth electrode plate as the first end of the second capacitor, wherein an orthographic projection of the second electrode plate on the base substrate is at least partially with an orthographic projection of the fourth electrode plate on the base substrate. The fourth electrode plate of the second capacitor is connected with the first reference signal line through a via.

In some exemplary implementation modes, the drive circuit layer further includes at least one second power supply connection line extending along a first direction and at least one second power supply line extending along a second direction, the first direction intersecting with the second direction; the second power supply line is connected with the second power supply connection line to form a mesh-like structure for transmitting a second power supply signal; a portion of the second power supply connection line is located between the first capacitor and the second capacitor. The first signal line and the second power supply line transmit a same signal.

In some exemplary implementation modes, the pixel circuit further includes a first initialization transistor and a compensation transistor. A gate electrode of the first initialization transistor is electrically connected with a first scan signal line, a first electrode of the first initialization transistor is electrically connected with a first initial signal line, and a second electrode of the first initialization transistor is electrically connected with the gate electrode of the drive transistor. A gate electrode of the compensation transistor is electrically connected with a second scan signal line, a first electrode of the compensation transistor is electrically connected with the gate electrode of the drive transistor, and a second electrode of the compensation transistor is electrically connected with a second electrode of the drive transistor. The first initialization transistor and the compensation transistor are located at a side of the first capacitor away from the second capacitor; extension directions of the first initial signal line, the first scan signal line, and the second scan signal line are at least partially the same and the first initial signal line, the first scan signal line, and the second scan signal line are located at a side of the first initialization transistor away from the first capacitor; the first initial signal line is located between the first scan signal line and the second scan signal line.

Description of the display substrate of the example may be referred to description of the aforementioned embodiments, and thus will not be repeated here.

FIG. 33 is a schematic diagram of a display apparatus according to at least one embodiment of the present disclosure. In some examples, as shown in FIG. 33, the embodiment provides a display apparatus 91, including a display substrate 910 of the aforementioned embodiments. In some examples, the display substrate 910 may include an OLED display substrate, a QLED display substrate, a Micro-LED display substrate, or a Mini-LED display substrate. The display apparatus 91 may be any product or component with a display function, such as a mobile phone, a tablet computer, a television, a display, a laptop computer, a digital photo frame, and a navigator. However, the embodiment is not limited thereto.

The drawings of the present disclosure only involve structures involved in the present disclosure, and other structures may be referred to conventional designs. The embodiments of the present disclosure and features in the embodiments may be combined with each other to obtain new embodiments if there is no conflict. Those of ordinary skills in the art should understand that modifications or equivalent replacements may be made to the technical solutions of the present disclosure without departing from the spirit and scope of the technical solutions of the present disclosure, and shall all fall within the scope of the claims of the present disclosure.

1. A display substrate, comprising:
a base substrate and a drive circuit layer disposed on the base substrate, wherein the drive circuit layer comprises at least a plurality of circuit units, at least one of the plurality of circuit units comprises a pixel circuit, and the pixel circuit comprises at least a first capacitor, a second capacitor, a data writing transistor, a drive transistor, and a first light emitting control transistor;
a first end of the first capacitor is electrically connected with a gate electrode of the drive transistor, a second end of the first capacitor is electrically connected with a second end of the second capacitor, and a first end of the second capacitor is electrically connected with a first signal line;
a gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor;
a gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor;
the first signal line and the first power supply line are configured to provide different constant voltage signals.

2. The display substrate according to claim 1, wherein the pixel circuit further comprises a first reference transistor, wherein a gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor;
the first signal line and the first reference signal line output a same signal.

3. The display substrate according to claim 1, further comprising: a light emitting structure layer disposed at a side of the drive circuit layer away from the base substrate, wherein the light emitting structure layer comprises at least a plurality of light emitting units, at least one of the plurality of light emitting units comprises a cathode, and the cathode is connected with a second power supply line;
the first signal line and the second power supply line output a same signal.

4. The display substrate according to claim 1, wherein the first capacitor comprises at least a first electrode plate as the first end of the first capacitor and a third electrode plate as the second end of the first capacitor, wherein an orthographic projection of the first electrode plate on the base substrate is at least partially overlapped with an orthographic projection of the third electrode plate on the base substrate;
the second capacitor comprises at least a second electrode plate as the second end of the second capacitor and a fourth electrode plate as the first end of the second capacitor, wherein an orthographic projection of the second electrode plate on the base substrate is at least partially overlapped with an orthographic projection of the fourth electrode plate on the base substrate;
the fourth electrode plate is connected with the first signal line, the second electrode plate is connected with the third electrode plate, and the first electrode plate serves as the gate electrode of the drive transistor.

5-7. (canceled)

8. The display substrate according to claim 4, wherein the first power supply line extends along a second direction, and the drive circuit layer further comprises at least one first power supply connection line extending along a first direction, the first direction intersecting with the second direction; the first power supply line is connected with the first power supply connection line to form a mesh-like structure for transmitting a first power supply signal; an orthographic projection of the first power supply connection line on the base substrate is partially overlapped with an orthographic projection of the first capacitor on the base substrate.

9. The display substrate according to claim 8, wherein the drive circuit layer further comprises at least one second power supply connection line extending along the first direction and at least one second power supply line extending along the second direction, the first direction and the second direction intersect; the second power supply line is connected with the second power supply connection line to form a mesh-like structure for transmitting a second power supply signal; the second power supply connection line is located at a side of the first power supply connection line close to the second capacitor.

10-13. (canceled)

14. The display substrate according to claim 4, wherein the drive circuit layer further comprises at least one first reference signal line extending along a first direction and at least one reference signal connection line extending along a second direction, the first direction and the second direction intersect; the first reference signal line is connected with the reference signal connection line to form a mesh-like structure for transmitting a first reference signal;
the first reference signal line serves as the first signal line, and the fourth electrode plate of the second capacitor is connected with the first reference signal line.

15. The display substrate according to claim 14, wherein the first reference signal line is located at a side of the second capacitor away from the first capacitor, and a first reference connection block extending along the second direction is disposed at a side of the first reference signal line close to the second capacitor, the first reference connection block is connected with the fourth electrode plate of the second capacitor through a via, and is further connected with the reference signal connection line through another via.

16. The display substrate according to claim 1, wherein the pixel circuit further comprises a first initialization transistor and a compensation transistor;
a gate electrode of the first initialization transistor is electrically connected with a first scan signal line, a first electrode of the first initialization transistor is electrically connected with a first initial signal line, and a second electrode of the first initialization transistor is electrically connected with the gate electrode of the drive transistor;
a gate electrode of the compensation transistor is electrically connected with a second scan signal line, a first electrode of the compensation transistor is electrically connected with the gate electrode of the drive transistor, and a second electrode of the compensation transistor is electrically connected with a second electrode of the drive transistor.

17. The display substrate according to claim 16, wherein the at least one circuit unit further comprises a first shield electrode, wherein an orthographic projection of the first shield electrode on the base substrate is at least partially overlapped with an orthographic projection of a first active layer between two gate electrodes of first initialization transistors in the circuit unit on the base substrate, and the orthographic projection of the first shield electrode on the base substrate is further at least partially overlapped with an orthographic projection of a second active layer between two gate electrodes of compensation transistors in an adjacent circuit unit on the base substrate.

18. (canceled)

19. The display substrate according to claim 16, wherein extension directions of the first initial signal line, the first scan signal line, and the second scan signal line are at least partially the same and the first initial signal line, the first scan signal line, and the second scan signal line are located at a same side of the first initialization transistor; the first initial signal line is located between the first scan signal line and the second scan signal line.

20. (canceled)

21. The display substrate according to claim 16, wherein the pixel circuit further comprises a second light emitting control transistor;
a gate electrode of the second light emitting control transistor is electrically connected with a second light emitting signal line, a first electrode of the second light emitting control transistor is electrically connected with the second electrode of the drive transistor, and a second electrode of the second light emitting control transistor is electrically connected with a light emitting device;
the second light emitting signal line and the first light emitting signal line are of a same layer structure.

22. The display substrate according to claim 1, wherein the pixel circuit further comprises a second reference transistor and a second initialization transistor; a gate electrode of the second reference transistor is electrically connected with a fourth scan signal line, a first electrode of the second reference transistor is electrically connected with a second reference signal line, and a second electrode of the second reference transistor is electrically connected with the first electrode of the drive transistor;
a gate electrode of the second initialization transistor is electrically connected with the fourth scan signal line, a first electrode of the second initialization transistor is electrically connected with a second initial signal line, and a second electrode of the second initialization transistor is electrically connected with a light emitting device;
active layers of at least two adjacent second initialization transistors along a first direction are connected into an integral structure through a second active connection line.

23. The display substrate according to claim 4, wherein in a direction perpendicular to the display substrate, the drive circuit layer comprises a semiconductor layer, a first conductive layer, a second conductive layer, a third conductive layer, and a fourth conductive layer sequentially disposed on the base substrate;
active layers of the data writing transistor, the drive transistor, and the first light emitting control transistor are located in the semiconductor layer;
gate electrodes of the data writing transistor, the drive transistor, and the first light emitting control transistor, the first electrode plate of the first capacitor, and the second electrode plate of the second capacitor are located in the first conductive layer;
the third electrode plate of the first capacitor and the fourth electrode plate of the second capacitor are located in the second conductive layer;
the third scan signal line is located in the third conductive layer;
the first power supply line and the data signal line are located in the fourth conductive layer.

24. A display apparatus, comprising a display substrate according to claim 1.

25. A preparation method of a display substrate, comprising:
forming a drive circuit layer on a base substrate; wherein the drive circuit layer comprises at least a plurality of circuit units, at least one of the plurality of circuit units comprises a pixel circuit, and the pixel circuit comprises at least a first capacitor, a second capacitor, a data writing transistor, a drive transistor, and a first light emitting control transistor; a first end of the first capacitor is electrically connected with a gate electrode of the drive transistor, a second end of the first capacitor is electrically connected with a second end of the second capacitor, and a first end of the second capacitor is electrically connected with a first signal line; a gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor; a gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor; the first signal line and the first power supply line are configured to provide different constant voltage signals.

26. A display substrate, comprising:
a base substrate and a drive circuit layer disposed on the base substrate, wherein the drive circuit layer comprises at least a plurality of circuit units, at least one of the plurality of circuit units comprises a pixel circuit, and the pixel circuit comprises at least a first capacitor, a second capacitor, a data writing transistor, a drive transistor, and a first light emitting control transistor;
a first end of the first capacitor is electrically connected with a gate electrode of the drive transistor, a second end of the first capacitor is electrically connected with a second end of the second capacitor, and a first end of the second capacitor is electrically connected with a first signal line;
a gate electrode of the data writing transistor is electrically connected with a third scan signal line, a first electrode of the data writing transistor is electrically connected with a data signal line, and a second electrode of the data writing transistor is electrically connected with the second end of the first capacitor and the second end of the second capacitor;
a gate electrode of the first light emitting control transistor is electrically connected with a first light emitting signal line, a first electrode of the first light emitting control transistor is electrically connected with a first power supply line, and a second electrode of the first light emitting control transistor is electrically connected with a first electrode of the drive transistor;
the first signal line and the first power supply line are configured to provide different constant voltage signals;
the data writing transistor, the second capacitor, the first capacitor, and the first light emitting control transistor are sequentially disposed along a second direction, and an orthographic projection of the first capacitor on the base substrate is partially overlapped with an orthographic projection of the drive transistor on the base substrate.

27. The display substrate according to claim 26, wherein the pixel circuit further comprises a first reference transistor, wherein a gate electrode of the first reference transistor is electrically connected with a fifth scan signal line, a first electrode of the first reference transistor is electrically connected with a first reference signal line, and a second electrode of the first reference transistor is electrically connected with the second end of the first capacitor and the second end of the second capacitor;
the first reference signal line is located at a side of the second capacitor away from the first capacitor.

28. (canceled)

29. The display substrate according to claim 26, wherein the drive circuit layer further comprises at least one second power supply connection line extending along a first direction and at least one second power supply line extending along a second direction, the first direction intersecting with the second direction; the second power supply line is connected with the second power supply connection line to form a mesh-like structure for transmitting a second power supply signal; a portion of the second power supply connection line is located between the first capacitor and the second capacitor;
the first signal line and the second power supply line transmit a same signal.

30. The display substrate according to claim 26, wherein the pixel circuit further comprises a first initialization transistor and a compensation transistor;
a gate electrode of the first initialization transistor is electrically connected with a first scan signal line, a first electrode of the first initialization transistor is electrically connected with a first initial signal line, and a second electrode of the first initialization transistor is electrically connected with the gate electrode of the drive transistor;
a gate electrode of the compensation transistor is electrically connected with a second scan signal line, a first electrode of the compensation transistor is electrically connected with the gate electrode of the drive transistor, and a second electrode of the compensation transistor is electrically connected with a second electrode of the drive transistor;
the first initialization transistor and the compensation transistor are located at a side of the first capacitor away from the second capacitor; extension directions of the first initial signal line, the first scan signal line, and the second scan signal line are at least partially the same and the first initial signal line, the first scan signal line, and the second scan signal line are located at a side of the first initialization transistor away from the first capacitor; the first initial signal line is located between the first scan signal line and the second scan signal line.
